(19) United States
(12) Patent Application Publication
(10) Pub. No.: US 2024/0321577 A1
(43) Pub. Date: Sep. 26, 2024

(54) METAL OXIDE FILM, SEMICONDUCTOR DEVICE, AND METHOD FOR EVALUATING METAL OXIDE FILM

(71) Applicant: SEMICONDUCTOR ENERGY LABORATORY CO., LTD., Atsugi-shi, Kanagawa-ken (JP)

(72) Inventors: Toshimitsu OBONAI, Shimotsuke (JP); Yasuharu HOSAKA, Tochigi (JP); Kenichi OKAZAKI, Tochigi (JP); Masahiro TAKAHASHI, Atsugi (JP); Tomonori NAKAYAMA, Atsugi (JP); Tomosato KANAGAWA, Omihachiman (JP); Shunpei YAMAZAKI, Tokyo (JP)

(21) Appl. No.: 18/668,768

(22) Filed: May 20, 2024

Related U.S. Application Data
(62) Division of application No. 17/431,275, filed on Aug. 16, 2021.

(30) Foreign Application Priority Data
Feb. 22, 2019 (JP) 2019-030643
Mar. 8, 2019 (JP) 2019-042866
Apr. 12, 2019 (JP) 2019-076585

(51) Int. Cl. H01L 21/02; C23C 14/00; C23C 14/08; C23C 14/34; H01L 21/66

(52) U.S. Cl. CPC H01L 21/02554; C23C 14/081; C23C 14/086; C23C 14/087; C23C 14/34; H01L 21/02488; H01L 21/02565; H01L 21/02595; H01L 21/02609; H01L 21/02631; H01L 22/12; C23C 14/0036; C23C 14/08

(57) ABSTRACT

A metal oxide film with high electrical characteristics is provided. A metal oxide film with high reliability is provided. The metal oxide film contains indium, M (M is aluminum, gallium, yttrium, or tin), and zinc. In the metal oxide film, distribution of interplanar spacings d determined by electron diffraction by electron beam irradiation from a direction perpendicular to a film surface of the metal oxide film has a first peak and a second peak. The top of the first peak is positioned at greater than or equal to 0.25 nm and less than or equal to 0.30 nm, and the top of the second peak is positioned at greater than or equal to 0.15 nm and less than or equal to 0.20 nm. The distribution of the interplanar spacings d is obtained from a plurality of electron diffraction patterns of a plurality of regions of the metal oxide film. The electron diffraction is performed using an electron beam with a beam diameter of greater than or equal to 0.3 nm and less than or equal to 10 nm.

### CROSS REFERENCE TO RELATED APPLICATIONS

This application is a divisional of U.S. application Ser. No. 17/431,275, filed Aug. 16, 2021, now pending, which is incorporated by reference and is a U.S. National Phase Application under 35 U.S.C. § 371 of International Application PCT/IB2020/050999, filed on Feb. 10, 2020, which is incorporated by reference and claims the benefit of foreign priority applications filed in Japan on Feb. 22, 2019, as Application No. 2019-030643, on Mar. 8, 2019, as Application No. 2019-042866, and on Apr. 12, 2019, as Application No. 2019-076585.

### TECHNICAL FIELD

One embodiment of the present invention relates to a metal oxide film. One embodiment of the present invention relates to a semiconductor device using a metal oxide film. One embodiment of the present invention relates to an evaluation method of a metal oxide film.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device generally means a device that can function by utilizing semiconductor characteristics.

### BACKGROUND ART

As a semiconductor material that can be used in a transistor, an oxide semiconductor has been attracting attention. For example, Patent Document 1 discloses a semiconductor device that achieves increased field-effect mobility (simply referred to as mobility or μFE in some cases) by stacking a plurality of oxide semiconductor layers, containing indium and gallium in an oxide semiconductor layer serving as a channel in the plurality of oxide semiconductor layers, and making the proportion of indium higher than the proportion of gallium.

### REFERENCE

### Patent Document

[Patent Document 1] Japanese Published Patent Application No. 2014-7399

### SUMMARY OF THE INVENTION

### Problems to be Solved by the Invention

An object of one embodiment of the present invention is to provide a metal oxide film with excellent electrical characteristics. An object of one embodiment of the present invention is to provide a metal oxide film with high reliability. An object of one embodiment of the present invention is to provide a metal oxide film with excellent mass productivity. An object of one embodiment of the present invention is to provide a novel metal oxide film.

Another object of one embodiment of the present invention is to provide a semiconductor device that uses a metal oxide film and has excellent electrical characteristics. An object of one embodiment of the present invention is to provide a highly reliable semiconductor device using a metal oxide film.

Another object of one embodiment of the present invention is to provide a novel analysis method, evaluation method, or examination method of a metal oxide film.

Note that the description of these objects does not preclude the existence of other objects. Note that one embodiment of the present invention does not have to achieve all these objects. Note that objects other than these can be derived from the description of the specification, the drawings, the claims, and the like.

### Means for Solving the Problems

One embodiment of the present invention is a metal oxide film containing indium, M (M is aluminum, gallium, yttrium, or tin), and zinc. In the metal oxide film, distribution of interplanar spacings d determined by electron diffraction by electron beam irradiation from a direction perpendicular to a film surface of the metal oxide film has a first peak and a second peak. The top of the first peak is positioned at greater than or equal to 0.25 nm and less than or equal to 0.30 nm, and the top of the second peak is positioned at greater than or equal to 0.15 nm and less than or equal to 0.20 nm. The distribution of the interplanar spacings d is obtained from a plurality of electron diffraction patterns of a plurality of regions of the metal oxide film. The electron diffraction is performed using an electron beam with a beam diameter of greater than or equal to 0.3 nm and less than or equal to 10 nm.

In the above, the height of the top of the first peak is preferably larger than the height of the top of the second peak. Alternatively, in the above, the height of the top of the first peak is preferably smaller than the height of the top of the second peak.

Another embodiment of the present invention is a semiconductor device including a semiconductor layer, a gate electrode, and a gate insulating layer. The semiconductor layer includes the metal oxide film having any one of the above structures.

Another embodiment of the present invention is an evaluation method of a metal oxide film, which includes a step of irradiating a plurality of regions of the metal oxide film with an electron beam with a beam diameter of greater than or equal to 0.3 nm and less than or equal to 10 nm from a direction perpendicular to a film surface of the metal oxide film to acquire a plurality of electron diffraction patterns; a step of calculating interplanar spacings d for a plurality of spots observed in the plurality of electron diffraction patterns; and a step of evaluating crystallinity of the metal oxide film from the shape of frequency distribution of the interplanar spacings d.

Another embodiment of the present invention is an evaluation method of a metal oxide film, which includes a step of irradiating a plurality of regions of the metal oxide film with an electron beam with a beam diameter of greater than or equal to 0.3 nm and less than or equal to 10 nm from a direction perpendicular to a film surface of the metal oxide film to acquire a plurality of electron diffraction patterns; a step of calculating angles θ from reference lines for a plurality of spots observed in the plurality of electron diffraction patterns; and a step of evaluating crystallinity of the metal oxide film from the shape of distribution of the angles θ.

### Effect of the Invention

According to one embodiment of the present invention, a metal oxide film with excellent electrical characteristics can be provided. Furthermore, a metal oxide film with high reliability can be provided. Furthermore, a novel metal oxide film can be provided.

According to one embodiment of the present invention, a semiconductor device that uses a metal oxide film and has excellent electrical characteristics can be provided. Furthermore, a highly reliable semiconductor device using a metal oxide film can be provided.

According to one embodiment of the present invention, a novel analysis method, evaluation method, or examination method of a metal oxide film can be provided.

Note that the description of the effects does not preclude the existence of other effects. Note that one embodiment of the present invention does not need to have all these effects. Note that effects other than these can be derived from the description of the specification, the drawings, the claims, and the like.

### BRIEF DESCRIPTION OF THE DRAWINGS

FIG. 1A is a schematic view of a metal oxide film. FIG. 1B and FIG. 1C are schematic views of electron diffraction patterns. FIG. 1D and FIG. 1E are schematic views of histograms.

FIG. 2A to FIG. 2C are schematic views of histograms.

FIG. 3A and FIG. 3B are schematic views of electron diffraction patterns.

FIG. 4A is an electron diffraction pattern. FIG. 4B is a histogram of a lattice spacing.

FIG. 5A is an electron diffraction pattern. FIG. 5B is a histogram of a lattice spacing.

FIG. 6A is an electron diffraction pattern. FIG. 6B is a histogram of a lattice spacing.

FIG. 7A is an electron diffraction pattern. FIG. 7B is a histogram of a lattice spacing.

FIG. 8A is an electron diffraction pattern. FIG. 8B is a histogram of a lattice spacing.

FIG. 9A is an electron diffraction pattern. FIG. 9B is a histogram of a lattice spacing.

FIG. 10 is a graph showing a ratio of frequency of electron diffraction peaks.

FIG. 11A is a graph showing a change in a lattice spacing from frame to frame. FIG. 11B is a graph showing a change in an angle of a spot from frame to frame.

FIG. 12A is a graph showing a change in a lattice spacing from frame to frame. FIG. 12B is a graph showing a change in an angle of a spot from frame to frame.

FIG. 13A, FIG. 13B, and FIG. 13C are XRD spectra.

FIG. 14A, FIG. 14B, and FIG. 14C are XRD spectra.

FIG. 15A, FIG. 15B, and FIG. 15C are XRD spectra.

FIG. 16A, FIG. 16B, and FIG. 16C are XRD spectra.

FIG. 17 is a graph showing an angle of a top of an X-ray diffraction peak.

FIG. 18A to FIG. 18E are diagrams showing calculation models.

FIG. 19A to FIG. 19E are diagrams showing calculation models.

FIG. 20A is a graph showing a relationship between a temperature and average energy. FIG. 20B is a graph showing a relationship between a temperature and a difference in average energy.

FIG. 21 is a graph illustrating formation energy of a defect.

FIG. 22A is a diagram illustrating classification of IGZO crystal structures. FIG. 22B is a graph illustrating an XRD spectrum of quartz glass. FIG. 22C is a graph illustrating an XRD spectrum of crystalline IGZO. FIG. 22D is a diagram illustrating a nanobeam electron diffraction pattern of crystalline IGZO.

FIG. 23A is a top view of a semiconductor device. FIG. 23B and FIG. 23C are cross-sectional views of the semiconductor device.

FIG. 24A and FIG. 24B are cross-sectional views of a semiconductor device.

FIG. 25A is a top view of a semiconductor device. FIG. 25B and FIG. 25C are cross-sectional views of the semiconductor device.

FIG. 26A is a top view of a semiconductor device. FIG. 26B and FIG. 26C are cross-sectional views of the semiconductor device.

FIG. 27A and FIG. 27B are cross-sectional views of semiconductor devices.

FIG. 28A to FIG. 28C are diagrams showing a structure example of a display device.

FIG. 29 is a diagram showing a cross-sectional structure example of a display device.

FIG. 30 is a diagram showing a cross-sectional structure example of a display device.

FIG. 31 is a diagram showing a cross-sectional structure example of a display device.

FIG. 32A is a block diagram of a display device. FIG. 32B and FIG. 32C are circuit diagrams of the display device.

FIG. 33A, FIG. 33C, and FIG. 33D are circuit diagrams of display devices. FIG. 33B is a timing chart.

FIG. 34A and FIG. 34B show a structure example of a display module.

FIG. 35A to FIG. 35C are diagrams showing structure examples of an electronic device.

FIG. 36A to FIG. 36E are diagrams showing structure examples of an electronic device.

FIG. 37A to FIG. 37G are diagrams showing structure examples of electronic devices.

FIG. 38A to FIG. 38D are diagrams showing structure examples of electronic devices.

FIG. 39A to FIG. 39D are graphs showing Id-Vg characteristics of transistors.

FIG. 40 is a graph showing results of evaluating reliability of transistors.

FIG. 41A to FIG. 41D are graphs showing Id-Vg characteristics of transistors.

FIG. 42 shows HAADEF-STEM images and EDX mapping images.

FIG. 43A to FIG. 43D show results of quantitative analysis of compositions of a metal oxide film.

FIG. 44A to FIG. 44C are histograms of compositions of metal oxide films.

### MODE FOR CARRYING OUT THE INVENTION

Hereinafter, embodiments will be described with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the following description of the embodiments.

Note that in structures of the present invention described below, the same portions or portions having similar functions are denoted by the same reference numerals in different drawings, and a description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not necessarily limited to the illustrated scale.

Note that in this specification and the like, the ordinal numbers such as “first” and “second” are used in order to avoid confusion among components and do not limit the number. A transistor is a kind of semiconductor elements and can achieve amplification of current or voltage, switching operation for controlling conduction or non-conduction, or the like. An IGFET (Insulated Gate Field Effect Transistor) and a thin film transistor (TFT) are in the category of a transistor in this specification.

Functions of a “source” and a “drain” are sometimes replaced with each other when a transistor of opposite polarity is used or when the direction of current is changed in circuit operation, for example. Therefore, the terms “source” and “drain” can be switched in this specification.

Moreover, in this specification and the like, the term “film” and the term “layer” can be interchanged with each other. For example, in some cases, the term “conductive layer” and the term “insulating layer” can be interchanged with the term “conductive film” and the term “insulating film,” respectively.

In this specification and the like, a display panel that is one embodiment of a display device has a function of displaying (outputting) an image or the like on (to) a display surface. Thus, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases. Note that in this specification and the like, a touch panel that is one embodiment of a display device has a function of displaying an image or the like on a display surface and a function of a touch sensor capable of detecting the contact, press, approach, or the like of a sensing target such as a finger or a stylus with or to the display surface. Therefore, the touch panel is one embodiment of an input/output device.

A touch panel can also be referred to as, for example, a display panel (or a display device) with a touch sensor or a display panel (or a display device) having a touch sensor function. A touch panel can include a display panel and a touch sensor panel. Alternatively, a touch panel can have a function of a touch sensor inside a display panel or on a surface thereof.

In this specification and the like, a substrate of a touch panel on which a connector and an IC are mounted is referred to as a touch panel module, a display module, or simply a touch panel or the like in some cases.

### Embodiment 1

In this embodiment, a metal oxide film and a method for evaluating a metal oxide film of embodiments of the present invention will be described.

### Metal Oxide Film

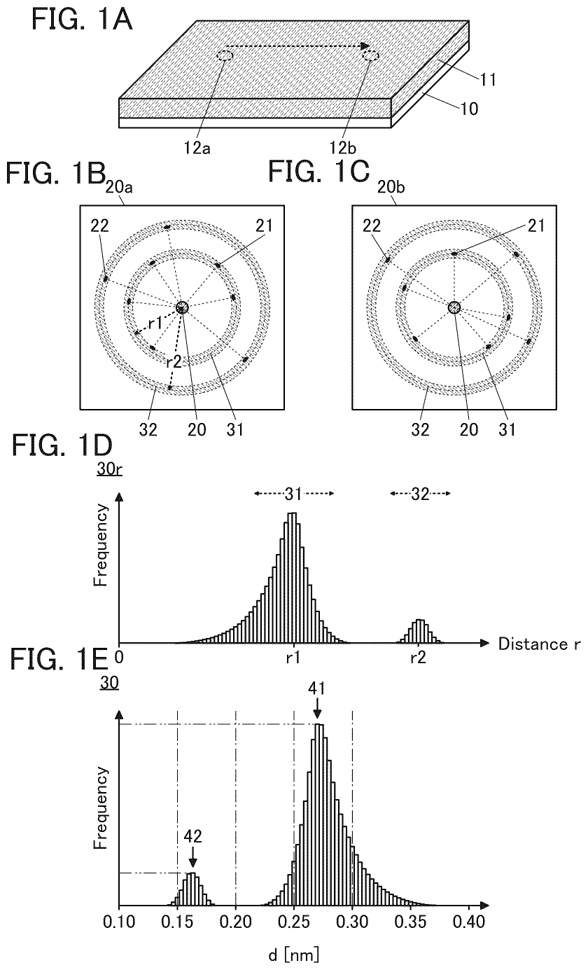

FIG. 1A shows a schematic view of a metal oxide film 11 formed over a substrate 10.

The metal oxide film 11 of one embodiment of the present invention is an oxide film containing indium, M (M is aluminum, gallium, yttrium, or tin), and zinc. Such an oxide film is characterized in that it exhibits semiconductor characteristics. The metal oxide film 11 is preferably a film deposited by a sputtering method. Specifically, a polycrystalline metal oxide target is preferably used as a sputtering target.

The metal oxide film 11 includes a plurality of extremely minute (several nanometers or less) crystal regions with random orientation (or, without orientation). The metal oxide film 11 having such crystallinity has much higher reliability than an amorphous metal oxide film. The metal oxide film 11 may be a film in which a crystal region without orientation and a crystal region with orientation are mixed.

The metal oxide film 11 of one embodiment of the present invention can be applied to a semiconductor device. For example, the metal oxide film can be used as a semiconductor where a channel of a transistor is formed.

It is particularly preferable that the metal oxide film 11 be an oxide film containing indium, gallium, and zinc. For the metal oxide film 11, a material is preferably used whose content ratio of indium, among the metal elements contained in the metal oxide film 11, is high. It is particularly preferable to use a material in which the content ratio of indium is higher than the content ratio of gallium. When the above metal oxide film 11 is used for a semiconductor layer of a transistor, a transistor with high field-effect mobility can be achieved.

The crystallinity of the metal oxide film 11 can be controlled by varying film formation conditions. For example, the film can have high crystallinity when formed with the proportion of an oxygen gas in a film formation gas (also referred to as an oxygen flow rate ratio) set high. In contrast, the film can have low crystallinity when formed using a film formation gas in which the proportion of an oxygen gas is low or a film formation gas containing no oxygen gas. Alternatively, the film can have higher crystallinity when formed with the substrate temperature set higher; the film can have low crystallinity when formed with the substrate temperature set low or when formed in the state where the substrate is not heated. The metal oxide film 11 has higher stability when having higher crystallinity. On the other hand, the metal oxide film 11 having lower crystallinity can more readily increase the field-effect mobility of a transistor when used therein.

### Electron Diffraction

The metal oxide film 11 of one embodiment of the present invention is a film that has the following features in its electron diffraction pattern obtained by electron beam irradiation from a direction perpendicular to the film surface.

As an electron diffraction method, a nanobeam electron diffraction (NBED) method in which a sample is irradiated with a converged electron beam is preferably employed. Alternatively, a selected-area electron diffraction (SAED) method which uses a parallel electron beam and in which a region to be irradiated is narrowed and a minute region is irradiated with the electron beam may be employed.

When the metal oxide film 11 having extremely minute crystal regions is subjected to measurement of an electron diffraction pattern under conditions with an extremely small beam diameter of the electron beam (e.g., greater than or equal to 0.3 nm and less than or equal to 10 nm or less than or equal to 5 nm), a plurality of spots discretely distributed in a circumferential direction (also referred to as direction) are observed. In contrast, in an electron diffraction pattern obtained under conditions with a large beam diameter (e.g., greater than or equal to 50 nm, or greater than or equal to 100 nm), a ring-like (or “annular”) pattern is observed.

FIG. 1B and FIG. 1C are each a schematic view of an electron diffraction pattern obtained when an electron beam having a beam diameter of several nanometers is irradiated from a direction perpendicular to the film surface of the metal oxide film 11. An electron diffraction pattern 20a shown in FIG. 1B is an electron diffraction pattern in a region 12a shown in FIG. 1A, while an electron diffraction pattern 20b shown in FIG. 1C is an electron diffraction pattern in a region 12b which is different from the region 12a.

As shown in FIG. 1B, in the electron diffraction pattern 20a of the metal oxide film 11, a spot (direct spot 20) of the incident electron beam passing through the sample, a first spot 21 closer to the direct spot 20, and a second spot 22 further from the direct spot 20 than the first spot 21 are observed.

The first spot 21 is observed in an annular first region 31 which is at and near a position where a distance r from the direct spot 20 in the radius vector direction is a distance r1. The second spot 22 is observed in an annular second region 32 which is at and near a position where the distance r from the direct spot 20 in the radius vector direction is a distance r2. The second region 32 is positioned outside the first region 31. That is, the distance r2 is larger than the distance r1.

When the irradiation position of the electron beam is scanned parallel to a film surface direction of the metal oxide film 11 as shown in FIG. 1A and an electron diffraction pattern of a region (the region 12b) different from the region 12a is observed, the first spot 21 is observed in a different position in the first region 31 and the second spot 22 is observed in a different position in the second region 32 as shown in FIG. 1C.

This shows that the metal oxide film 11 includes an extremely minute crystal region. Since the positions of the first spot 21 and the second spot 22 are different in the different regions, the minute crystal region included in the metal oxide film 11 is found to have no orientation.

As described above, a plurality of electron diffraction patterns can be observed through measurement which is performed while the irradiation position of an electron beam is scanned parallel to the film surface direction of the metal oxide film 11. From each of a plurality of electron diffraction patterns thus obtained, information such as the positions and detection intensity of the first spot 21 and the second spot 22 can be acquired. As the positional information of the first spot 21 and the second spot 22, there are the distance r from the direct spot 20 and an angle ┐ from a freely determined reference line. From the information obtained from a plurality of electron diffraction patterns, histograms (also referred to as distribution charts or frequency distribution charts) regarding the distance r, the angle ┐, detection intensity, and the like can be obtained.

An evaluation method of the metal oxide film of one embodiment of the present invention is described. First, a plurality of regions of the metal oxide film are irradiated with an electron beam with a beam diameter of greater than or equal to 0.3 nm and less than or equal to 10 nm from a direction perpendicular to the film surface of the metal oxide film, so that a plurality of electron diffraction patterns are acquired. Subsequently, an interplanar spacing d for each of a plurality of spots observed in the plurality of electron diffraction patterns acquired is calculated. Then, the crystallinity of the metal oxide film can be evaluated from the shape of frequency distribution of the calculated interplanar spacings d.

The angle ⁻ from the reference line for each of a plurality of spots observed in a plurality of electron diffraction patterns acquired in a similar manner is calculated, so that the crystallinity of the metal oxide film can be evaluated from the shape of distribution of the angles ┐.

In addition, the crystallinity of the metal oxide film can also be evaluated from information (e.g., shape of distribution) on luminance (detection intensity) of a plurality of spots observed in a plurality of electron beam patterns acquired in a similar manner.

A larger number of electron diffraction patterns are preferably acquired, in which case the information can be more accurate. For example, the number of electron diffraction patterns to be acquired is preferably 50 or more, further preferably 100 or more, still further preferably 1000 or more. The upper maximum is not particularly limited; the obtained information can be sufficiently precise even when the number is 10000 or less, or 5000 or less.

More specific examples are described below.

FIG. 1D shows an example of a histogram 30r which shows the number (frequency) of spots observed in an electron diffraction pattern of the metal oxide film 11 as a function of the distance r from the direct spot 20. As shown in FIG. 1D, in the histogram 30r, there are a peak of the first spots 21 whose top is positioned in the first region 31 and a peak of the second spots 22 whose top is positioned in the second region 32.

In an electron diffraction method, the value of the interplanar spacing d (hereinafter referred to as d value) corresponding to a spot of interest can be calculated by Formula (1) below using the distance r from the center of the direct spot to the spot of interest.

$$[ Formula 1 ]$$

$$d = L λ / r \qquad ( 1 )$$

In Formula (1), L is a camera distance and λ is the wavelength of an electron beam.

FIG. 1E shows a histogram 30 created using the thus calculated d value.

A histogram of the d value obtained from an electron diffraction pattern of the metal oxide film 11 of one embodiment of the present invention has two peaks (a first peak 41 and a second peak 42 from a larger d value side) as shown in FIG. 1E.

The shape of the frequency distribution of the d values of the metal oxide film 11 is preferably such that the top of the first peak 41 is positioned within a range of the d values of greater than or equal to 0.25 nm and less than or equal to 0.30 nm and the top of the second peak 42 is positioned within a range of the d values of greater than or equal to 0.15 nm and less than or equal to 0.20 nm, as shown in FIG. 1E.

A plurality of the first spots 21 constituting the first peak 41 include a spot due to a scattered electron derived from a medium-range order structure of a minute crystalline cluster contained in the metal oxide film 11. The first spots 21 include a scattered electron due to diffraction with a different interplanar spacing in the crystalline cluster, a scattered electron from a crystalline cluster with a different structure, and the like, which causes a variation in the scattering angle, with the result that the width of a region where the d value of the first spot 21 can be observed is large. Accordingly, the full width at half maximum of the first peak 41 tends to be larger than the full width at half maximum of the second peak 42.

Note that the first spots 21 may include a spot due to a diffracted electron diffracted by a minute crystal region contained in the metal oxide film 11.

A plurality of the second spots 22 constituting the second peak 42 are spots due to diffracted electrons diffracted by a minute crystal region contained in the metal oxide film 11. For example, in the case where the crystal region has a crystal structure similar to that of an InGaZnO₄ crystal, the second spots 22 are probably derived from diffracted electrons due to the (110) plane and a crystal plane equivalent to the (110) plane.

The shapes and heights of the first peak 41 and the second peak 42 of the histogram 30 reflect the crystallinity of the metal oxide film 11. It is thus possible to evaluate the crystallinity of the metal oxide film 11 from the shape of the frequency distribution of the histogram 30.

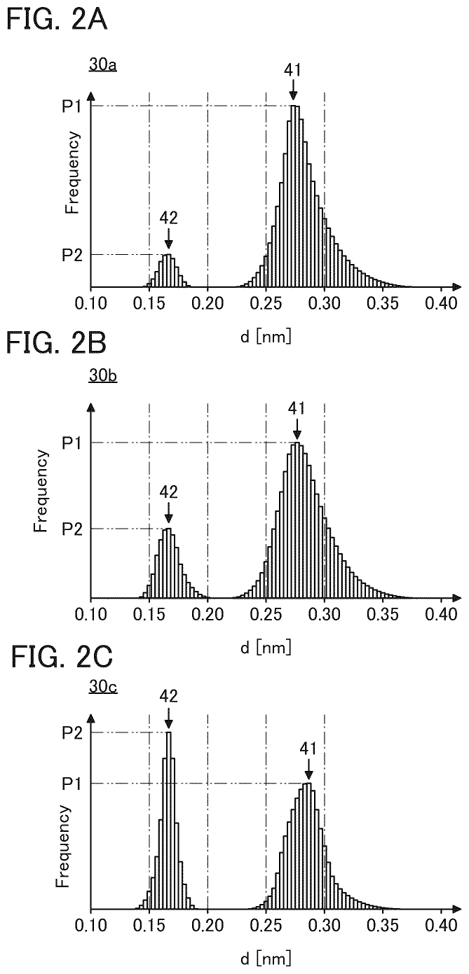

As examples, FIG. 2A, FIG. 2B, and FIG. 2C show the histograms 30 of the metal oxide films 11 having different crystallinities.

A histogram 30a shown in FIG. 2A is an example of the metal oxide film 11 with low crystallinity. FIG. 2A shows a peak value P1, which is the value of the top of the first peak 41, and a peak value P2, which is the value of the top of the second peak 42. Note that the heights and positions of the peak value P1 and the peak value P2 change depending on the data dividing width (class width) of the histogram 30a and thus, the class width can be set as appropriate. Typically, it is preferable that the number of classes be approximately the square root of the total number of data.

In the histogram 30a, the peak value P2 of the second peak 42 is smaller than the peak value P1 of the first peak 41. When the metal oxide film 11 has still lower crystallinity, the second peak 42 is hardly observed in some cases.

A histogram 30b shown in FIG. 2B is an example of the metal oxide film 11 with crystallinity higher than that of FIG. 2A. The number of the second spots 22 derived from diffracted electrons increases owing to the improved crystallinity, whereby the peak value P2 of the second peak 42 becomes larger than that in FIG. 2A. In contrast, the number of the first spots 21 decreases owing to a decrease in the proportion of a less ordered region in the metal oxide film 11, whereby the peak value P1 of the first peak 41 becomes smaller. Accordingly, the difference between the peak value P1 of the first peak 41 and the peak value P2 of the second peak 42 becomes small as compared to FIG. 2A.

A histogram 30c shown in FIG. 2C is an example of the metal oxide film 11 with crystallinity higher than that of FIG. 2B. The number of the second spots 22 increases and the number of the first spots 21 decreases owing to the improved crystallinity, so that the relationship between the peak value P1 of the first peak 41 and the peak value P2 of the second peak 42 is reversed, with the peak value P2 being larger than the peak value P1.

Histogram examples are as described above. The evaluation method described here makes it possible to evaluate the crystallinity of the metal oxide film 11 from the shape of the frequency distribution of the histogram. In addition, the crystallinities of the metal oxide films 11 formed under different film formation conditions can be compared by comparing the frequency distribution shapes of the histograms.

The metal oxide film 11 may be a film in which a low-crystallinity region and a high-crystallinity region are mixed. When an electron diffraction pattern of the metal oxide film 11 is measured while an electron beam is scanned parallel to the film surface direction as described above, an electron diffraction pattern derived from the low-crystallinity region and an electron diffraction pattern derived from the high-crystallinity region appear alternately in some cases.

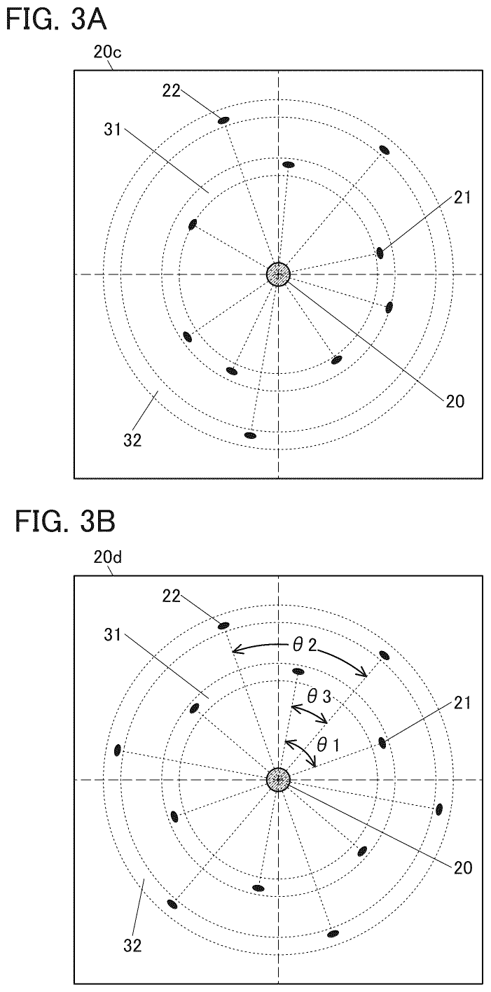

FIG. 3A shows an example of an electron diffraction pattern 20c when the low-crystallinity region of the metal oxide film 11 is subjected to the measurement.

In the electron diffraction pattern 20c, a plurality of the first spots 21 in the first region 31 are observed. The first spots 21 vary in the position in the radius vector direction (specifically, the distance from the direct spot 20 to the first spot 21). Although not shown here, the first spots 21 also vary in the detection intensity.

In the electron diffraction pattern 20c, the second spots 22 in the second region 32 are observed. The variation of the second spots 22 in the radius vector direction is smaller than that of the first spots 21. In many cases, the number of the second spots 22 observed is smaller than that of the first spots 21 observed, because of the low crystallinity of the region. In addition, the detection intensity is sometimes relatively low.

FIG. 3B shows an example of an electron diffraction pattern 20d when the high-crystallinity region of the metal oxide film 11 is subjected to the measurement.

In the electron diffraction pattern 20d, six first spots 21 in the first region 31 are observed. An angle ┐1 formed by two adjacent first spots 21 with respect to the direct spot 20 as the center is approximately 60°. That is, the six first spots 21 observed have six-fold symmetry with respect to the direct spot 20 as the center. The position in the radius vector direction and the detection intensity of the first spots 21 vary less than those of the first spots 21 in the electron diffraction pattern 20c.

In the electron diffraction pattern 20d, six second spots 22 in the second region 32 are observed. In a manner similar to that of the first spots 21, the second spots 22 observed have six-fold symmetry, and an angle ┐2 formed by two adjacent second spots 22 is approximately 60°.

An angle ┐3 formed by the first spot 21 and the second spot 22 with respect to the direct spot 20 as the center is approximately 30°. It is thus found that the high-crystallinity region of the metal oxide film 11 has six-fold symmetry with respect to an axis perpendicular to the film surface.

In the case where the crystal region included in the metal oxide film 11 has a crystal structure similar to that of an InGaZn₂O₅ crystal, the first spots 21 are probably derived from diffracted electrons due to the (100) plane and a crystal plane equivalent to the (100) plane. Note that in the case where the crystal region has a crystal structure similar to that of an InGaZnO₄ crystal, the (100) plane satisfies the extinction rule and thus, no diffracted electron is observed in theory. However, even when a crystal structure similar to that of an InGaZnO₄ crystal is included, a diffracted electron from the (100) plane which is supposed not to be observed is observed in some cases where the crystal region is, instead of being entirely a complete crystal, in an incomplete state including lattice distortion and the extinction rule is accordingly violated.

In the case where the crystal structure of the crystal region included in the metal oxide film 11 is classified as a hexagonal crystal system, from the six-fold symmetry of the electron diffraction pattern 20d obtained by electron beam irradiation perpendicular to the film surface, the crystal orientation of the crystal region included in the metal oxide film 11 can be presumed to be such that the c-axis is aligned in the thickness direction.

### Formation Method of Metal Oxide Film

A formation method of the metal oxide film of one embodiment of the present invention is described below.

The metal oxide film of one embodiment of the present invention can be formed by a sputtering method in the state where the substrate is heated or not heated.

In performing deposition with the substrate heated, the substrate temperature is higher than or equal to room temperature and lower than or equal to 250° C., preferably higher than or equal to room temperature and lower than or equal to 200° C., further preferably higher than or equal to room temperature and lower than or equal to 140°° C. For example, when the substrate temperature is higher than or equal to room temperature and lower than 140° C., high productivity is achieved, which is preferable.

In the case where deposition is performed without heating the substrate, the substrate temperature is initially room temperature or a temperature close to room temperature. Note that the energy given to the substrate from sputtered particles or the like at the time of the deposition might heat the substrate. The apparatus for depositing the metal oxide film does not need a mechanism for heating the substrate, which allows the apparatus to be simple and the cost to decrease.

The deposition may be performed under an oxygen-containing atmosphere. For example, the proportion of the oxygen flow rate with respect to the total flow rate of the deposition gas fed to the deposition chamber of the deposition apparatus (hereinafter referred to as oxygen flow rate ratio) can be set to an appropriate value within a range of greater than or equal to 0%and less than or equal to 100%. By adjusting the oxygen flow rate, the crystallinity of the metal oxide film to be deposited can be controlled. Specifically, the higher the oxygen flow rate ratio is, the higher the crystallinity of the metal oxide film can be; the lower the oxygen flow rate ratio is, the lower the crystallinity of the metal oxide film can be. As a gas contained in the deposition gas other than oxygen, a rare gas such as argon can be used, for example. Deposition under an oxygen-containing atmosphere can reduce oxygen vacancies in the metal oxide film. Alternatively, deposition may be performed under an atmosphere containing no oxygen.

An oxide target that can be used for deposition of the metal oxide film can be, for example, an In—M—Zn-based oxide (M is Al, Ga, Y, or Sn). In particular, an In—Ga—Zn-based oxide is preferably used.

As an oxide target that can be used for the deposition of the metal oxide film, an In—M-based oxide, an In—Zn-based oxide, or the like can also be used. An In—Ga an oxide is particularly preferable because an oxygen vacancy is not easily formed.

Here, the metal oxide contained in the oxide target preferably has a high In content ratio. For example, in the metal oxide target used, the proportion of In is preferably greater than or equal to 33% and less than or equal to 60%, further preferably greater than or equal to 40% and less than or equal to 50% when the total composition of In, M, and Zn is 1 (100%). Typically, it is possible to use an oxide of In:Ga:Zn=1:1:1 or the neighborhood thereof, an oxide of In:Ga:Zn=4:2:3 or the neighborhood thereof, an oxide of In:Ga:Zn=4:2:4.1 or the neighborhood thereof, an oxide of In:Ga:Zn=5:1:3 or the neighborhood thereof, an oxide of In:Ga:Zn=5:3:4 or the neighborhood thereof, an oxide of In:Ga:Zn=10:1:3 or the neighborhood thereof, or the like.

Thus, the deposited metal oxide film can be a metal oxide film having a high In content ratio. Here, the composition of the deposited metal oxide film does not necessarily agree with that of the oxide target. Specifically, the Zn content ratio of the deposited metal oxide film tends to be lower than that of the oxide target.

In the above manner, the metal oxide film can be formed.

Note that a method for forming the metal oxide film is not limited to the above. Any of the other film formation methods such as a plasma-enhanced chemical vapor deposition (PECVD) method, a thermal CVD (Chemical Vapor Deposition) method, an ALD (Atomic Layer Deposition) method, a vacuum evaporation method, a pulsed laser deposition (PLD) method, and a liquid phase method (e.g., a spin coating method or a spray method) may be employed. As examples of a thermal CVD method, an MOCVD (Metal Organic Chemical Vapor Deposition) method and the like can be given.

The above is the description of the formation method of the metal oxide film.

### Evaluation Example of Metal Oxide Film

Results of analyzing a metal oxide film of one embodiment of the present invention by the above-described evaluation method are described below.

Crystallinities of metal oxide films fabricated by different methods were evaluated through nanobeam electron diffraction analysis and X-ray diffraction (XRD) analysis. For the evaluation, samples (sample A1 to sample A6) in each of which a metal oxide film with a thickness of 40 nm was formed over a silicon wafer were used. An In—Ga—Zn oxide was used for the metal oxide film, and the deposition conditions of the metal oxide film were different between the samples.

### Fabrication of Sample

The metal oxide films were formed by a sputtering method using an In—Ga—Zn oxide target (In:Ga:Zn=4:2:4.1 [atomic ratio]). Note that the film composition of a sample formed using a target having a composition In:Ga:Zn=4:2:4.1 [atomic ratio] is around In:Ga:Zn=4:2:3 [atomic ratio].

Table 1 lists the deposition conditions of the metal oxide films of sample A1 to sample A6. Note that in Table 1, Tsub, O₂/(Ar+O₂), Pressure, and Power respectively indicate the substrate temperature, the oxygen flow rate ratio, the pressure, and the power at the time of the deposition of the metal oxide film.

TABLE 1

| | | Tsub | O₂/(Ar + O₂) | Pressure | Power |
|---|---|---|---|---|---|
| sample A1 | IGZO | RT | 10% | 0.6 Pa | 2.5 kW |
| sample A2 | (4:2:3) | RT | 30% | 0.6 Pa | 2.5 kW |
| sample A3 | | RT | 40% | 0.6 Pa | 2.5 kW |
| sample A4 | | RT | 50% | 0.6 Pa | 2.5 kW |
| sample A5 | | 100° C. | 10% | 0.6 Pa | 2.5 kW |
| sample A6 | | 100° C. | 30% | 0.6 Pa | 2.5 kW |

For sample A1, the substrate temperature at the time of the deposition of the metal oxide film was room temperature (hereinafter also denoted as RT). A mixed gas of an oxygen gas and an argon gas was used as the deposition gas, and the oxygen flow rate ratio was 10%. The deposition pressure was 0.6 Pa, and the power was 2.5 kW.

For sample A2, the substrate temperature at the time of the deposition of the metal oxide film was room temperature (RT). A mixed gas of an oxygen gas and an argon gas was used as the deposition gas, and the oxygen flow rate ratio was 30%. The deposition pressure was 0.6 Pa, and the power was 2.5 kW.

For sample A3, the substrate temperature at the time of the deposition of the metal oxide film was room temperature (RT). A mixed gas of an oxygen gas and an argon gas was used as the deposition gas, and the oxygen flow rate ratio was 40%. The deposition pressure was 0.6 Pa, and the power was 2.5 kW.

For sample A4, the substrate temperature at the time of the deposition of the metal oxide film was room temperature (RT). A mixed gas of an oxygen gas and an argon gas was used as the deposition gas, and the oxygen flow rate ratio was 50%. The deposition pressure was 0.6 Pa, and the power was 2.5 kW.

For sample A5, the substrate temperature at the time of the deposition of the metal oxide film was 100° C. A mixed gas of an oxygen gas and an argon gas was used as the deposition gas, and the oxygen flow rate ratio was 10%. The deposition pressure was 0.6 Pa, and the power was 2.5 kW.

For sample A6, the substrate temperature at the time of the deposition of the metal oxide film was 100°° C. A mixed gas of an oxygen gas and an argon gas was used as the deposition gas, and the oxygen flow rate ratio was 30%. The deposition pressure was 0.6 Pa, and the power was 2.5 kW.

### Nanobeam Electron Diffraction

Each of sample A1 to sample A6 was thinned in a direction parallel to the formation surface of the metal oxide film to have a thickness of approximately 20 nm to 30 nm. The thinned samples each include the surface of the metal oxide film at the time of the deposition of the metal oxide film.

Next, an electron beam with an acceleration voltage of 200 kV (wavelength: approximately 2.51 pm) and a beam diameter of 1 nm was incident from a direction perpendicular to the formation surface of the metal oxide film, so that a plurality of electron diffraction patterns were obtained. The plurality of electron diffraction patterns were obtained by capturing a moving image of an electron diffraction pattern while an electron beam irradiation portion was moved. The moving image was captured while the electron beam irradiation portion was moved approximately 0.08 nm to 0.10 nm per frame, and approximately 3700 frames for each sample were obtained. The electron diffraction patterns were captured using an imaging plate with 200 pixels×200 pixels. The magnitude (q) of a scattering vector for one pixel was 0.082426/nm/pixel.

Next, spots were examined for each frame of the moving image.

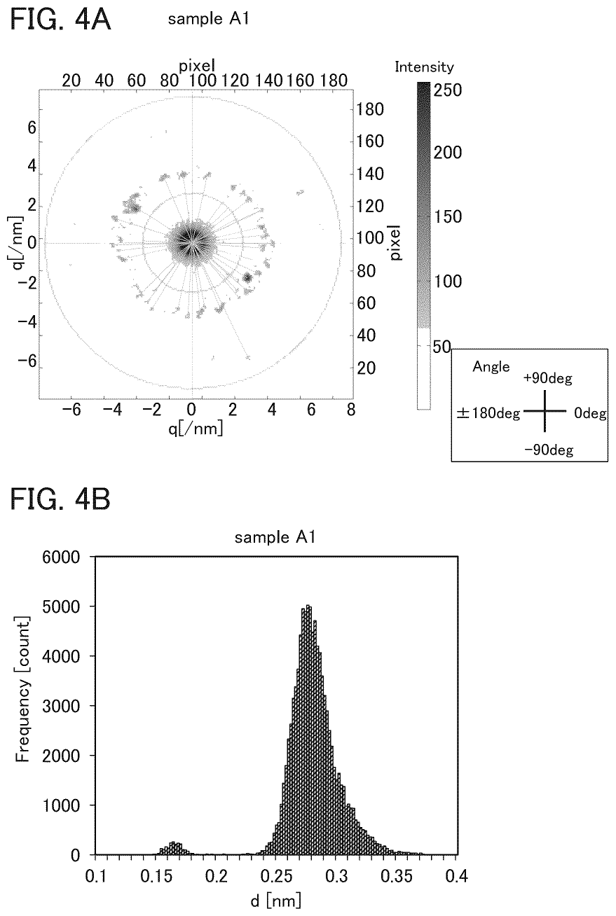

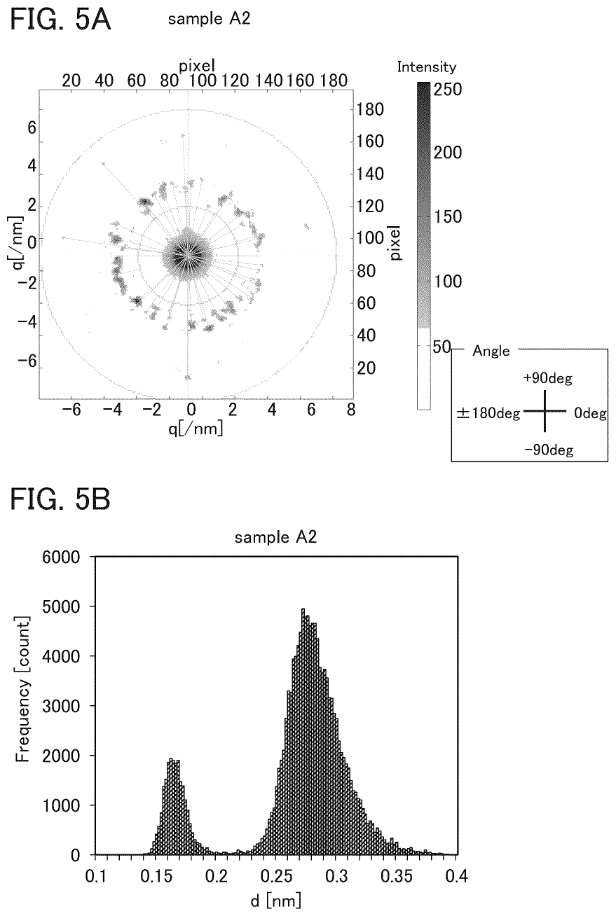

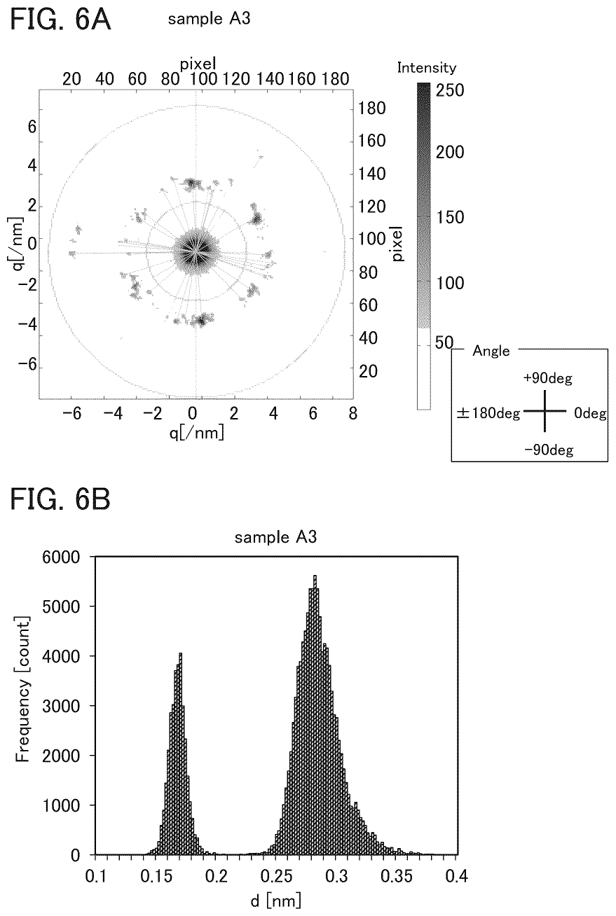

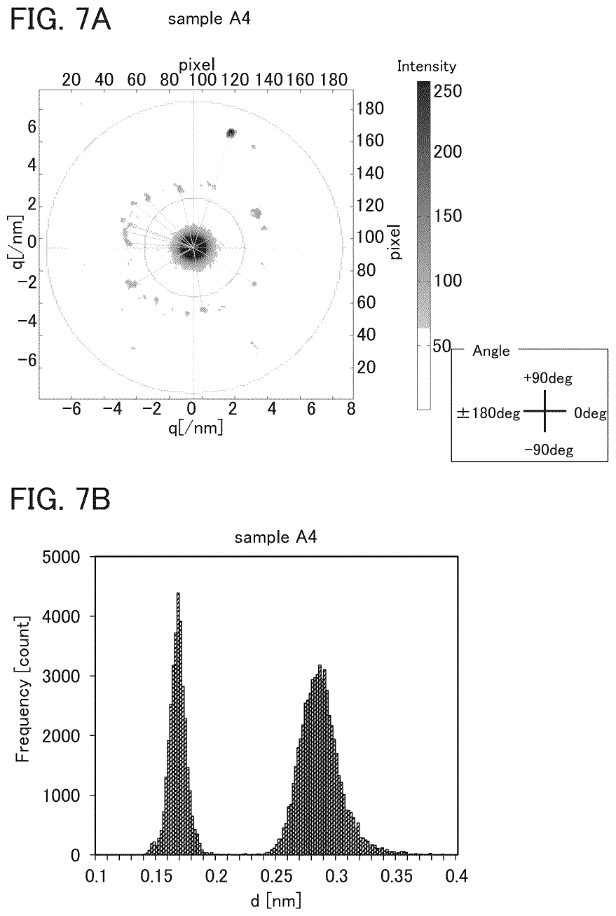

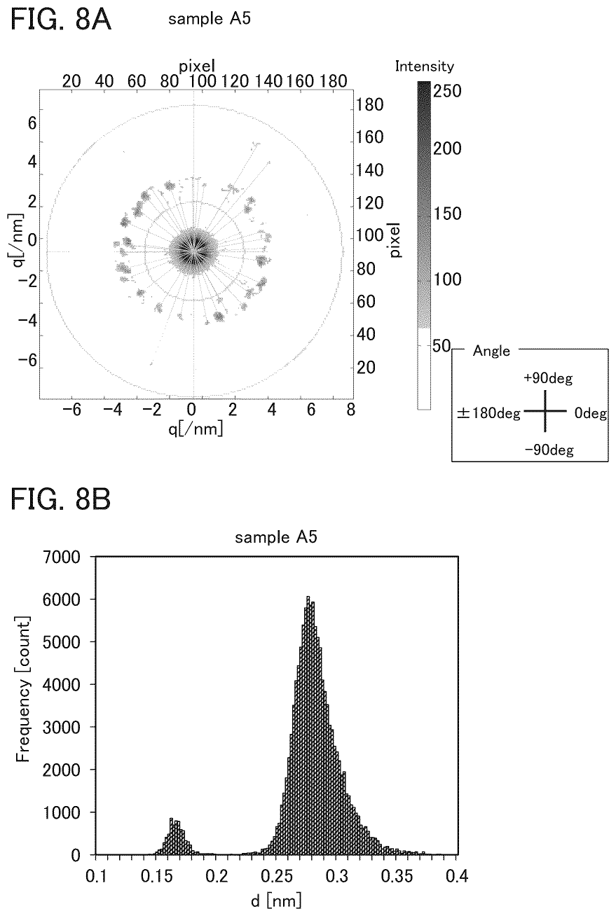

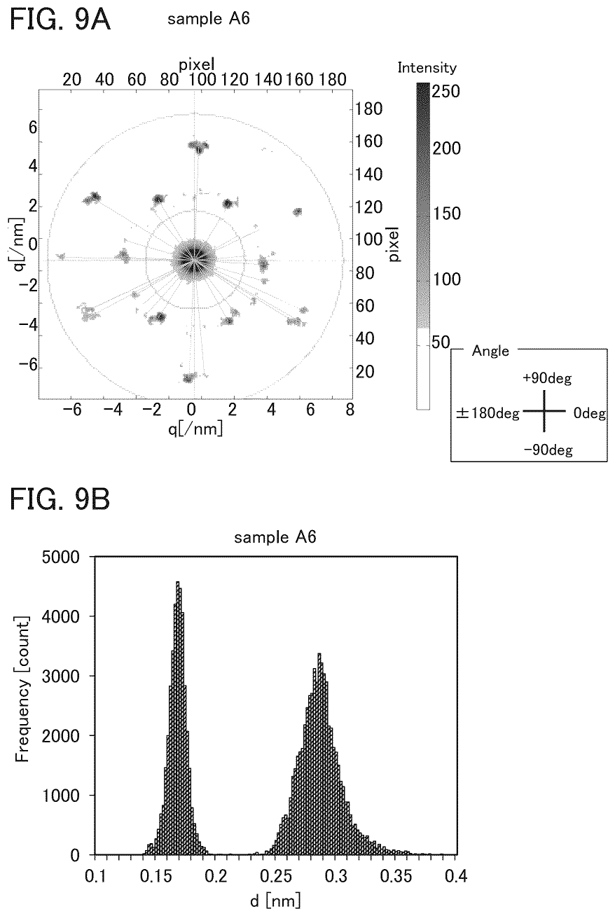

FIG. 4A and FIG. 4B show results of the nanobeam electron diffraction for sample A1. FIG. 5A and FIG. 5B show results of the nanobeam electron diffraction for sample A2. FIG. 6A and FIG. 6B show results of the nanobeam electron diffraction for sample A3. FIG. 7A and FIG. 7B show results of the nanobeam electron diffraction for sample A4. FIG. 8A and FIG. 8B show results of the nanobeam electron diffraction for sample A5. FIG. 9A and FIG. 9B show results of the nanobeam electron diffraction for sample A6.

Each of FIG. 4A, FIG. 5A, FIG. 6A, FIG. 7A, FIG. 8A, and FIG. 9A shows the electron diffraction pattern of the final frame of the moving image for the sample. In each of the drawings, the upper horizontal axis and the right vertical axis represent the coordinates of the pixels of the imaging plate (denoted as “pixel”), where the reference is at the lower left. The lower horizontal axis and the left vertical axis represent the magnitude (q [/nm]) of a scattering vector. The dots shown in each drawing are more highly colored when the intensity of spots (detection intensity (“Intensity”)) is higher and are more lightly colored when it is lower.

The position and intensity value of each of the spots (first spots) observed in the region that is 30 pixels to 90 pixels (inclusive) away from the center of the electron diffraction pattern were obtained. In FIG. 4A, FIG. 5A, FIG. 6A, FIG. 7A, FIG. 8A, and FIG. 9A, the region 30 pixels away from the center and the region 90 pixels away from the center are shown as solid-line circles. The region 30 pixels to 90 pixels (inclusive) away from the center of the electron diffraction pattern corresponds to lattice spacings (d) of greater than or equal to 0.13348 nm and less than or equal to 0.4044 nm. Only the spots whose intensity (0 to 255) was 64 or more and whose area was two pixels or more were subject to the evaluation. In FIG. 4A, FIG. 5A, FIG. 6A, FIG. 7A, FIG. 8A, and FIG. 9A, the center of the electron diffraction pattern and each spot are connected with a solid line. Note that the center of the electron diffraction pattern was the center of the spot (also referred to as direct spot) of an incident electron beam which passed through the sample without being diffracted therein.

FIG. 4B, FIG. 5B, FIG. 6B, FIG. 7B, FIG. 8B, and FIG. 9B are each a histogram (frequency distribution chart) of lattice spacings (d) in all the frames of the moving image acquired from the sample. In each drawing, the horizontal axis represents a lattice spacing (d [nm]) and the vertical axis represents frequency (Frequency [count]). Note that in this embodiment, the data interval (class width) of the histogram was a lattice spacing (d) of 0.002 nm.

As shown in FIG. 4B, FIG. 5B, FIG. 6B, FIG. 7B, FIG. 8B, and FIG. 9B, under all the conditions, there are a peak (first peak) whose top is in the range of lattice spacings (d) of greater than or equal to 0.25 nm and less than or equal to 0.30 nm and a peak (second peak) whose top is in the range of lattice spacings (d) of greater than or equal to 0.15 nm and less than or equal to 0.20 1 m.

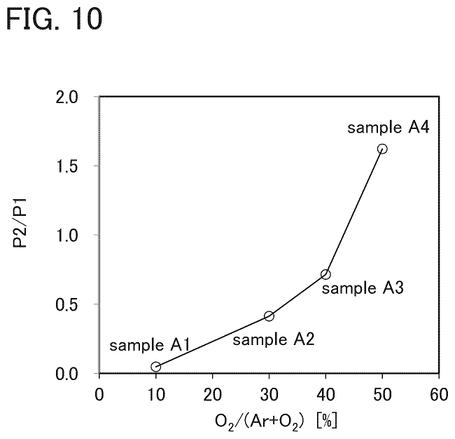

Here, FIG. 10 shows a ratio (P2/P1) of the value of the top of the second peak (the peak value P2) to the value of the top of the first peak (the peak value P1) for each of sample A1 to sample A4. In FIG. 10, the horizontal axis represents the oxygen flow rate ratio (O₂/(Ar+O₂) [%]) at the time of the deposition of the metal oxide film, whereas the vertical axis represents the ratio (P2/P1) of the peak value P2 to the peak value P1. Note that the values shown in FIG. 10 use the frequency at d=0.278 nm as the peak value P1 and the frequency at d=0.168 nm as the peak value P2.

When sample A1 to sample A4 are compared, it is found that the second peak tends to be higher when the oxygen flow rate ratio is higher. In sample A1 to sample A3, the value of the top of the first peak (the peak value P1) is larger than the value of the top of the second peak (the peak value P2). In contrast, in sample A4 under the conditions with the highest oxygen flow rate ratio, the relationship between the values is reversed, i.e., the value of the top of the second peak (the peak value P2) is larger than the value of the top of the first peak (the peak value P1), and the value of P2/P1 shown in FIG. 10 exceeds 1.

In a similar manner, comparing sample A5 and sample A6 shows that the value of the top of the first peak is larger than the value of the top of the second peak in sample A5 under the conditions with a low oxygen flow rate ratio, whereas the value of the top of the second peak is larger than the value of the top of the first peak in sample A6 under the conditions with a high oxygen flow rate ratio. It can be thus confirmed that a higher oxygen flow rate ratio led to higher crystallinity.

Comparing sample A1 and sample A5, in which the deposition was performed with the same oxygen flow rate ratio, shows that the second peak of sample A5 is higher. The same applies to sample A2 and sample A6. It can be thus confirmed that a higher substrate temperature at the time of the deposition results in higher crystallinity even with the same oxygen flow rate ratio.

By the evaluation method of one embodiment of the present invention, information on the crystallinity of a metal oxide film can be obtained not only from a histogram but also from data for each frame regarding the position and luminance of a detected spot.

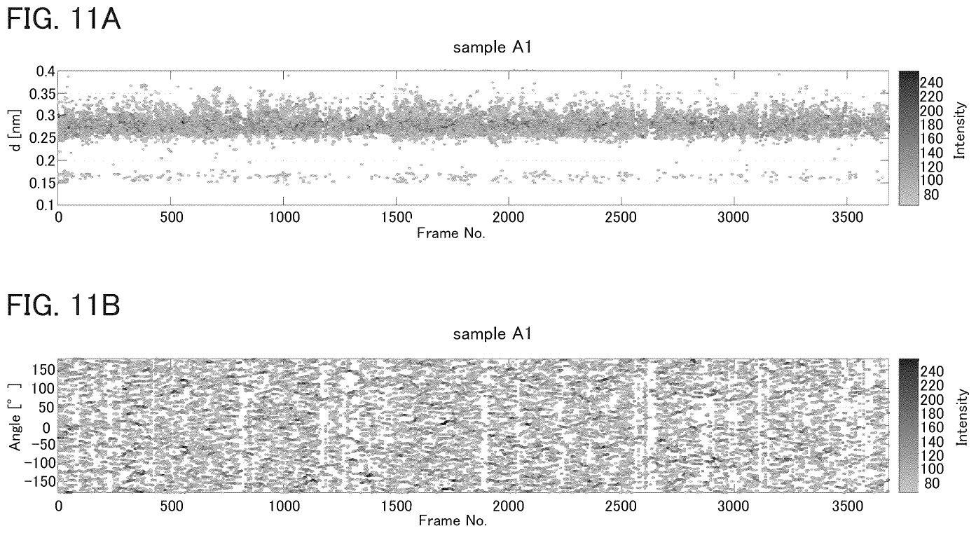

FIG. 11A shows a change in the lattice spacing (d) from frame to frame for sample A1. In FIG. 11A, the horizontal axis represents the frame number (Frame No.) and the vertical axis represents the lattice spacing (d [nm]). The dots shown in FIG. 11A are more highly colored when the intensity of spots is higher and are more lightly colored when it is lower.

FIG. 11B shows a change in the angle of a spot from frame to frame for sample A1. In FIG. 11B, the horizontal axis represents the frame number (Frame No.) and the vertical axis represents the angle of a spot (Angle [°]). The dots shown in FIG. 11B are more highly colored when the intensity of spots is higher and are more lightly colored when it is lower.

As shown in FIG. 11A, in sample A1, the first spots were observed in the region where the lattice spacing (d) is 0.25 nm to 0.35 nm and the second spots were observed in the region where the lattice spacing (d) is 0.15 nm to 0.20 nm. As shown in FIG. 11A, the first spots were continuously observed regardless of the measurement position, whereas the second spots were observed discretely. It is presumable that in the position where the second spot is observed, there is a region having crystallinity which is high as compared to other positions. It can be thus confirmed that the metal oxide film did not have uniform crystallinity but a region with relatively high crystallinity and a region with relatively low crystallinity were mixed therein.

As shown in FIG. 11B, there is almost no angle dependence of a spot in sample A1. It is thus presumed that almost all the crystal regions included in sample A1 are oriented randomly without orientation.

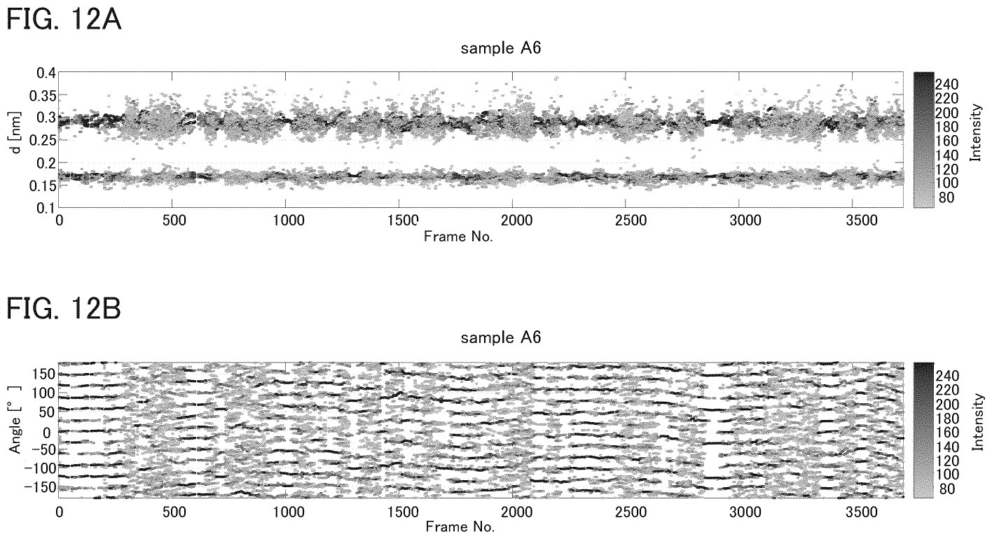

Next, FIG. 12A shows a change in the lattice spacing (d) from frame to frame for sample A6, and FIG. 12B shows a change in the angle of a spot from frame to frame.

In FIG. 12A, the second spots which can be seen in the region where the lattice spacing (d) is 0.15 nm to 0.20 nm are continuously observed regardless of the position (frame); thus, it can be confirmed that sample A6 has much higher crystallinity than sample A1. With a focus on the first spots which can be seen in the region where the lattice spacing (d) is 0.25 nm to 0.35 nm, it can be confirmed that a region with a small variation (e.g., the range from the 0-th frame to the 200-th frame) and a region with a large variation (e.g., the range from the 300-th frame to the 500-th frame) alternately appear. In the region with a small variation of the first spots, a variation of the second spots also tends to be small. It is thus presumed that a crystal region with a large size exists in the metal oxide film.

Moreover, from FIG. 12B, it can be confirmed that spots are discretely observed at intervals of approximately 30° in the region with a small variation of the first spots in FIG. 12A. In FIG. 9A, six first spots and six second spots outside the first spots are observed in a manner to be positioned at the vertices of the respective regular hexagons, which shows that the electron diffraction pattern has six-fold symmetry. It is thus presumed that one crystal region having six-fold symmetry is observed in the region with a small variation of the first spots in FIG. 12A and FIG. 12B.

As described above, the crystallinities of metal oxide films can be precisely evaluated and compared by the evaluation method of one embodiment of the present invention.

### X-Ray Diffraction

Next, X-ray diffraction (XRD) analysis was performed on sample A1 to the sample A6.

For the XRD analysis, a GIXRD (Grazing-Incidence XRD) method that is one kind of an out-of-plane method was used. A GIXRD method is also referred to as a thin film method or a Seemann-Bohlin method. In a GIXRD method, X-ray diffraction intensity is measured while the incident angle of an X-ray is fixed at an extremely shallow angle and the angle of a detector facing an X-ray source is changed. In this embodiment, the incident angle was 0.70°. CuK⁻ rays with a wavelength of 0.15418 nm were used as an X-ray source, the scanning range was 2┐=15° to 70°, and the step width was 0.01°.

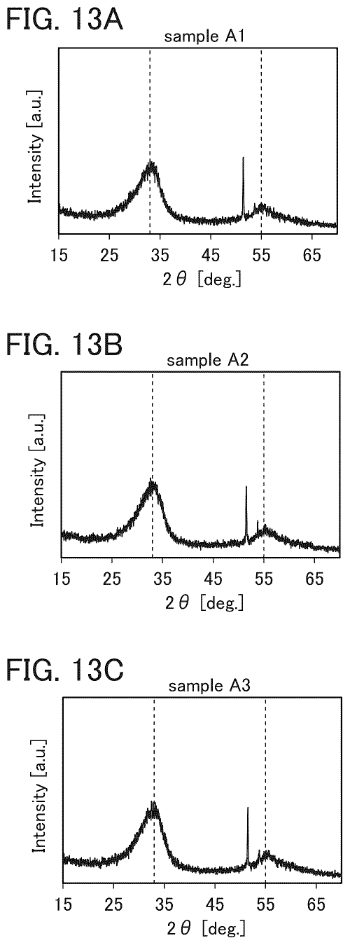

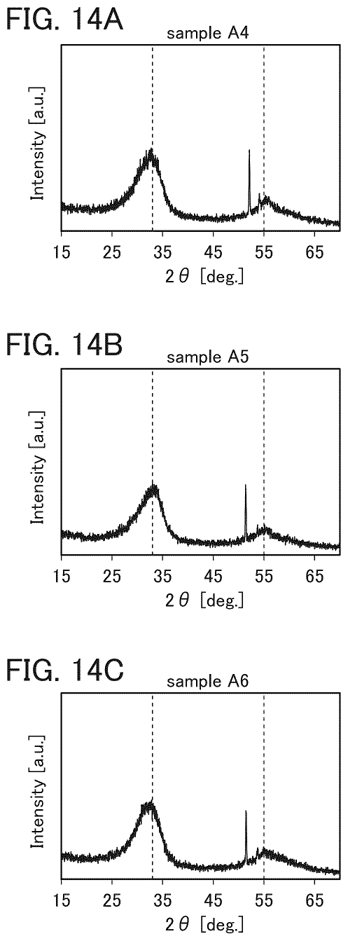

FIG. 13A to FIG. 13C show the XRD measurement results of sample A1 to sample A3. FIG. 14A to FIG. 14C show the XRD measurement results of sample A4 to sample A6.

In FIG. 13A to FIG. 14C, the horizontal axis represents 2⁻ and the vertical axis represents intensity. In FIG. 13A to FIG. 14C, dashed lines as auxiliary lines are shown at 2┐=33° (denoted as deg.) and 2┐=55°.

As shown in FIG. 13A to FIG. 14C, diffraction peaks were observed at 2┐ of around 33° and at 2┐ of around 55° in each sample. The diffraction peak at 2┐ of around 33° corresponds to a lattice spacing (d) of approximately 0.27 nm and can be deemed to correspond to the first peak in the aforementioned electron diffraction. In addition, the peak at 2┐ of around 55° was also observed. Note that a sharp peak observed at 2┐ of around 51° is a peak attributed to diffraction from the silicon wafer as the substrate.

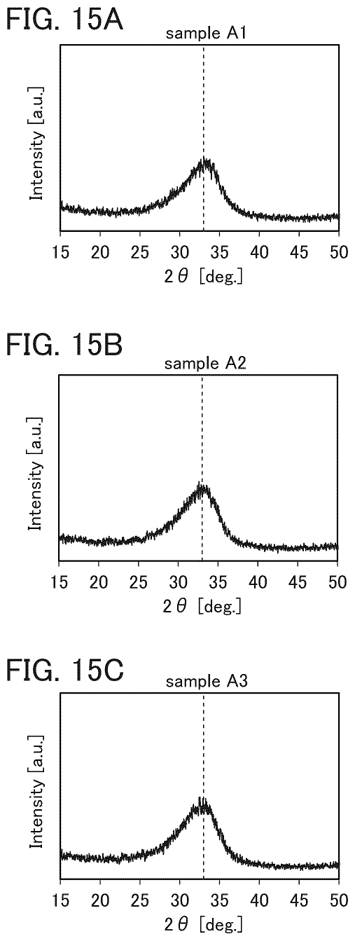

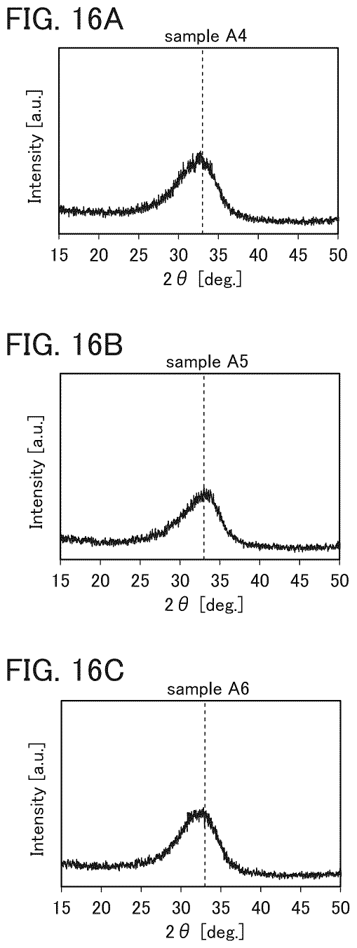

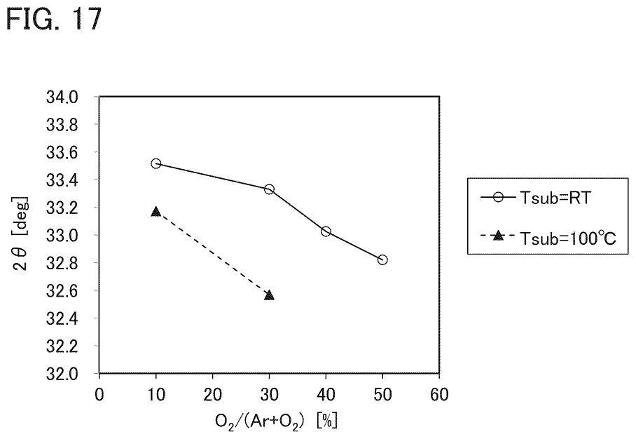

The angle (2┐) of the top of the diffraction peak at 2┐ of around 33° observed in each sample was calculated by fitting of the Lorenz function. A least squares method was used for the fitting of the Lorenz function. FIG. 15A, FIG. 15B, and FIG. 15C show enlarged views of FIG. 13A, FIG. 13B, and FIG. 13C. FIG. 16A, FIG. 16B, and FIG. 16C show enlarged views of FIG. 14A, FIG. 14B, and FIG. 14C. FIG. 17 shows the angles (2┐) of the tops of the diffraction peaks of the samples. In FIG. 17, the horizontal axis represents the oxygen flow rate ratio (O₂/(Ar+O₂) [%]) at the time of the deposition of the metal oxide film and the vertical axis represents the angle (2┐ [deg.]) of the top of the diffraction peak. In FIG. 17, the samples (denoted as Tsub=RT) whose substrate temperature was room temperature are plotted as circles, and the samples (denoted as Tsub=100°° C.) whose substrate temperature was 100° C. are plotted as triangles.

As shown in FIG. 15A to FIG. 16C and FIG. 17, a higher oxygen flow rate ratio at the time of the deposition of the metal oxide film tended to result in smaller 2┐ of the top of the diffraction peak. A higher substrate temperature at the time of the deposition of the metal oxide film tended to result in smaller 2┐ of the top of the diffraction peak. This is presumably because higher crystallinity of the metal oxide film results in a higher intensity of the diffraction peak at 2┐ of around 31° (which corresponds to the peak of the (009) plane of an InGaZnO₄ crystal).

As shown in FIG. 17, information on the crystallinity of a metal oxide film can be obtained by XRD analysis. Accordingly, more detailed information on the crystallinity of a metal oxide film can be obtained through multifaceted analysis combining the above-described evaluation method using electron diffraction with the evaluation method using XRD which is described here as an example.

### Stability of nc Film

In this section, the stability of a metal oxide film including a submicroscopic crystal region (hereinafter also referred to as nc film) is described with results of first-principles calculation.

Note that to describe the stability of an nc film, two calculation models (Calculation Model 1A and Calculation Model 2A) were prepared. Calculation Model 1A is a calculation model including a crystal region and simulating an nc film. Calculation Model 2A is a calculation model including no crystal region and simulating an amorphous film. Note that the crystal region will be described later.

### Creating Method of Calculation Model 1A

A creating method of Calculation Model 1A is described below.

First, a hexagonal-prism-shaped region (referred to as crystal region) is cut from a crystal structure of an In—Ga—Zn oxide of In:Ga:Zn:O=1:1:1:4 [atomic ratio], and the crystal region is placed at the center of the calculation model. Note that the number of atoms placed in the crystal region is 87. Hereinafter, the atoms positioned in the crystal region mean the 87 atoms placed in the crystal region. Any one or more of the atoms positioned in the crystal region move to a peripheral portion of the crystal region in some cases as a result of calculation performed later.

Next, a plurality of In atoms, a plurality of Ga atoms, a plurality of Zn atoms, and a plurality of O atoms are randomly placed in the peripheral portion of the above crystal region. Note that the numbers of the In atoms, the Ga atoms, the Zn atoms, and the O atoms which are placed in the peripheral portion and the size of the peripheral portion are adjusted such that the atomic ratio of the atoms placed in the above crystal region and the peripheral portion becomes In:Ga:Zn:O=1:1:1:4 and the calculation model has a density of 6.1 g/cm³. Note that the number of atoms placed in the peripheral portion is 291. Accordingly, the number of atoms included in the calculation model is 378. Any one or more of the atoms placed in the peripheral portion move to the crystal region in some cases as a result of calculation performed later.

Then, the coordinates of the atoms positioned in the above crystal region are fixed and calculation for melting the above peripheral portion is performed. Specifically, the temperature is set to 3500 K; the time step, 1 fs; and the number of steps, 6000. The calculation which is performed with the temperature, the time step, and the number of steps set is hereinafter referred to as first-principles molecular dynamics calculation or quantum molecular dynamics calculation in some cases.

For the calculation, the first-principles calculation software VASP (The Vienna Ab initio simulation package) was used. Calculation conditions other than the conditions set as described above are shown in Table 2. In the above first-principles molecular dynamics calculation, the calculation conditions are set to Conditions 1 shown in Table 2.

TABLE 2

| | Conditions 1 | Conditions 2 | Conditions 3 |
|---|---|---|---|
| Software | VASP | | |
| Basis function | Plane wave | | |
| Functional | GGA/PBE | | |
| Pseudopotential | PAW | | |
| The number of electrons | Neutral | | |
| Pseudopotential of oxygen | O_s | O | O |
| Cut-off energy | 280 eV | 400 eV | 400 eV |
| k-point grid | Γ-point only | Γ-point only | 2 × 2 × 2 |

As a pseudopotential of electronic states, a potential generated by a Projector Augmented Wave (PAW) method was used, and as a functional, GGA/PBE (Generalized-Gradient-Approximation/Perdew-Burke-Ernzerhof) was used.

Note that in the first-principles molecular dynamics calculation and later-described calculation for optimizing the structure of the calculation model (also referred to as optimization calculation), which are performed in this embodiment, the 3d state or the 4d state is not considered as a valence band for the potentials of In, Ga, and Zn. The lattice vector (the length of an axis and the angle between axes) of the calculation model is fixed. In other words, the first-principles molecular dynamics calculation is performed under conditions where the number of particles (N), volume (V), and temperature (T) are constant (NVT ensemble). In addition, in the first-principles molecular dynamics calculation, a Nose-Hoover thermostat is used as a method for controlling the temperature.

Next, calculation for cooling the melted peripheral portion to a temperature of 500 K is performed. Note that the cooling rate is 500 K/ps. Specifically, first, the coordinates of the atoms positioned in the crystal region are fixed, and the time step is set to 1 fs, the number of steps is set to 1000, and other calculation conditions are set to Conditions 1 shown in Table 2. Then, first-principles molecular dynamics calculation is performed, with the temperature set to 3500 K, on the calculation model obtained by the above calculation for melting the peripheral portion. Next, on the calculation model obtained following the calculation, first-principles molecular dynamics calculation is performed with the temperature set to 3000 K. Subsequently, on the calculation model obtained following the calculation, first-principles molecular dynamics calculation is performed with the temperature set to 2500 K. Then, on the calculation model obtained following the calculation, first-principles molecular dynamics calculation is performed with the temperature set to 2000 K. Next, on the calculation model obtained following the calculation, first-principles molecular dynamics calculation is performed with the temperature set to 1500 K. Subsequently, on the calculation model obtained following the calculation, first-principles molecular dynamics calculation is performed with the temperature set to 1000 K. Then, on the calculation model obtained following the calculation, first-principles molecular dynamics calculation is performed with the temperature set to 500 K. Through the above steps, the calculation for cooling the peripheral portion is completed.

Next, calculation for relaxation of the structure of the cooled peripheral portion is performed. Specifically, on the calculation model obtained by the calculation for cooling the peripheral portion, first-principles molecular dynamics calculation is performed with the coordinates of the atoms positioned in the crystal region fixed, the temperature set to 300 K, the time step set to 1 fs, the number of steps set to 5000, and other calculation conditions set to Conditions 1 shown in Table 2.

Then, the calculation conditions are set to Conditions 2 shown in Table 2, and on the calculation model obtained by the calculation for relaxation of the structure of the peripheral portion, calculation for optimizing the structure of the peripheral portion is performed with the coordinates of the atoms positioned in the crystal region fixed. Subsequently, on the calculation model obtained following the calculation, calculation for optimizing the structure of the crystal region is performed with the coordinates of the atoms positioned in the peripheral portion and the coordinates of one In atom at the center of the crystal region fixed. Then, on the calculation model obtained following the calculation, calculation for optimizing the structure of the entire calculation model (the crystal region and peripheral portion) is performed with the coordinates of only the In atom fixed. After that, the calculation conditions are set to Conditions 3 shown in Table 2, and on the calculation model obtained following the calculation, calculation for optimizing the structure of the entire calculation model is performed with the coordinates of only the In atom fixed.

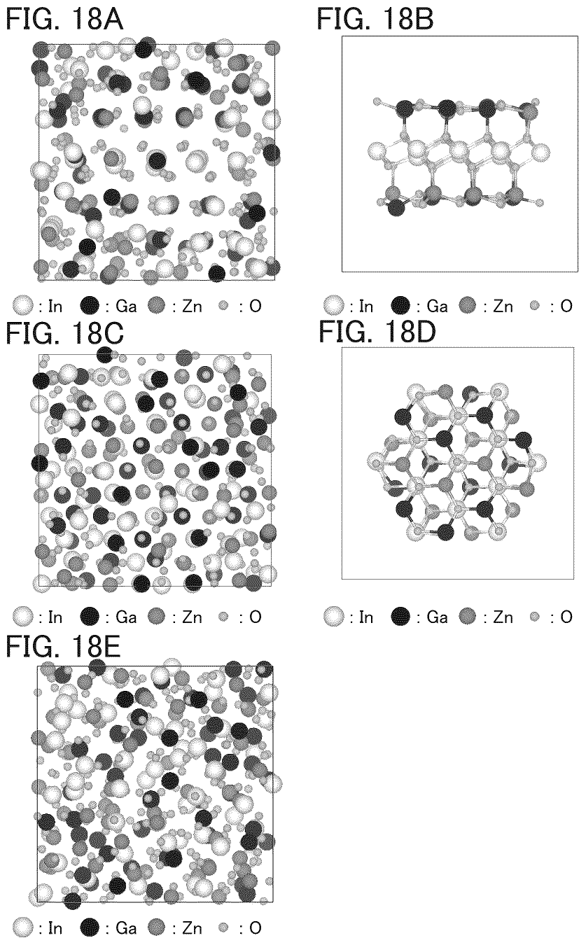

By the above method, Calculation Model 1A is created. The created Calculation Model 1A is shown in FIG. 18A to FIG. 18D. FIG. 18A and FIG. 18C show overall views of Calculation Model 1A. FIG. 18B and FIG. 18D show the crystal region of Calculation Model 1A. FIG. 18A and FIG. 18B are diagrams when the hexagonal-prism-shaped region is seen from a side surface thereof, whereas FIG. 18C and FIG. 18D are diagrams when the hexagonal-prism-shaped region is seen from a top surface thereof.

### Creating Method of Calculation Model 2A

A creating method of Calculation Model 2A is described below. Note that calculation for creating Calculation Model 2A adopts the calculation conditions shown in Table 2.

First, calculation for melting the crystal region and the peripheral portion of Calculation Model 1A is performed. Specifically, Calculation Model 1A is prepared, and first-principles molecular dynamics calculation is performed with the coordinates of all the atoms not fixed, the temperature set to 3500 K, the time step set to 1 fs, the number of steps set to 6000, and other calculation conditions set to Conditions 1 shown in Table 2.

Next, calculation for cooling the entire melted calculation model to a temperature of 500 K is performed. Note that the cooling rate is 500 K/ps. Specifically, first, the time step is set to 1 fs, the number of steps is set to 1000, and other calculation conditions are set to Conditions 1 shown in Table 2 while the coordinates of all the atoms are not fixed. Then, first-principles molecular dynamics calculation is performed, with the temperature set to 3500 K, on the calculation model obtained by the calculation for melting the crystal region and the peripheral portion. Next, on the calculation model obtained following the calculation, first-principles molecular dynamics calculation is performed with the temperature set to 3000 K. Subsequently, on the calculation model obtained following the calculation, first-principles molecular dynamics calculation is performed with the temperature set to 2500 K. Then, on the calculation model obtained following the calculation, first-principles molecular dynamics calculation is performed with the temperature set to 2000 K. Next, on the calculation model obtained following the calculation, first-principles molecular dynamics calculation is performed with the temperature set to 1500 K. Subsequently, on the calculation model obtained following the calculation, first-principles molecular dynamics calculation is performed with the temperature set to 1000 K. Then, on the calculation model obtained following the calculation, first-principles molecular dynamics calculation is performed with the temperature set to 500 K. Through the above steps, the calculation for cooling the entire calculation model is completed.

Next, calculation for relaxation of the structure of the entire cooled calculation model is performed. Specifically, on the calculation model obtained by the calculation for cooling the entire calculation model, first-principles molecular dynamics calculation is performed with the coordinates of all the atoms not fixed, the temperature set to 300 K, the time step set to 1 fs, the number of steps set to 5000, and other calculation conditions set to Conditions 1 shown in Table 2.

Then, the calculation conditions are set to Conditions 2 shown in Table 2, and on the calculation model obtained by the calculation for relaxation of the entire calculation model, calculation for optimizing the structure of the entire calculation model is performed with the coordinates of all the atoms not fixed. After that, the calculation conditions are set to Conditions 3 shown in Table 2, and on the calculation model obtained following the calculation, calculation for optimizing the structure of the entire calculation model is performed with the coordinates of all the atoms not fixed.

By the above method, Calculation Model 2A is created. FIG. 18E shows an overall view of Calculation Model 2A.

The total energies of Calculation Model 1A and Calculation Model 2A created by the above methods were calculated and compared. Specifically, the calculation conditions are set to

Conditions 3 shown in Table 2, and single point calculation is performed on Calculation Model 1A with the coordinates of only one In atom at the center of the crystal region fixed, whereas single point calculation is performed on Calculation Model 2A with the coordinates of all the atoms not fixed. The total energies calculated through the calculation are compared.

The results of the above calculation showed that the total energy value of Calculation Model 1A was smaller than the total energy value of Calculation Model 2A by, specifically, 6.83 eV. It is thus found that Calculation Model 1A including the crystal region is more stable than Calculation Model 2A including no crystal region. That is, it is suggested that the nc film is stabilized by including the crystal region.

Then, Calculation Model 3A for comparison with Calculation Model 1A is prepared. Note that the structure of Calculation Model 3A is a single crystal structure.

First, a calculation model is prepared which has an InGaZnO4 single crystal structure (space group: R-3m), an atomic ratio In:Ga:Zn:O=1:1:1:4, and a density of 6.36 g/cm³ and includes 112 atoms. Then, the k-point grid is set to 2×2×3, other calculation conditions are set to Conditions 3 shown in Table 2, and calculation for optimizing the coordinates of the atoms of the calculation model is performed. Through the above steps, Calculation Model 3A is created.

The total energy of Calculation Model 3A created by the above method is calculated. Specifically, the k-point grid is set to 2×2×3, other calculation conditions are set to Conditions 3 shown in Table 2, and single point calculation is performed. The value which is obtained by multiplying the total energy calculated by the calculation by 3.375 (=378/112) is the total energy value of the calculation model of the single crystal structure.

The results of the above calculation showed that the total energy value of the calculation model of the single crystal structure was smaller than the total energy value of Calculation Model 1A by, specifically, 54.88 eV. That is, it is found that improvement of the crystallinity in the film makes the film energetically stable.

It is suggested that the existence of the crystal region contributes to stabilization of the nc film since Calculation Model 1A is more stable than Calculation Model 2A although having higher energy than the calculation model of the single crystal structure, as described above.

The above is the description of the stability of the nc film.

### Thermal Stability of nc Film

In this section, thermal stability of an nc film is described with results of first-principles calculation. Note that thermal stability of an nc film is evaluated using internal energy which will be described later.

Here, internal energy is described. In this specification, internal energy U is calculated using the following formula.

$$[ Formula 2 ]$$

$$U = {\sum }_{I} \frac{1}{2} {M}_{I} {v}_{I}^{2} + {\sum }_{I} {\sum }_{J > I} \frac{{Z}_{I} {Z}_{J}}{{r}_{IJ}} + 〈 Ψ \vert {\sum }_{i} ( - \frac{{ℏ}^{2}}{2 m} {∇}_{i}^{2} ) +$$

$${\sum }_{i} {\sum }_{j > i} \frac{{e}^{2}}{{r}_{ij}} \vert Ψ 〉 + 〈 Ψ \vert {\sum }_{i} {\sum }_{I} \frac{{eZ}_{I}}{{r}_{iI}} \vert Ψ 〉$$

Here, M_{I} is the mass of the I-th (I is a natural number) atomic nucleus and m is the mass of an electron. Furthermore, vi is the speed of the I-th atomic nucleus. In other words, the first term of the right side of the above formula denotes the kinetic energy of the atomic nucleus, and the third term of the right side of the above formula denotes the kinetic energy of an electron.

Furthermore, Z_{I} is an electric charge of the I-th atomic nucleus, and e is an electric charge of an electron. In addition, r_{IJ} is the distance between the I-th atomic nucleus and the J-th (J is an integer larger than I) atomic nucleus, and rᵢⱼ is the distance between the i-th (i is a natural number) electron and the j-th (j is an integer larger than i) electron. In other words, the second term of the right side of the above formula is potential energy involved in interaction between the atomic nuclei; the fourth term of the right side of the above formula is potential energy involved in interaction between the electrons; and the fifth term of the right side of the above formula is potential energy involved in interaction between the atomic nucleus and the electron.

From the above, the internal energy U is calculated as the sum of kinetic energies and potential energies.

Note that the stability of a phase in an equilibrium state or the like is described with Hermholtz free energy F. Here, the Hermholtz free energy F is a value obtained by subtracting a product of a temperature T and an entropy S from the internal energy U (F=U−TS). However, since it is difficult to evaluate the entropy S, the internal energy U is used to study thermodynamic phase stability in this specification.

The above is the description of the internal energy. Next, a specific method for evaluating the thermal stability of an nc film is described.

On each of Calculation Model 1A and Calculation Model 2A described above, first-principles molecular dynamics calculation is performed with the temperature set to 300 K, 673 K, 1000 K, 1500 K, or 2000 K. Note that in the case of using Calculation Model 1A, the first-principles molecular dynamics calculation is performed with the coordinates of one In atom at the center of the crystal region fixed. In the case of using Calculation Model 2A, the first-principles molecular dynamics calculation is performed with the coordinates of all the atoms not fixed. In the first-principles molecular dynamics calculation, the time step is set to 1 fs, the number of steps is set to 10000, and other calculation conditions are set to Conditions 2 shown in Table 2.

Then, internal energy is calculated for the calculation models (10 kinds in total) after the first-principles molecular dynamics calculation is performed on each of Calculation Model 1A and

Calculation Model 2A above at each temperature. Specifically, the average value of internal energy from the 9001st step to 10000th step is calculated. Note that the average value of internal energy when the average value of internal energy that is obtained by performing first-principles molecular dynamics calculation on Calculation Model 1A with the temperature set to 300 K is the reference (0.0 eV) is referred to as average energy.

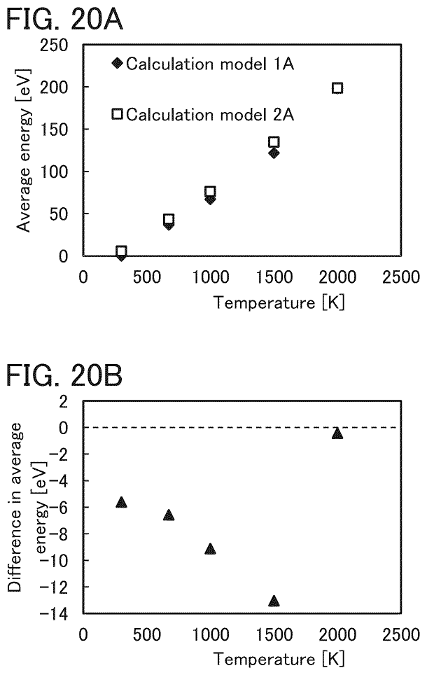

FIG. 20A shows the relationship between the temperature and the average energy calculated by the above-described method. In FIG. 20A, the horizontal axis represents the temperature [K] and the vertical axis represents the average energy [eV]. In FIG. 20A, the average energy in the case of using Calculation Model 1A is plotted as black rhombi and that in the case of using Calculation Model 2A is plotted as white squares.

Next, on each of the calculation models (five kinds in total) which are obtained by performing the first-principles molecular dynamics calculation on Calculation Model 1A at each temperature, calculation for optimizing the structure of the calculation model is performed with the calculation conditions set to Conditions 2 shown in Table 2. Note that the optimization calculation is performed with the coordinates of one In atom at the center of the crystal region fixed. Then, on each of the calculation models (five kinds in total) obtained by the optimization calculation, calculation for optimizing the structure of the calculation model is performed with the calculation conditions set to Conditions 3 shown in Table 2.

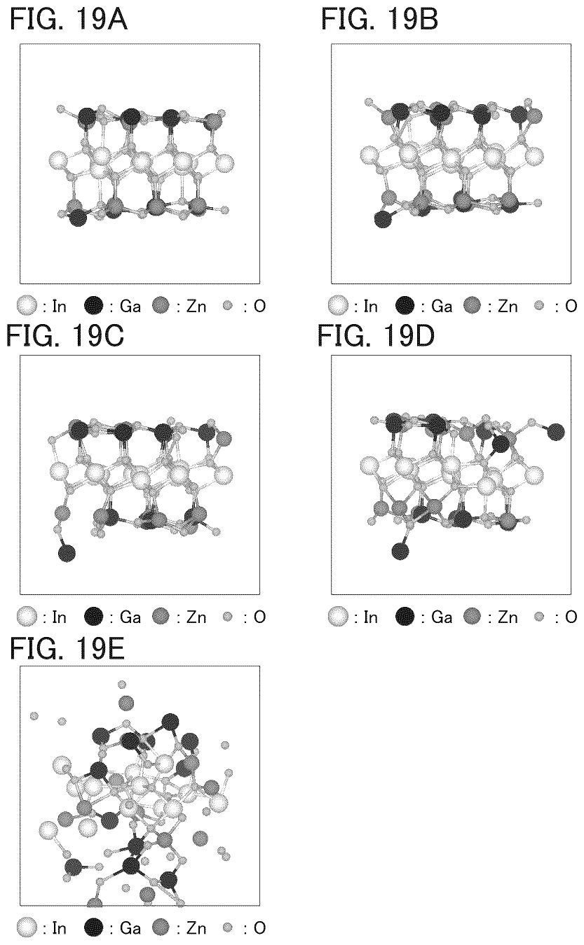

FIG. 19A to FIG. 19E show part of the calculation models (five kinds in total) obtained by the above calculation. Note that FIG. 19A to FIG. 19E show arrangement of 87 atoms of the calculation model which are placed in the crystal region before placement of atoms in the peripheral portion of the crystal region. FIG. 19A is a calculation model obtained by performing the first-principles molecular dynamics calculation with the temperature set to 300 K and the optimization calculation; FIG. 19B, a calculation model obtained by performing the first-principles molecular dynamics calculation with the temperature set to 673 K and the optimization calculation; FIG. 19C, a calculation model obtained by performing the first-principles molecular dynamics calculation with the temperature set to 1000 K and the optimization calculation; FIG. 19D, a calculation model obtained by performing the first-principles molecular dynamics calculation with the temperature set to 1500 K and the optimization calculation; and FIG. 19E, a calculation model obtained by performing the first-principles molecular dynamics calculation with the temperature set to 2000 K and the optimization calculation.

As can be seen from FIG. 19A to FIG. 19D, in the calculation models obtained by performing the first-principles molecular dynamics calculation with the temperature set to 1500 K or less and the optimization calculation, the lattice arrangement of the crystal region is maintained. As can be seen from FIG. 19E, in the calculation model obtained by performing the first-principles molecular dynamics calculation with the temperature set to 2000 K and the optimization calculation, the crystal structure collapses. As can be seen from FIG. 19D, in the calculation model obtained by performing the first-principles molecular dynamics calculation with the temperature set to 1500 K and the optimization calculation, the lattice arrangement of the crystal region is maintained but the atomic arrangement is more disordered than in the calculation model obtained by performing the first-principles molecular dynamics calculation with the temperature set to 1000 K and the optimization calculation, showing signs that the crystal structure starts to collapse.

Here, the difference between the average energy of Calculation Model 1A and that of Calculation Model 2A at each temperature is calculated to compare the thermal stability of Calculation Model 1A and that of Calculation Model 2A. Note that the relationship between the temperature and the average energies of Calculation Model 1A and Calculation Model 2A is as shown in FIG. 20A.

FIG. 20B shows the relationship between the temperature and the value (also referred to as the difference in average energy) obtained by subtracting the average energy of Calculation Model 2A from the average energy of Calculation Model 1A. In FIG. 20B, the horizontal axis represents the temperature [K] and the vertical axis represents the difference in average energy [eV].

FIG. 20B shows that in the case where the temperature is set to 2000 K, the difference in average energy is close to 0 and the average energy in the case of using Calculation Model 1A is substantially equal to that in the case of using Calculation Model 2A. In contrast, it is shown that in the case where the temperature is set to 1500 K or less, the difference in average energy has a negative value and the average energy in the case of using Calculation Model 1A is lower than the average energy in the case of using Calculation Model 2A at any of the temperatures. That is, it is presumed that at the temperature at which the lattice arrangement of the crystal region is maintained, the calculation model including the crystal region is more thermally stable than the calculation model including no crystal region. It is thus suggested that except in a high temperature range, the existence of the crystal region increases the thermal stability of the film.

The above is the description of the thermal stability of the nc film.

### Ease of Formation of H_{O} in nc Film

In this section, ease of formation of defects in an nc film is described with results of first-principles calculation. Specifically, formation energy of a defect in which hydrogen enters an oxygen vacancy (hereinafter sometimes referred to as V_{O}H or H_{O}) is calculated by first-principles calculation.

H_{O} generates an electron serving as a carrier in some cases. Thus, when H_{O} is formed in a channel formation region of an oxide semiconductor, the transistor easily has normally-on characteristics, for example, which means a variation in the electrical characteristics of a transistor. Thus, it is preferable to inhibit formation of H_{O} in a channel formation region of an oxide semiconductor.

Here, formation energy of a defect is described. In this specification, formation energy of a defect is calculated using the following formula. A defect whose formation energy is lower can be regarded as being formed more easily.

$$[ Formula 3 ]$$

$${E}_{form} ( defect ) = E ( defect ) - \{ E ( no defect ) + {\sum }_{X} {n}_{X} μ ( X ) \}$$

Here, E_{form} (defect) is the formation energy of a defect, E (defect) is the total energy of a calculation model including one defect, E (no defect) is the total energy of a calculation model with no defect, an atom X is an atom the number of which has increased or decreased owing to formation of a defect, μ(X) is the chemical potential of the atom X, and n_{X} is the increment or decrement of the atom X. For example, in the case where the defect is H_{O}, X is an oxygen atom (O) or a hydrogen atom (H), n_{O} is −1, and n_{H} is +1.

The chemical potential μ(O) of an oxygen atom and the chemical potential μ(H) of a hydrogen atom are calculated using the following formula.

$$[ Formula 4 ]$$

$$\begin{matrix}μ ( O ) = E ( {O}_{2} ) / 2 \\ μ ( H ) = E ( {H}_{2} O ) / 2 - E ( {O}_{2} ) / 4\end{matrix}$$

Here, E(O₂) is the total energy of an oxygen molecule (O₂) and E(H₂O) is the total energy of a water molecule (H₂O).

Note that E(O₂) is calculated in the following manner: one O₂ molecule is placed in a 1-nm³ lattice, calculation for optimizing the structure of the O₂ molecule is performed with the calculation conditions set to Conditions 2 shown in Table 2, and then, on the calculation model obtained following the calculation, single point calculation is performed. Furthermore, E(H₂O) is calculated in the following manner: one H₂O molecule is placed in a 1-nm³ lattice, calculation for optimizing the structure of the H₂O molecule is performed with the calculation conditions set to Conditions 2 shown in Table 2, and then, on the calculation model obtained following the calculation, single point calculation is performed.

The above is the description of the formation energy of a defect.

To calculate the formation energy of a defect, Calculation Model 3A was prepared. A creating method of Calculation Model 3A is described below. Note that calculation for creating Calculation Model 3A adopts the calculation conditions shown in Table 2.

First, Calculation Model 1A is prepared and calculation for relaxation of the structure of the peripheral portion of Calculation Model 1A is performed. Specifically, Calculation Model 1A is prepared, and first-principles molecular dynamics calculation is performed with the coordinates of the atoms positioned in the crystal region fixed, the temperature set to 1000 K, the time step set to 1 fs, the number of steps set to 10000, and other calculation conditions set to Conditions 2 shown in Table 2.

Then, while the calculation conditions set to Conditions 2 shown in Table 2 are maintained, on the calculation model obtained by the calculation for relaxation of the structure of the peripheral portion, calculation for optimizing the structure of the peripheral portion is performed with the coordinates of the atoms positioned in the crystal region fixed. Subsequently, on the calculation model obtained following the calculation, calculation for optimizing the structure of the crystal region is performed with the coordinates of the atoms positioned in the peripheral portion and the coordinates of one In atom at the center of the crystal region fixed. Then, on the calculation model obtained following the calculation, calculation for optimizing the structure of the entire calculation model is performed with the coordinates of the one In atom at the center of the crystal region fixed. After that, the calculation conditions are set to Conditions 3 shown in Table 2, and on the calculation model obtained following the calculation, calculation for optimizing the structure of the entire calculation model is performed with the coordinates of the one In atom at the center of the crystal region fixed.

By the above method, Calculation Model 3A is created.

With the use of Calculation Model 3A created by the above method, the formation energy of H_{O} is calculated. Specifically, one oxygen atom in Calculation Model 3A is replaced with one hydrogen atom, so that a calculation model including one H_{O} is prepared. Note that the number of oxygen atoms in Calculation Model 3A is 216 and thus, 216 calculation models each including one H_{O} are prepared. Note that a calculation model including no H_{O} is Calculation Model 3A itself.

On each of the calculation models including one H_{O} and the calculation model including no H_{O}, calculation for optimizing the structure of the entire calculation model is performed with the calculation conditions set to Conditions 3 shown in Table 2. The total energy of the calculation model including one H_{O} which is obtained following the calculation is E(defect), whereas the total energy of the calculation model including no H_{O} which is obtained following the calculation is E(no defect). Note that performing the calculation on the calculation model including one H_{O} sometimes changes the H_{O} into a different defect (e.g., an oxygen vacancy and hydrogen).

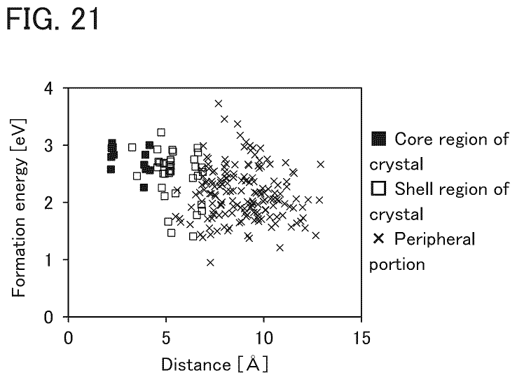

With the use of E(defect) and E(no defect) calculated by the above method, the formation energy of H_{O} is calculated. The calculated formation energy of H_{O} is shown in FIG. 21. In FIG. 21, the horizontal axis represents the distance [A] from the In atom at the center of the crystal region to the H_{O} placed in the calculation model before the calculation for optimizing the structure of the entire calculation model is performed, whereas the vertical axis represents the formation energy [eV] of H_{O}. Note that in FIG. 21, the formation energy of H_{O} positioned in a region (also referred to as a core region of a crystal) near In in the crystal region is plotted as black squares (▪); the formation energy of H_{O} positioned in a region (also referred to as a shell region of a crystal) other than the core region in the crystal region is plotted as white squares (□); and the formation energy of H_{O} positioned in the peripheral portion is plotted as crosses (×). Note that the number of oxygen positioned in the core region of the crystal is 12, and the number of oxygen positioned in the shell region of the crystal is 38.

The average value of formation energy of the H_{O} positioned in the core region of the crystal, that of the H_{O} positioned in the shell region of the crystal, and that of the H_{O} positioned in the peripheral portion are respectively 2.75 eV, 2.60 eV, and 2.14 eV.

As can be seen from FIG. 21, a variation in the formation energy of H_{O} was larger and some H_{O}'s had smaller H_{O} formation energy values in the shell region of the crystal than in the core region of the crystal. This is presumably because the structure is distorted in a region of the crystal region which is close to the interface between the crystal region and the peripheral portion.

It is also shown that the variation in the formation energy of H_{O} is larger and more H_{O}'s have smaller H_{O} formation energy values in the peripheral portion than in the crystal region (the core region of the crystal and the shell region of the crystal). This is presumably because fluctuation in bond length is greater and more oxygen atoms have weakened bonding strength with a metal atom in the peripheral portion having low crystallinity than in the crystal region.

The above suggests that H_{O} is not easily formed in the crystal region and H_{O} is easily formed in the region having low crystallinity (the above peripheral portion). Accordingly, the existence of the crystal region inhibits formation of H_{O}. Therefore, the use of an nc film for a transistor can inhibit a variation in the electrical characteristics of the transistor.

The above is the description of ease of formation of H_{O} in an nc film.

### Structure of Metal Oxide

Oxide semiconductors (metal oxides) can be classified into a single crystal oxide semiconductor and a non-single-crystal oxide semiconductor. Examples of a non-single-crystal oxide semiconductor include a CAAC-OS (c-axis aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that it is difficult to observe a clear crystal grain boundary (also referred to as grain boundary) even in the vicinity of distortion in the CAAC-OS. That is, formation of a crystal grain boundary is found to be inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like. Note that a crystal structure in which a clear grain boundary is observed is what is called polycrystal. It is highly probable that the grain boundary becomes a recombination center and traps carriers and thus decreases the on-state current and field-effect mobility of a transistor. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary more than an In oxide.

The CAAC-OS tends to have a layered crystal structure (also referred to as a layered structure) in which a layer containing indium and oxygen (hereinafter, an In layer) and a layer containing the element M, zinc, and oxygen (hereinafter, an (M,Zn) layer) are stacked. Note that indium and the element M can be replaced with each other, and when the element M in the (M,Zn) layer is replaced with indium, the layer can also be referred to as an (In,M,Zn) layer. Furthermore, when indium in the In layer is replaced with the element M, the layer can be referred to as an (In,M) layer.

The CAAC-OS is a metal oxide with high crystallinity. On the other hand, a clear crystal grain boundary cannot be observed in the CAAC-OS; thus, it can be said that a reduction in electron mobility due to the crystal grain boundary is less likely to occur. Entry of impurities, formation of defects, or the like might decrease the crystallinity of a metal oxide, which means that the CAAC-OS is a metal oxide having small amounts of impurities and defects (e.g., oxygen vacancies). Thus, a metal oxide including a CAAC-OS is physically stable. Therefore, the metal oxide including a CAAC-OS is resistant to heat and has high reliability.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

Note that an In—Ga—Zn oxide (hereinafter, IGZO) that is a kind of metal oxide containing indium, gallium, and zinc has a stable structure in some cases by being formed of the above-described nanocrystals. In particular, crystals of IGZO tend not to grow in the air and thus, a stable structure is obtained when IGZO is formed of smaller crystals (e.g., the above-described nanocrystals) rather than larger crystals (here, crystals with a size of several millimeters or several centimeters).

An a-like OS is a metal oxide having a structure between those of the nc-OS and an amorphous oxide semiconductor. The a-like OS includes a void or a low-density region. That is, the a-like OS has low crystallinity as compared with the nc-OS and the CAAC-OS.

An oxide semiconductor (metal oxide) can have various structures which show different properties. Two or more of the amorphous oxide semiconductor, the polycrystalline oxide semiconductor, the a-like OS, the nc-OS, and the CAAC-OS may be included in an oxide semiconductor of one embodiment of the present invention.

As a non-single-crystal oxide semiconductor, a CAC (Cloud-Aligned Composite)-OS may be used. Note that the CAC-OS relates to the material composition.

### Structure of Metal Oxide

A CAC-OS has a conducting function in part of the material and has an insulating function in another part of the material; as a whole, the CAC-OS has a function of a semiconductor. Note that in the case where the CAC-OS is used in an active layer of a transistor, the conducting function is a function that allows electrons (or holes) serving as carriers to flow, and the insulating function is a function that does not allow electrons serving as carriers to flow. By the complementary action of the conducting function and the insulating function, a switching function (On/Off function) can be given to the CAC-OS. In the CAC-OS, separation of the functions can maximize both of the functions.

In addition, the CAC-OS includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. Furthermore, in some cases, the conductive regions are observed to be coupled in a cloud-like manner with their boundaries blurred.

In the CAC-OS, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

The CAC-OS is composed of components having different band gaps. For example, the CAC-OS is composed of a component having a wide gap due to the insulating region and a component having a narrow gap due to the conductive region. In the case of the structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS is used in a channel formation region of a transistor, the transistor in the on state can achieve high current driving capability, that is, high on-state current and high field-effect mobility.

In other words, the CAC-OS can also be referred to as a matrix composite or a metal matrix composite.

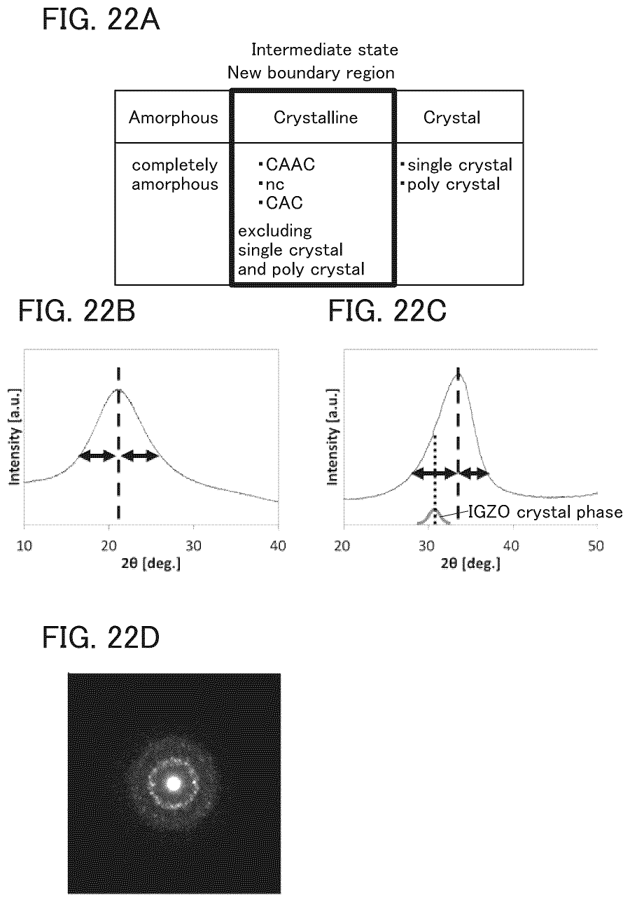

Oxide semiconductors might be classified in a manner different from the above-described one when classified in terms of the crystal structure. Here, the classification of the crystal structures of an oxide semiconductor is explained with FIG. 22A. FIG. 22A is a diagram showing the classification of crystal structures of an oxide semiconductor, typically IGZO (a metal oxide containing In, Ga, and Zn).

As shown in FIG. 22A, IGZO is roughly classified into “Amorphous”, “Crystalline”, and “Crystal”. “Amorphous” includes “completely amorphous”. “Crystalline” includes “CAAC”, “nc”, and “CAC”. Note that “single crystal”, “poly crystal”, and “completely amorphous” are excluded from the category of “Crystalline”. “Crystal” includes “single crystal” and “poly crystal”.

Note that the structures in the thick frame in FIG. 22A are in an intermediate state between “Amorphous” and “Crystal”, and belong to a new boundary region (New crystalline phase). These structures are in a boundary region between “Amorphous” and “Crystal”. In other words, these structures can each be rephrased as a structure completely different from “Amorphous”, which is energetically unstable, and “Crystal”.

Note that a crystal structure of a film or a substrate can be evaluated with an X-ray diffraction (XRD) image. Here, XRD spectra of quartz glass and IGZO, which has a crystal structure classified into “Crystalline” (also referred to as Crystalline IGZO), are shown in FIG. 22B and FIG. 22C. FIG. 22B shows an XRD spectrum of quartz glass and FIG. 22C shows an XRD spectrum of crystalline IGZO. Note that the composition of the crystalline IGZO shown in FIG. 22C is in the neighborhood of In:Ga:Zn=4:2:3 [atomic ratio]. Furthermore, the crystalline IGZO shown in FIG. 22C has a thickness of 500 nm.

As indicated by arrows in FIG. 22B, the shape of the XRD spectrum peak of the quartz glass is substantially bilaterally symmetrical. In contrast, as indicated by arrows in FIG. 22C, the shape of the XRD spectrum peak of the crystalline IGZO is bilaterally asymmetrical. The bilaterally asymmetrical shape of the XRD spectrum peak clearly shows the existence of a crystal. In other words, the structure cannot be regarded as “Amorphous” unless the shape of the XRD spectrum peak is bilaterally symmetrical. Note that in FIG. 22C, a crystal phase (IGZO crystal phase) is explicitly denoted at 2θ of 31° or around 31°. The bilaterally asymmetric shape of the XRD spectrum peak is presumably attributed to the crystal phase (microcrystal).

Specifically, there is a peak at 2θ of 34° or around 34° in the XRD spectrum of the crystalline IGZO shown in FIG. 22C. Furthermore, the microcrystal exhibits a peak at 2θ of 31° or around 31°. In the case of evaluating an oxide semiconductor film with the use of an X-ray diffraction image, as shown in FIG. 22C, the width of the spectrum is large on a smaller angle side than the peak at 2θ of 34° or around 34°. This suggests that the oxide semiconductor film includes a microcrystal exhibiting a peak at 2θ of 31° or around 31°.

A crystal structure of a film can be evaluated with a diffraction pattern observed by a nanobeam electron diffraction (NBED) method (such a pattern is also referred to as a nanobeam electron diffraction pattern). FIG. 22D shows a diffraction pattern of an IGZO film deposited with the substrate temperature set to room temperature. Note that the IGZO film shown in FIG. 22D is deposited by a sputtering method using an oxide target of In:Ga:Zn=1:1:1 [atomic ratio].

In the nanobeam electron diffraction method, electron diffraction was performed with a probe diameter of 1 nm.

As shown in FIG. 22D, not a halo but a spot-like pattern is observed in the diffraction pattern of the IGZO film deposited at room temperature. Thus, it is presumed that the IGZO film deposited at room temperature is in an intermediate state, which is neither a crystal state nor an amorphous state, and the IGZO film cannot be concluded to be in an amorphous state.

At least part of this embodiment can be implemented in combination with the other embodiments described in this specification as appropriate.

### Embodiment 2

In this embodiment, a structure example of a semiconductor device using a metal oxide film of one embodiment of the present invention will be described. A transistor will be described below as an example.

### Structure Example 1

### Structure Example 1-1

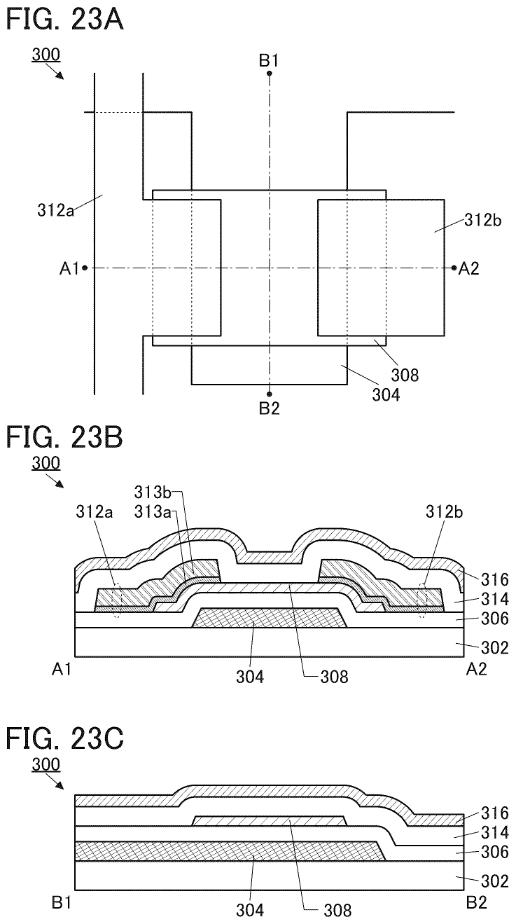

FIG. 23A is a top view of a transistor 300, FIG. 23B corresponds to a cross-sectional view of a cut plane taken along a dashed-dotted line A1-A2 in FIG. 23A, and FIG. 23C corresponds to a cross-sectional view of a cut plane taken along a dashed-dotted line B1-B2 in FIG. 23A. The direction of the dashed-dotted line A1-A2 corresponds to a channel length direction, and the direction of the dashed-dotted line B1-B2 corresponds to a channel width direction. Note that in FIG. 23A, some components of the transistor 300 (a gate insulating layer and the like) are not illustrated. Furthermore, some components are not illustrated in top views of transistors in the following drawings, as in FIG. 23A.

The transistor 300 is provided over a substrate 302 and includes a conductive layer 304, an insulating layer 306, a semiconductor layer 308, a conductive layer 312a, a conductive layer 312b, and the like. The insulating layer 306 is provided to cover the conductive layer 304. The semiconductor layer 308 has an island-like shape and is provided over the insulating layer 306. The conductive layer 312a and the conductive layer 312b are each in contact with a top surface of the semiconductor layer 308 and are apart from each other over the semiconductor layer 308. In addition, an insulating layer 314 is provided to cover the insulating layer 306, the conductive layer 312a, the conductive layer 312b, and the semiconductor layer 308, and an insulating layer 316 is provided over the insulating layer 314.

The metal oxide film described in Embodiment 1 can be used for the semiconductor layer 308.

Although there is no particular limitation on a material and the like of the substrate 302, it is necessary that the substrate have heat resistance high enough to withstand at least heat treatment performed later. For example, a single crystal semiconductor substrate or a polycrystalline semiconductor substrate including silicon or silicon carbide as a material, a compound semiconductor substrate of silicon germanium or the like, an SOI substrate, a glass substrate, a ceramic substrate, a quartz substrate, a sapphire substrate, or the like may be used as the substrate 302. Alternatively, any of these substrates on which a semiconductor element is provided may be used as the substrate 302.

A flexible substrate may be used as the substrate 302 and the semiconductor device may be formed directly on the flexible substrate. A separation layer may be provided between the substrate 302 and the semiconductor device. The separation layer can be used when part or the whole of a semiconductor device completed thereover is separated from the substrate 302 and transferred onto another substrate. In that case, the semiconductor device can be transferred to even a substrate having low heat resistance or a flexible substrate.

The conductive layer 304 functions as a gate electrode. Part of the insulating layer 306 functions as a gate insulating layer. The conductive layer 312a functions as one of a source electrode and a drain electrode, and the conductive layer 312b functions as the other of the source electrode and the drain electrode. A region of the semiconductor layer 308 that overlaps with the conductive layer 304 functions as a channel formation region. The transistor 300 is what is called a bottom-gate transistor, in which the gate electrode is provided more on the formation surface side than the semiconductor layer 308. Here, a side of the semiconductor layer 308 opposite to the conductive layer 304 side is sometimes referred to as a back channel side. The transistor 300 has what is called a channel-etched structure in which no protection layer is provided between the back channel side of the semiconductor layer 308 and the source and drain electrodes.

The semiconductor layer 308 may have a stacked-layer structure of two or more layers. At this time, the semiconductor film included in the semiconductor layer 308 preferably contains a metal oxide. In the case where the semiconductor layer 308 has a two-layer structure, the semiconductor film positioned on the back channel side preferably has higher crystallinity than the semiconductor film positioned on the conductive layer 304 side. With this structure, the semiconductor layer 308 can be prevented from being partly etched and lost at the time of processing of the conductive layer 312a and the conductive layer 312b.

The semiconductor layer 308 preferably contains indium, M (M is one kind or a plurality of kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. It is particularly preferable that aluminum, gallium, yttrium, or tin may be used as the element M.

It is particularly preferable to use an oxide containing indium, gallium, and zinc for the semiconductor layer 308.

The conductive layer 312a and the conductive layer 312b each have a stacked-layer structure in which a conductive layer 313a and a conductive layer 313b are stacked in this order from the formation surface side.

The conductive layer 313b is preferably formed using a low-resistance conductive material containing copper, silver, gold, aluminum, or the like. It is particularly preferable that the conductive layer 313b contain copper or aluminum. In that case, the conductive layer 312a and the conductive layer 312b can have extremely low resistance.

For the conductive layer 313a, a conductive material different from that for the conductive layer 313b can be used. For example, for the conductive layer 313a, a conductive material containing titanium, tungsten, molybdenum, chromium, tantalum, zinc, indium, platinum, ruthenium, or the like is preferably used.

When the conductive layer 313a is provided between the conductive layer 313b containing copper, aluminum, or the like and the semiconductor layer 308 as described above, the metal element contained in the conductive layer 313b can be prevented from diffusing into the semiconductor layer 308; thus, the transistor 300 can have high reliability. The conductive layer 313a preferably functions as a barrier layer that prevents diffusion of oxygen in the semiconductor layer 308 to the conductive layer 313b.

Note that the structures of the conductive layer 312a and the conductive layer 312b are not limited to a two-layer structure and may be a three-layer structure or a four-layer structure including a conductive layer containing copper, silver, gold, or aluminum. For example, for the conductive layer 312a and the conductive layer 312b, a three-layer structure in which a conductive layer containing the same conductive material as the conductive layer 313a is stacked over the conductive layer 313b may be employed. Accordingly, oxidation of a top surface of the conductive layer 313b can be prevented and the metal element contained in the conductive layer 313b can be prevented from scattering into the surrounding, whereby a highly reliable transistor can be achieved.

For the conductive layer 304, any of the above conductive materials that can be used for the conductive layer 313a or the conductive layer 313b can be used as appropriate. The use of a conductive material containing copper is particularly preferable.

For the insulating layer 306 and the insulating layer 314 that are in contact with the semiconductor layer 308, an insulating material containing an oxide is preferably used. In the case where the insulating layer 306 or the insulating layer 314 has a stacked-layer structure, an insulating material containing an oxide is used for a layer in contact with the semiconductor layer 308.

For the insulating layer 306, a nitride insulating film of silicon nitride, aluminum nitride, or the like may be used. In the case where an insulating material containing no oxide is used, treatment of adding oxygen to an upper portion of the insulating layer 306 is preferably performed to form an oxygen-containing region. Examples of the treatment of adding oxygen include heat treatment or plasma treatment in an oxygen-containing atmosphere, and an ion doping treatment.

The insulating layer 316 functions as a protection layer protecting the transistor 300. For the insulating layer 316, an inorganic insulating material such as silicon nitride, silicon nitride oxide, silicon oxide, silicon oxynitride, aluminum oxide, or aluminum nitride can be used. It is particularly preferable that a material less likely to diffuse oxygen, such as silicon nitride or aluminum oxide, be used for the insulating layer 316, in which case release of oxygen from the semiconductor layer 308 or the insulating layer 314 to the outside through the insulating layer 316 due to heat applied during the fabrication process or the like can be prevented.

For the insulating layer 316, an organic insulating material functioning as a planarization film may be used. Alternatively, a stacked-layer film that includes a film containing an inorganic insulating material and a film containing an organic insulating material may be used as the insulating layer 316.

In the semiconductor layer 308, a pair of low-resistance regions, which are positioned in portions in contact with the conductive layer 312a and the conductive layer 312b and in the vicinity thereof and function as a source region and a drain region, may be formed. The regions are part of the semiconductor layer 308 and have lower resistance than the channel formation region. The low-resistance regions can also be referred to as regions with high carrier concentration, n-type regions, or the like. In the semiconductor layer 308, a region that is sandwiched between the pair of low-resistance regions and overlaps with the conductive layer 304 functions as a channel formation region.

### Structure Example 1-2

A structure example of a transistor whose structure is partly different from that of Structure example 1-1 is described below. Note that description of the same portions as those in Structure example 1-1 is omitted below in some cases.

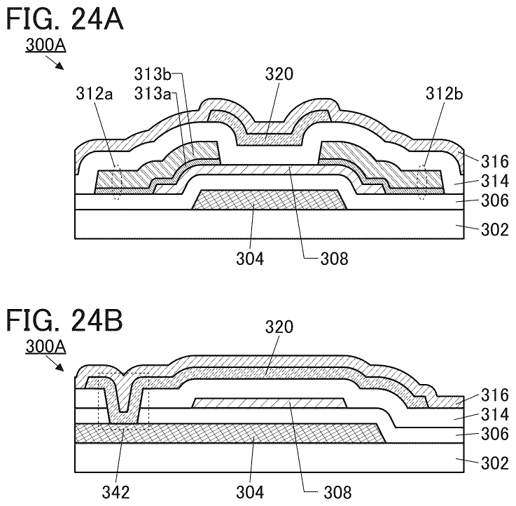

FIG. 24A is a cross-sectional view of a transistor 300A in the channel length direction and FIG. 24B is a cross-sectional view of the transistor in the channel width direction.

The transistor 300A is different from Structure example 1-1 mainly in that a conductive layer 320 is provided over the insulating layer 314.

The conductive layer 320 includes a region overlapping with the semiconductor layer 308 with the insulating layer 314 positioned therebetween.

In the transistor 300A, the conductive layer 304 has a function of a first gate electrode (also referred to as a bottom gate electrode), and the conductive layer 320 has a function of a second gate electrode (also referred to as a top gate electrode). Part of the insulating layer 314 functions as a second gate insulating layer.

As illustrated in FIG. 24B, the conductive layer 320 may be electrically connected to the conductive layer 304 through an opening 342 provided in the insulating layer 314 and the insulating layer 306. In this way, the same potential can be supplied to the conductive layer 320 and the conductive layer 304, which enables a transistor having high on-state current to be provided.

As illustrated in FIG. 24B, the conductive layer 304 and the conductive layer 320 preferably extend beyond the end portion of the semiconductor layer 308 in the channel width direction. In that case, as illustrated in FIG. 24B, the semiconductor layer 308 in the channel width direction is entirely covered with the conductive layer 304 and the conductive layer 320.

With such a structure, the semiconductor layer 308 can be electrically surrounded by electric fields generated by the pair of gate electrodes. In that case, it is particularly preferable that the same potential be supplied to the conductive layer 304 and the conductive layer 320. In that case, electric fields for inducing a channel can be effectively applied to the semiconductor layer 308, whereby the on-state current of the transistor 300A can be increased. Thus, the transistor 300A can also be miniaturized.

Note that a structure in which the conductive layer 304 and the conductive layer 320 are not connected to each other may be employed. In that case, a constant potential may be supplied to one of the pair of gate electrodes, and a signal for driving the transistor 300A may be supplied to the other. In this case, the potential supplied to one of the gate electrodes can control the threshold voltage at the time of driving the transistor 300A with the other gate electrode.

Alternatively, the conductive layer 320 may be electrically connected to any one of the conductive layer 312a and the conductive layer 312b. In particular, it is preferable to electrically connect the conductive layer 320 to either the conductive layer 312a or the conductive layer 312b, whichever is a conductive layer (e.g., the source electrode) supplied with a constant potential.

The above is the description of Structure example 1.

### Structure Example 2

A structure example of a transistor that is different from the above structure example 1 is described below.

### Structure Example 2-1

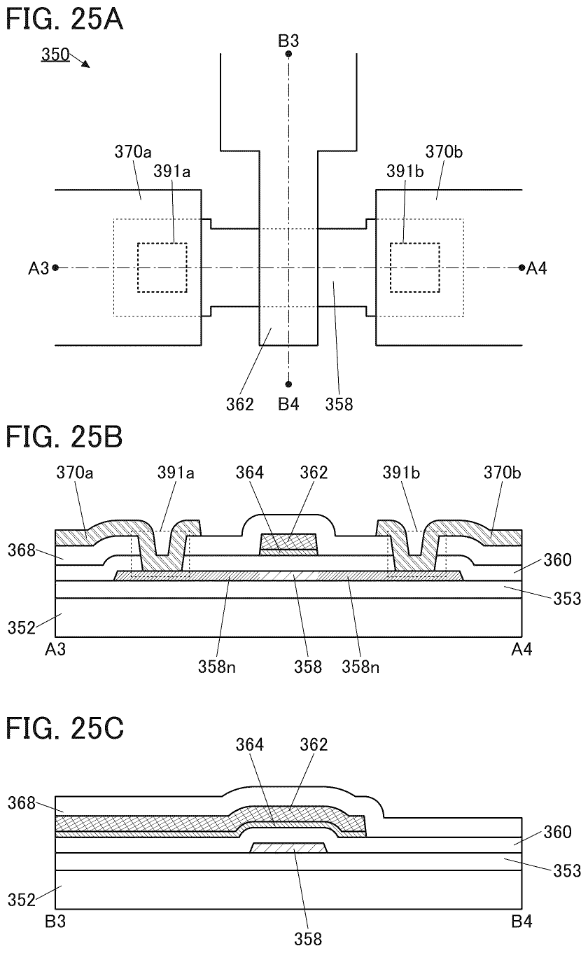

FIG. 25A is a top view of a transistor 350, FIG. 25B corresponds to a cross-sectional view of a cut plane along the dashed-dotted line A3-A4 shown in FIG. 25A, and FIG. 25C corresponds to a cross-sectional view of a cut plane along the dashed-dotted line B3-B4 shown in FIG. 25A. The direction of the dashed-dotted line A3-A4 corresponds to a channel length direction, and the direction of the dashed-dotted line B3-B4 corresponds to a channel width direction.

The transistor 350 is provided over a substrate 352 and includes an insulating layer 353, a semiconductor layer 358, an insulating layer 360, a metal oxide layer 364, a conductive layer 362, an insulating layer 368, and the like. The semiconductor layer 358 having an island shape is provided over the insulating layer 353. The insulating layer 360 is provided in contact with a top surface of the insulating layer 353 and a top surface and a side surface of the semiconductor layer 358. The metal oxide layer 364 and the conductive layer 362 are provided to be stacked in this order over the insulating layer 360 and each include a portion overlapping with the semiconductor layer 358. The insulating layer 368 is provided to cover a top surface of the insulating layer 360, a side surface of the metal oxide layer 364, and a top surface of the conductive layer 362.

The metal oxide film described in Embodiment 1 can be used for the semiconductor layer 358.

As illustrated in FIG. 25A and FIG. 25B, the transistor 350 may include a conductive layer 370a and a conductive layer 370b over the insulating layer 368. The conductive layer 370a and the conductive layer 370b function as a source electrode and a drain electrode. The conductive layer 370a and the conductive layer 370b are electrically connected to a low-resistance region 358n respectively through an opening 391a and an opening 391b formed in the insulating layer 368 and the insulating layer 360.

Part of the conductive layer 362 functions as a gate electrode. Part of the insulating layer 360 functions as a gate insulating layer. The transistor 350 is what is called a top-gate transistor, in which the gate electrode is provided over the semiconductor layer 358.

The conductive layer 362 and the metal oxide layer 364 are processed to have substantially the same top surface shapes.

Note that in this specification and the like, the expression “having substantially the same top surface shapes” means that at least outlines of stacked layers partly overlap with each other.

For example, the case of processing an upper layer and a lower layer with the use of the same mask pattern or mask patterns that are partly the same is included. However, in some cases, the outlines do not exactly overlap with each other and the outline of the upper layer is located on an inner side of the outline of the lower layer or the outline of the upper layer is located on an outer side of the outline of the lower layer; such a case is also represented by the expression “having substantially the same top surface shapes”.

The metal oxide layer 364 positioned between the insulating layer 360 and the conductive layer 362 functions as a barrier film that prevents diffusion of oxygen contained in the insulating layer 360 into a conductive layer 362 side. Furthermore, the metal oxide layer 364 also functions as a barrier film that prevents diffusion of hydrogen and water contained in the conductive layer 362 into an insulating layer 360 side. For the metal oxide layer 364, a material that is less likely to transmit oxygen and hydrogen than at least the insulating layer 360 can be used, for example.

Even in the case where a metal material that is likely to absorb oxygen, such as aluminum or copper, is used for the conductive layer 362, the metal oxide layer 364 can prevent diffusion of oxygen from the insulating layer 360 into the conductive layer 362. Furthermore, even in the case where the conductive layer 362 contains hydrogen, diffusion of hydrogen from the conductive layer 362 to the semiconductor layer 358 through the insulating layer 360 can be prevented. Consequently, carrier density of the semiconductor layer 358 in a channel formation region can be extremely low.

For the metal oxide layer 364, an insulating material or a conductive material can be used. When the metal oxide layer 364 has insulating properties, the metal oxide layer 364 functions as part of the gate insulating layer. By contrast, when the metal oxide layer 364 has conductivity, the metal oxide layer 364 functions as part of the gate electrode.

An insulating material having a higher permittivity than silicon oxide is preferably used for the metal oxide layer 364. It is particularly preferable to use an aluminum oxide film, a hafnium oxide film, a hafnium aluminate film, or the like because drive voltage can be reduced.

For the metal oxide layer 364, a conductive oxide such as indium oxide, indium tin oxide (ITO), or indium tin oxide containing silicon (ITSO) can also be used, for example. A conductive oxide containing indium is particularly preferable because of its high conductivity.

For the metal oxide layer 364, an oxide material containing one or more of the same elements as those of the semiconductor layer 358 is preferably used. It is particularly preferable to use an oxide semiconductor material that can be used for the semiconductor layer 358. Here, a metal oxide film formed using the same sputtering target as that for the semiconductor layer 358 is preferably applied to the metal oxide layer 364 because an apparatus can be shared.

In addition, the metal oxide layer 364 is preferably formed with a sputtering apparatus. For example, in the case where an oxide film is formed with a sputtering apparatus, forming the oxide film in an atmosphere containing an oxygen gas can favorably supply oxygen into the insulating layer 360 or the semiconductor layer 358.

The semiconductor layer 358 includes a region overlapping with the conductive layer 362 and a pair of low-resistance regions 358n between which the region is sandwiched. A region of the semiconductor layer 358 that overlaps with the conductive layer 362 functions as a channel formation region of the transistor 350. Meanwhile, the low-resistance region 358n functions as a source region or a drain region of the transistor 350.

The low-resistance region 358n can be regarded as a region having lower resistance than the channel formation region, a region having a higher carrier concentration than the channel formation region, a region having a higher oxygen defect density than the channel formation region, a region having a higher impurity concentration than the channel formation region, or an n-type region.

The low-resistance region 358n of the semiconductor layer 358 is a region containing an impurity element. Examples of the impurity element are hydrogen, boron, carbon, nitrogen, fluorine, phosphorus, sulfur, arsenic, aluminum, a rare gas, and the like. Note that typical examples of a rare gas include helium, neon, argon, krypton, xenon, and the like. In particular, boron or phosphorus is preferably contained. Furthermore, two or more of these elements may be contained.

Treatment of adding an impurity to the low-resistance region 358n can be performed through the insulating layer 360 with the use of the conductive layer 362 as a mask. As the treatment of adding an impurity to the low-resistance regions 358n, a plasma ion doping method or an ion implantation method can be suitably used.

The low-resistance region 358n preferably includes a region whose impurity concentration is higher than or equal to 1×10¹⁹ atoms/cm³ and lower than or equal to 1×10²³ atoms/cm³, preferably higher than or equal to 5×10¹⁹ atoms/cm³ and lower than or equal to 5×10²² atoms/cm³, and further preferably higher than or equal to 1×10²⁰ atoms/cm³ and lower than or equal to 1×10²² atoms/cm³.

The concentrations of the impurity contained in the low-resistance region 358n can be analyzed by an analysis method such as secondary ion mass spectrometry (SIMS) or X-ray photoelectron spectroscopy (XPS), for example. In the case of using XPS analysis, it is possible to find out concentration distribution in the depth direction by the combination of XPS analysis and ion sputtering from a front surface side or a rear surface side.

In addition, the impurity element preferably exists in an oxidized state in the low-resistance region 358n. For example, it is preferable to use an element that is easily oxidized, such as boron, phosphorus, magnesium, aluminum, or silicon, as the impurity element. Such an element that is easily oxidized can exist stably in a state of being bonded to oxygen in the semiconductor layer 358 to be oxidized and thus can be inhibited from being released even when a high temperature (e.g., higher than or equal to 400° C., higher than or equal to 600° C., or higher than or equal to 800° C.) is applied in a later step. Furthermore, when the impurity element takes oxygen in the semiconductor layer 358 away, many oxygen vacancies are generated in the low-resistance region 358n. The oxygen vacancies are bonded to hydrogen in the film to serve as carrier supply sources; thus, the low-resistance region 358n is in an extremely low-resistance state.

For example, in the case where boron is used as the impurity element, boron contained in the low-resistance region 358n can exist in a state of being bonded to oxygen. This can be confirmed when a spectrum peak attributed to a B₂O₃ bond is observed in XPS analysis. Furthermore, in XPS analysis, the intensity of a spectrum peak attributed to a state where a boron element exists alone is so low that the spectrum peak is not observed or is buried in background noise at the measurement lower limit.

The insulating layer 360 includes a region in contact with the channel formation region of the semiconductor layer 358, i.e., a region overlapping with the conductive layer 362. The insulating layer 360 includes a region that is in contact with the low-resistance region 358n of the semiconductor layer 358 and does not overlap with the conductive layer 362.

In some cases, a region of the insulating layer 360, which overlaps with the low-resistance region 358n, contains the above impurity element. In this case, as in the low-resistance region 358n, the impurity element in the insulating layer 360 also preferably exists in a state of being bonded to oxygen. Since such an element that is easily oxidized can exist stably in a state of being bonded to oxygen in the insulating layer 360 to be oxidized, the element can be inhibited from being released even when a high temperature is applied in a later step. Furthermore, particularly in the case where oxygen (also referred to as excess oxygen) that might be released by heating is included in the insulating layer 360, the excess oxygen and the impurity element are bonded to each other and stabilized, so that oxygen can be inhibited from being supplied from the insulating layer 360 to the low-resistance region 358n. Furthermore, since oxygen is less likely to be diffused in part of the insulating layer 360 containing the oxidized impurity element, it is possible to prevent an increase in the resistance of the low-resistance region 358n which might be caused by supply of oxygen to the low-resistance region 358n from components above the insulating layer 360 through the insulating layer 360.

The insulating layer 368 functions as a protection layer protecting the transistor 350. For example, an inorganic insulating material such as an oxide or a nitride can be used for the insulating layer 368. More specifically, for example, an inorganic insulating material such as silicon oxide, silicon oxynitride, silicon nitride, silicon nitride oxide, aluminum oxide, aluminum oxynitride, aluminum nitride, hafnium oxide, or hafnium aluminate can be used.

### Structure Example 2-2

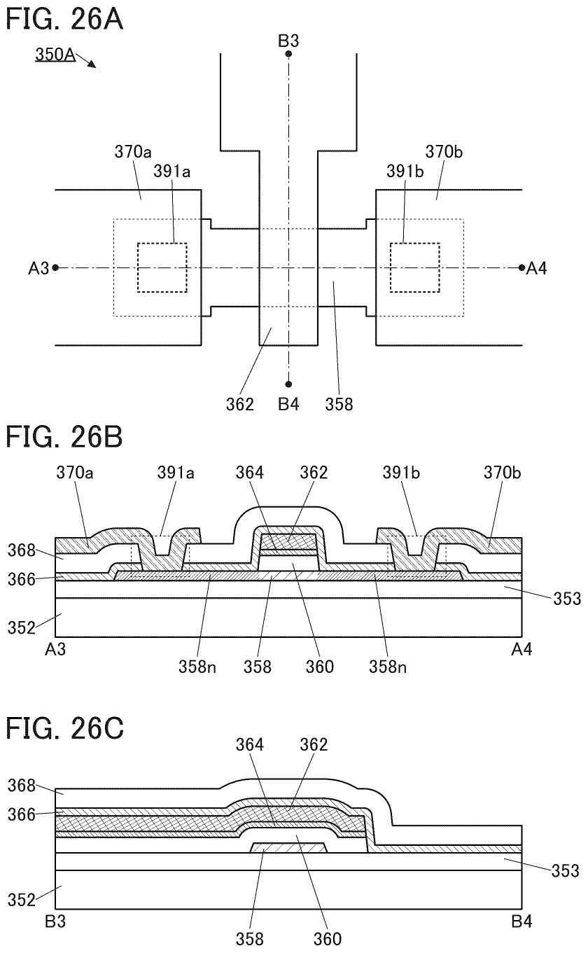

FIG. 26A is a top view of a transistor 350A, FIG. 26B is a cross-sectional view of the transistor 350A in the channel length direction, and FIG. 26C is a cross-sectional view of the transistor 350A in the channel width direction.

The transistor 350A is different from the transistor 350 described in Structure Example 2-1 mainly in the structure of the insulating layer 360 and the existence of an insulating layer 366.

The insulating layer 360 is processed so as to have a top surface shape substantially the same as the top surface shapes of the conductive layer 362 and the metal oxide layer 364. The insulating layer 360 can be formed with the use of a resist mask for processing the conductive layer 362 and the metal oxide layer 364, for example.

The insulating layer 366 is provided in contact with a top surface and a side surface of the semiconductor layer 358 which are not covered with the conductive layer 362, the metal oxide layer 364, and the insulating layer 360. The insulating layer 366 is provided to cover a top surface of the insulating layer 353, a side surface of the insulating layer 360, a side surface of the metal oxide layer 364, and a top surface and a side surface of the conductive layer 362.

The insulating layer 366 has a function of reducing the resistance of the low-resistance region 358n. As the insulating layer 366, an insulating film that can supply impurities to the low-resistance region 358n by being heated at the time of or after the deposition of the insulating layer 366 can be used. Alternatively, an insulating film that can generate oxygen vacancies in the low-resistance region 358n by being heated at the time of or after the deposition of the insulating layer 366 can be used.

For example, as the insulating layer 366, an insulating film functioning as a supply source that supplies impurities to the low-resistance region 358n can be used. In that case, the insulating layer 366 is preferably a film that release hydrogen by being heated. When the insulating layer 366 is formed in contact with the semiconductor layer 358, impurities such as hydrogen can be supplied to the low-resistance region 358n, so that the resistance of the low-resistance region 358n can be reduced.

The insulating layer 366 is preferably a film deposited using a gas containing an impurity element such as a hydrogen element as a deposition gas used for the deposition. In addition, by increasing the deposition temperature of the insulating layer 366, a large number of impurity elements can be effectively supplied to the semiconductor layer 358. The deposition temperature of the insulating layer 366 is higher than or equal to 200° C. and lower than or equal to 500° C., preferably higher than or equal to 220° C. and lower than or equal to 450° C., further preferably higher than or equal to 250° C. and lower than or equal to 400° C., for example.

When the insulating layer 366 is deposited under a reduced pressure while heating is performed, release of oxygen from the region to be the low-resistance region 358n in the semiconductor layer 358 can be promoted. When an impurity such as hydrogen is supplied to the semiconductor layer 358 where many oxygen vacancies are formed, the carrier density of the low-resistance region 358n is increased, and the resistance of the low-resistance region 358n can be lowered more effectively.

For the insulating layer 366, for example, an insulating film containing a nitride, such as silicon nitride, silicon nitride oxide, silicon oxynitride, aluminum nitride, or aluminum nitride oxide can be favorably used. In particular, because of having a blocking property against hydrogen and oxygen, silicon nitride can prevent both diffusion of hydrogen from the outside into the semiconductor layer and release of oxygen from the semiconductor layer to the outside, and thus a highly reliable transistor can be achieved.

The insulating layer 366 may be an insulating film having a function of absorbing oxygen in the semiconductor layer 358 and generating oxygen vacancies. In particular, a metal nitride is preferably used for the insulating layer 366.

In the case of using a metal nitride, it is preferable to use a nitride of aluminum, titanium, tantalum, tungsten, chromium, or ruthenium. It is particularly preferable that aluminum or titanium be contained. For example, an aluminum nitride film formed by a reactive sputtering method using aluminum as a sputtering target and a nitrogen-containing gas as a deposition gas can be a film having both an extremely high insulating property and an extremely high blocking property against hydrogen and oxygen when the flow rate of a nitrogen gas with respect to the total flow rate of the deposition gas is appropriately controlled. Thus, when such an insulating film containing a metal nitride is provided in contact with the semiconductor layer, the resistance of the semiconductor layer can be reduced, and release of oxygen from the semiconductor layer and diffusion of hydrogen into the semiconductor layer can be favorably prevented.

In the case where aluminum nitride is used as the metal nitride, the thickness of the insulating layer containing aluminum nitride is preferably 5 nm or more. A film with such a small thickness can have both a high blocking property against hydrogen and oxygen and a function of reducing the resistance of the semiconductor layer. Note that there is no upper limit of the thickness of the insulating layer; however, the thickness is preferably less than or equal to 500 nm, further preferably less than or equal to 200 nm, and still further preferably less than or equal to 50 nm in consideration of productivity.

In the case of using an aluminum nitride film as the insulating layer 366, it is preferable to use a film that satisfies the composition formula AlNₓ (x is a real number greater than 0 and less than or equal to 2, and preferably, x is a real number greater than 0.5 and less than or equal to 1.5). In that case, a film having an excellent insulating property and high thermal conductivity can be obtained, and thus dissipation of heat generated in driving the transistor 350A can be increased.

The insulating layer 366 is provided in contact with the low-resistance region 358n, whereby the insulating layer 366 absorbs oxygen in the low-resistance region 358n and oxygen vacancies can be formed in the low-resistance region 358n. Furthermore, when heat treatment is performed after the insulating layer 366 is formed, a larger number of oxygen vacancies can be formed in the low-resistance region 358n, so that the reduction in resistance can be promoted. In the case where a film containing a metal oxide is used as the insulating layer 366, as the result of absorption of oxygen in the semiconductor layer 358 by the insulating layer 366, a layer containing an oxide of a metal element included in the insulating layer 366 (e.g., aluminum) may be formed between the insulating layer 366 and the low-resistance region 358n.

Here, in the case where a metal oxide film containing indium is used as the semiconductor layer 358, a region where indium oxide is precipitated or a region having a high indium concentration is sometimes formed in the low-resistance region 358n in the vicinity of the interface with the insulating layer 366. Thus, the low resistance region 358n having extremely low resistance can be formed. Such a region can sometimes be observed by an analysis method such as X-ray photoelectron spectroscopy (XPS), for example.

### Structure Example 2-3

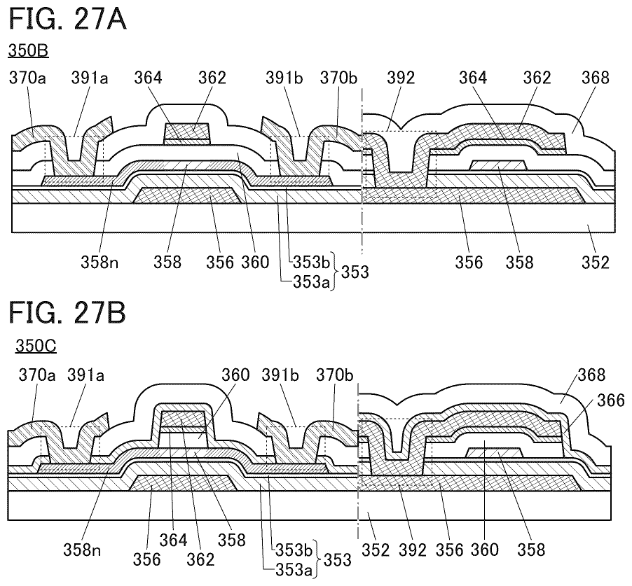

FIG. 27A is a cross-sectional view of a transistor 350B. In FIG. 27A, a cross section in the channel length direction is shown on the left side of the dashed-dotted line, and a cross section in the channel width direction is shown on the right side.

The transistor 350B is different from Structure example 2-1 mainly in that a conductive layer 356 is included between the substrate 352 and the insulating layer 353. The conductive layer 356 includes a region overlapping with the semiconductor layer 358 and the conductive layer 362.

In the transistor 350B, the conductive layer 362 has a function of a second gate electrode (also referred to as a top gate electrode), and the conductive layer 356 has a function of a first gate electrode (also referred to as a bottom gate electrode). In addition, part of the insulating layer 360 functions as a second gate insulating layer, and part of the insulating layer 353 functions as a first gate insulating layer.

A portion of the semiconductor layer 358 which overlaps with at least one of the conductive layer 362 and the conductive layer 356 functions as a channel formation region. Note that for easy explanation, a portion of the semiconductor layer 358 that overlaps with the conductive layer 362 is hereinafter referred to as a channel formation region in some cases; however, a channel can also be actually formed in a portion not overlapping with the conductive layer 362 and overlapping with the conductive layer 356 (a portion including the low-resistance region 358n).

As illustrated in FIG. 27A, the conductive layer 356 may be electrically connected to the conductive layer 362 through an opening 392 provided in the metal oxide layer 364, the insulating layer 360, and the insulating layer 353. In that case, the same potential can be supplied to the conductive layer 356 and the conductive layer 362.

The conductive layer 356 may be electrically connected to any one of the conductive layer 370a and the conductive layer 370b.

For the conductive layer 356, a material similar to that for the conductive layer 362, the conductive layer 370a, or the conductive layer 370b can be used. Specifically, a material containing copper is preferably used for the conductive layer 356, in which case wiring resistance can be reduced.

FIG. 27A illustrates the case where the insulating layer 353 has a stacked-layer structure in which an insulating layer 353a and an insulating layer 353b are stacked from the conductive layer 356 side. In that case, an insulating film that is less likely to diffuse a metal element included in the conductive layer 356 is preferably used as the insulating layer 353a positioned on the conductive layer 356 side. For example, an inorganic insulating film such as a silicon nitride film, a silicon nitride oxide film, an aluminum oxide film, or a hafnium oxide film is preferably used.

Meanwhile, an insulating film containing oxygen is preferably used as the insulating layer 353b in contact with the semiconductor layer 358. For example, a silicon oxide film, a silicon oxynitride film, or the like is preferably used.

In addition, as illustrated in FIG. 27A, the conductive layer 362 and the conductive layer 356 preferably project outward from an end portion of the semiconductor layer 358 in the channel width direction. In that case, as illustrated in FIG. 27A, a structure is employed in which the semiconductor layer 358 in the channel width direction is entirely covered with the conductive layer 362 and the conductive layer 356 with the insulating layer 360 and the insulating layer 353 therebetween.

With such a structure, the semiconductor layer 358 can be electrically surrounded by electric fields generated by a pair of gate electrodes. At this time, it is particularly preferable that the same potential be supplied to the conductive layer 356 and the conductive layer 362. In that case, electric fields for inducing a channel can be effectively applied to the semiconductor layer 358, so that the on-state current of the transistor 350B can be increased. Thus, the transistor 350B can also be miniaturized.

Note that a structure in which the conductive layer 362 and the conductive layer 356 are not connected to each other may be employed. In that case, a constant potential may be supplied to one of the pair of gate electrodes, and a signal for driving the transistor 350B may be supplied to the other. In this case, the potential supplied to one of the gate electrodes can control the threshold voltage at the time of driving the transistor 350B with the other gate electrode.

### Structure Example 2-4

FIG. 27B is a cross-sectional view of a transistor 350C. In FIG. 27B, a cross section in the channel length direction is shown on the left side of the dashed-dotted line, and a cross section in the channel width direction is shown on the right side.

The transistor 350C is an example in which the transistor 350A described in Structure example 2-2 is provided with the conductive layer 356 described in Structure example 2-3 and functioning as the second gate electrode.

Such a structure enables a transistor to have high on-state current. Alternatively, a transistor whose threshold voltage is controllable can be provided.

At least part of the structure examples, the drawings corresponding thereto, and the like exemplified in this embodiment can be implemented in combination with the other structure examples, the other drawings, and the like as appropriate.

At least part of this embodiment can be implemented in combination with the other embodiments described in this specification as appropriate.

### Embodiment 3

In this embodiment, examples of a structure of a display device which can be manufactured using a semiconductor device including a metal oxide film of one embodiment of the present invention will be described.

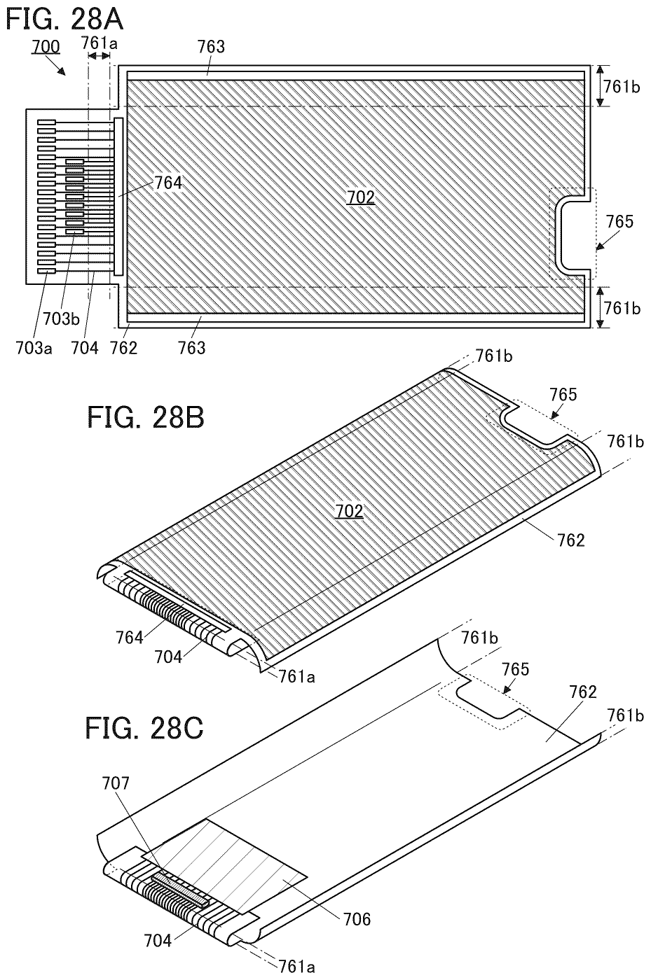

FIG. 28A is a schematic top view of a display device 700. The display device 700 includes a substrate 762 having flexibility. The substrate 762 is provided with a display portion 702, a pair of circuit portions 763, a circuit portion 764, wirings 704, connection terminals 703a, and connection terminals 703b.

The circuit portions 763 and the circuit portion 764 have a function of driving the display portion 702. Two circuit portions 763 are provided with the display portion 702 positioned therebetween. The circuit portion 764 is provided between the display portion 702 and the wirings 704. The circuit portions 763 function as gate drivers, for example, and the circuit portion 764 functions as a source driver or part of the source driver, for example. For example, the circuit portion 764 may include a buffer circuit or a demultiplexer circuit.

As a display element provided in the display portion 702, the above-described variety of display elements such as a liquid crystal element and a light-emitting element can be used. In particular, an organic EL element is preferably used as the display element.

In the top surface shape, a portion of the substrate 762 over which the wirings 704, the connection terminals 703a, and the connection terminals 703b are provided projects from the other portion. In other words, the width of the portion of the substrate 762 is smaller than the width of a portion of the substrate 762 over which the display portion 702 is provided.

Furthermore, the projecting portion of the substrate 762 includes a region that can be bent (a bent portion 761a) in a region overlapping with the wirings 704. Moreover, the substrate 762 includes a pair of regions that can be bent (bent portions 761b) in a region over which the display portion 702 is provided. As illustrated in FIG. 28A, owing to the projecting shape of the portion of the substrate 762, the bending direction of the bent portion 761a can intersect with the bending direction of the bent portions 761b.

The connection terminals 703a function as terminals to which an FPC (Flexible Printed Circuit) is to be connected, while the connection terminals 703b function as terminals to which an IC is to be connected.

FIG. 28B and FIG. 28C are perspective views of the display device 700 in the case where the substrate 762 is bent at the bent portion 761a and the bent portions 761b to a side opposite to the display surface side. FIG. 28B is a perspective view including the display surface side, and FIG. 28C is a perspective view including the side opposite to the display surface side. Furthermore, FIG. 28C clearly shows an FPC 706 connected to the connection terminals 703a and an IC 707 connected to the connection terminals 703b.

When both sides of the display portion 702 are bent as illustrated in FIG. 28B, at the time of incorporating the display device 700 in an electronic device, bent display portions can be provided on both sides of the electronic device. Thus, a highly functional electronic device can be provided.

Furthermore, as illustrated in FIG. 28B and FIG. 28C, owing to the bent portion 761a, part of the substrate 762 can be folded back to the side opposite to the display surface side. Specifically, the projecting portion of the substrate 762 can be folded back so that the wirings 704 are on an outer side. Accordingly, the connection terminals 703a and the connection terminals 703b can be placed on the side opposite to the display surface side; in addition, the FPC 706 can be placed on the side opposite to the display surface side. Thus, the area of a non-display portion can be reduced when the display device 700 is incorporated in an electronic device.

Furthermore, a notch 765 is provided in the substrate 762. The notch 765 is a portion in which, for example, a lens of a camera included in an electronic device, a variety of sensors such as an optical sensor, a lighting device, a design, or the like can be placed. Owing to the notch of part of the display portion 702, a further highly designed electronic device can be provided. In addition, owing to the notch, the screen occupation ratio with respect to the surface of a housing can be increased.

### Cross-Sectional Structure Examples

Examples of a cross-sectional structure of the display device are described below.

### Structure Example 1

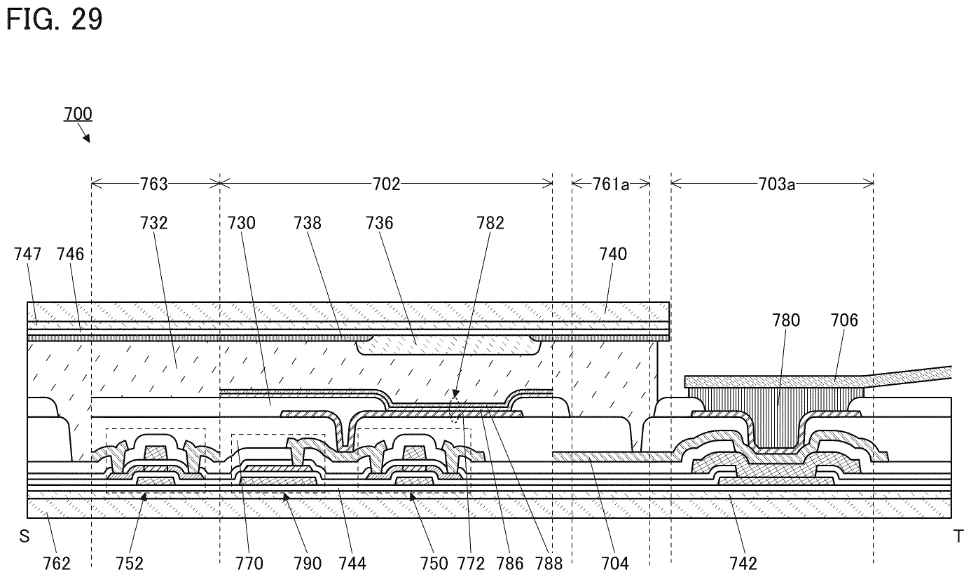

FIG. 29 shows a schematic cross-sectional view of the display device 700. FIG. 29 illustrates a cross section including the display portion 702, the circuit portion 763, the bent portion 761a, and the connection terminal 703a of the display device 700 shown in FIG. 28A. A transistor 750 and a capacitor 790 are provided in the display portion 702. A transistor 752 is provided in the circuit portion 763.

The transistor 750 and the transistor 752 are each a transistor using an oxide semiconductor for a semiconductor layer in which a channel is formed. Note that the transistors are not limited thereto, and a transistor using silicon (amorphous silicon, polycrystalline silicon, or single-crystal silicon) for its semiconductor layer or a transistor using an organic semiconductor for its semiconductor layer can be used.

The transistor used in this embodiment includes a highly purified oxide semiconductor film in which formation of oxygen vacancies is inhibited. The off-state current of the transistors can be reduced significantly. Accordingly, in the pixel employing such a transistor, the retention time of an electrical signal such as an image signal can be extended, and the interval between writes of an image signal or the like can also be set longer. Accordingly, the frequency of refresh operations can be reduced, so that power consumption can be reduced.

The transistor used in this embodiment can have relatively high field-effect mobility and thus is capable of high-speed operation. For example, with the use of such a transistor capable of high-speed operation for a display device, a switching transistor in a pixel and a driver transistor used in a circuit portion can be formed over one substrate. That is, a structure in which a driver circuit formed using a silicon wafer or the like is not used is possible, in which case the number of components of the display device can be reduced. Moreover, the use of the transistor capable of high-speed operation also in the pixel can provide a high-quality image.

The capacitor 790 includes a lower electrode formed by processing the same film as a film used for the first gate electrode of the transistor 750 and an upper electrode formed by processing the same metal oxide film as a film used for the semiconductor layer. The upper electrode has reduced resistance like a source region and a drain region of the transistor 750. Part of an insulating film functioning as a first gate insulating layer of the transistor 750 is provided between the lower electrode and the upper electrode. That is, the capacitor 790 has a stacked-layer structure in which an insulating film functioning as a dielectric film is positioned between a pair of electrodes. A wiring obtained by processing the same film as a film used for a source electrode and a drain electrode of the transistor 750 is connected to the upper electrode.

An insulating layer 770 that functions as a planarization film is provided over the transistor 750, the transistor 752, and the capacitor 790.

The transistor 750 in the display portion 702 and the transistor 752 in the circuit portion 763 may have different structures. For example, a top-gate transistor may be used as one of the transistors 750 and 752, and a bottom-gate transistor may be used as the other. Note that this description as for the circuit portions 763 can be applied to the circuit portion 764. Note that Embodiment 2, which is described above, can be referred to for the structures of the transistor 750 and the transistor 752.

The connection terminal 703a includes part of the wiring 704. As illustrated in FIG. 29, the connection terminal 703a preferably has a stacked-layer structure in which a plurality of conductive films are stacked, in which case the connection terminal 703a can have increased conductivity and increased mechanical strength. The connection terminal 703a is electrically connected to the FPC 706 via a connection layer 780. For the connection layer 780, for example, an anisotropic conductive material can be used.

The display device 700 includes the substrate 762 and a substrate 740, each of which functions as a support substrate. As the substrate 762 and the substrate 740, a glass substrate or a substrate having flexibility such as a plastic substrate can be used, for example. The transistor 750, the transistor 752, the capacitor 790, and the like are provided over an insulating layer 744. The substrate 762 and the insulating layer 744 are bonded to each other with an adhesive layer 742.

The display device 700 includes a light-emitting element 782, a coloring layer 736, a light-blocking layer 738, and the like.

The light-emitting element 782 includes a conductive layer 772, an EL layer 786, and a conductive layer 788. The conductive layer 772 is electrically connected to the source electrode or the drain electrode included in the transistor 750. The conductive layer 772 is provided over the insulating layer 770 and functions as a pixel electrode. An insulating layer 730 is provided to cover an end portion of the conductive layer 772. Over the insulating layer 730 and the conductive layer 772, the EL layer 786 and the conductive layer 788 are stacked.

For the conductive layer 772, a material having a property of reflecting visible light can be used. For example, a material containing aluminum, silver, or the like can be used. For the conductive layer 788, a material that transmits visible light can be used. For example, an oxide material containing indium, zinc, tin, or the like is preferably used. Thus, the light-emitting element 782 is a top-emission light-emitting element, which emits light to the side opposite the formation surface (the substrate 740 side).

The EL layer 786 contains an organic compound or an inorganic compound such as quantum dots. The EL layer 786 contains a light-emitting material that exhibits light when current flows.

As the light-emitting material, a fluorescent material, a phosphorescent material, a thermally activated delayed fluorescence (TADF) material, an inorganic compound (e.g., a quantum dot material), or the like can be used. Examples of materials that can be used for quantum dots include a colloidal quantum dot material, an alloyed quantum dot material, a core-shell quantum dot material, and a core quantum dot material.

The light-blocking layer 738 and the coloring layer 736 are provided on one surface of an insulating layer 746. The coloring layer 736 is provided in a position overlapping with the light-emitting element 782. The light-blocking layer 738 is provided in a region not overlapping with the light-emitting element 782 in the display portion 702. The light-blocking layer 738 may also be provided to overlap with the circuit portion 763 or the like.

The substrate 740 is bonded to the other surface of the insulating layer 746 with an adhesive layer 747. The substrate 740 and the substrate 762 are bonded to each other with a sealing layer 732.

Here, for the EL layer 786 included in the light-emitting element 782, a light-emitting material that exhibits white light emission is used. White light emission by the light-emitting element 782 is colored by the coloring layer 736 to be emitted to the outside. The EL layer 786 is provided over the pixels that exhibit different colors. The pixels provided with the coloring layer 736 transmitting any of red (R), green (G), and blue (B) are arranged in a matrix in the display portion 702, whereby the display device 700 can perform full-color display.

A conductive film having a transmissive property and a reflective property may be used for the conductive layer 788. In this case, a microcavity structure is achieved between the conductive layer 772 and the conductive layer 788 such that light of a specific wavelength can be intensified to be emitted. Also in this case, an optical adjustment layer for adjusting an optical distance may be placed between the conductive layer 772 and the conductive layer 788 such that the thickness of the optical adjustment layer differs between pixels of different colors, whereby the color purity of light emitted from each pixel can be increased.

Note that a structure in which the coloring layer 736 or the above optical adjustment layer is not provided may be employed when the EL layer 786 is formed into an island shape for each pixel or into a stripe shape for each pixel column, i.e., the EL layer 786 is formed by separate coloring.

Here, an inorganic insulating film that functions as a barrier film having low permeability is preferably used for each of the insulating layer 744 and the insulating layer 746. With such a structure in which the light-emitting element 782, the transistor 750, and the like are interposed between the insulating layer 744 and the insulating layer 746, deterioration of them can be inhibited and a highly reliable display device can be achieved.

### Structure Example 2

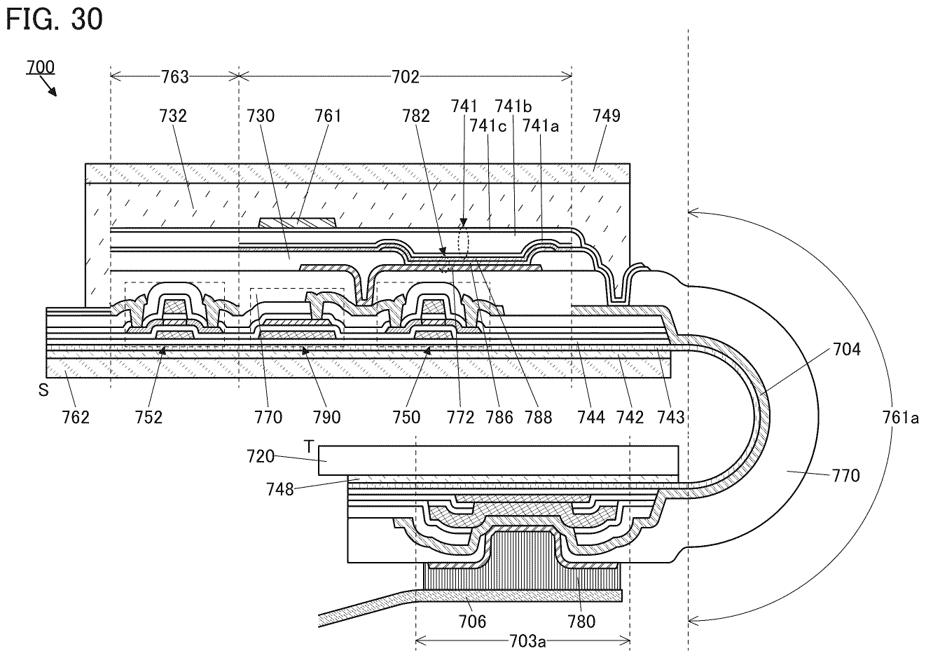

FIG. 30 is a cross-sectional view of the display device 700 having a structure partly different from that of FIG. 29. Furthermore, FIG. 30 clearly shows an embodiment in which part of the display device 700 is bent in the bent portion 761a and folded back to the side opposite to the display surface side.

In the display device 700 illustrated in FIG. 30, a resin layer 743 is provided between the adhesive layer 742 and the insulating layer 744 illustrated in FIG. 29. A protection layer 749 is provided instead of the substrate 740.

The resin layer 743 is a layer containing an organic resin such as polyimide or acrylic. The insulating layer 744 includes an inorganic insulating film of silicon oxide, silicon oxynitride, silicon nitride, or the like. The resin layer 743 and the substrate 762 are attached to each other with the adhesive layer 742. The resin layer 743 is preferably thinner than the substrate 762.

The protection layer 749 is attached to the sealing layer 732. A glass substrate, a resin film, or the like can be used as the protection layer 749. As the protection layer 749, an optical member such as a polarizing plate (including a circularly polarizing plate) or a scattering plate, an input device such as a touch sensor panel, or a structure in which two or more of these are stacked may be employed. Furthermore, the protection layer 749 may include a component included in part of a housing of an electronic device (for example, a portion to be a screen).

The EL layer 786 included in the light-emitting element 782 is provided over the insulating layer 730 and the conductive layer 772 in an island shape. The EL layers 786 are formed separately such that subpixels have the respective emission colors, whereby color display can be performed without use of the coloring layer 736.

A protection layer 741 is provided to cover the light-emitting element 782. The protection layer 741 has a function of preventing diffusion of impurities such as water into the light-emitting element 782. The protection layer 741 has a stacked-layer structure in which an insulating layer 741a, an insulating layer 741b, and an insulating layer 741c are stacked in this order from the conductive layer 788 side. In that case, it is preferable that inorganic insulating films with a high barrier property against impurities such as water be used as the insulating layer 741a and the insulating layer 741c, and an organic insulating film that functions as a planarization film be used as the insulating layer 741b. The protection layer 741 is preferably provided to extend also to the circuit portion 763 and the like.

An organic insulating film covering the transistor 750, the transistor 752, and the like is preferably formed in an island shape inward from the sealing layer 732. In other words, an end portion of the organic insulating film is preferably positioned inward from the sealing layer 732 or in a region overlapping with an end portion of the sealing layer 732. FIG. 30 shows an example in which the insulating layer 770, the insulating layer 730, and the insulating layer 741b are processed into island shapes. The insulating layer 741c and the insulating layer 741a are provided in contact with each other in a portion overlapping with the sealing layer 732, for example. Thus, a surface of the organic insulating film covering the transistor 750 and the transistor 752 is not exposed to the outside of the sealing layer 732, whereby diffusion of water or hydrogen from the outside to the transistor 750 and the transistor 752 through the organic insulating film can be favorably prevented. This can reduce variations in electrical characteristics of the transistors, so that a display device with extremely high reliability can be fabricated.

In FIG. 30, the bent portion 761a includes a portion where the substrate 762, the adhesive layer 742, and the inorganic insulating film such as the insulating layer 744 are not provided. The bent portion 761a has a structure in which the insulating layer 770 including an organic material covers the wiring 704 so that the wiring 704 is not exposed. In the structure illustrated in FIG. 30, the bent portion 761a has a stacked-layer structure in which the resin layer 743, the wiring 704, and the insulating layer 770 are stacked.

When a structure is employed in which an inorganic insulating film is not provided if possible in the bent portion 761a and only a conductive layer containing a metal or an alloy and a layer containing an organic material are stacked, generation of cracks caused at bending can be prevented. When the substrate 762 is not provided in the bent portion 761a, part of the display device 700 can be bent with an extremely small radius of curvature.

In a region overlapping with the connection terminal 703a, a support 720 is bonded to the resin layer 743 with an adhesive layer 748 positioned therebetween. A material having higher rigidity than the substrate 762 and the like can be used for the support 720. Alternatively, the support 720 may be part of a housing of an electronic device or part of a component placed in an electronic device.

In FIG. 30, a conductive layer 761 is provided over the protection layer 741. The conductive layer 761 can be used as a wiring or an electrode.

In the case where a touch sensor is provided so as to overlap with the display device 700, the conductive layer 761 can function as an electrostatic shielding film for preventing transmission of electrical noise to the touch sensor during pixel driving. In this case, the structure in which a predetermined constant potential is supplied to the conductive layer 761 can be employed.

Alternatively, the conductive layer 761 can be used as an electrode of the touch sensor, for example. This enables the display device 700 to function as a touch panel. For example, the conductive layer 761 can be used as an electrode or a wiring of a capacitive touch sensor. In this case, the conductive layer 761 can be used as a wiring or an electrode to which a sensor circuit is connected or a wiring or an electrode to which a sensor signal is input. When the touch sensor is formed over the light-emitting element 782 in this manner, the number of components can be reduced, and manufacturing cost of an electronic device or the like can be reduced.

The conductive layer 761 is preferably provided in a portion not overlapping with the light-emitting element 782. The conductive layer 761 can be provided in a position overlapping with the insulating layer 730, for example. Thus, a transparent conductive film with a relatively low conductivity is not necessarily used for the conductive layer 761, and a metal or an alloy having high conductivity or the like can be used, so that the sensitivity of the sensor can be increased.

As the type of the touch sensor that can be formed of the conductive layer 761, a variety of types such as a resistive type, a surface acoustic wave type, an infrared type, an optical type, and a pressure-sensitive type can be used, without limitation to a capacitive type. Alternatively, two or more of these types may be combined and used.

### Structure Example 3

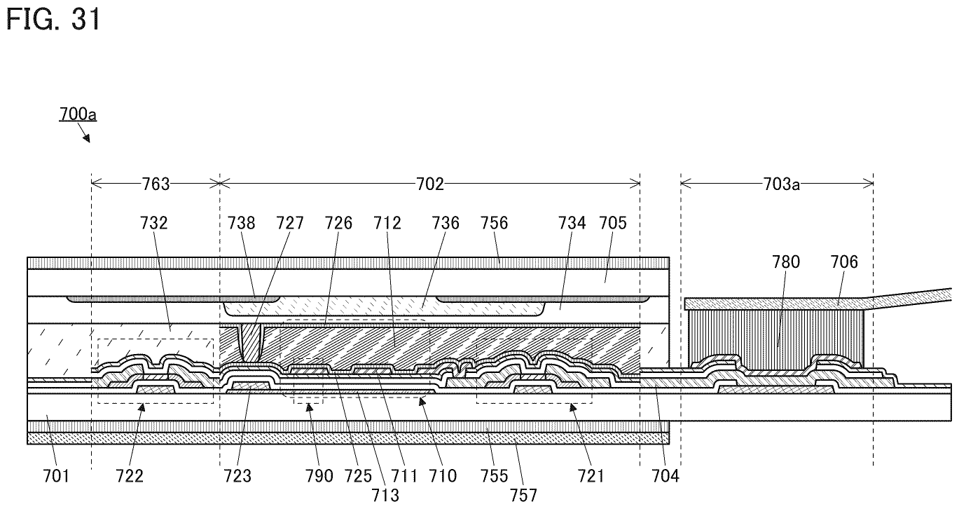

FIG. 31 illustrates a schematic cross-sectional view of a display device 700a in the case where a liquid crystal element is used as a display element. FIG. 31 illustrates a cross-sectional view of a region including the circuit portion 763, the display portion 702, and the connection terminal 703a.

The display device 700a illustrated in FIG. 31 includes a transistor 721, a transistor 722, a liquid crystal element 710, and the like between a substrate 701 and a substrate 705. The substrate 701 and the substrate 705 are bonded to each other with the sealing layer 732.

Here, the case where bottom-gate transistors are used as the transistor 721 and the transistor 722 is described.

The liquid crystal element 710 includes a conductive layer 711, a liquid crystal 712, and a conductive layer 713. The conductive layer 713 is provided over the substrate 701. One or more insulating layers are provided over the conductive layer 713, and the conductive layer 711 is provided over the insulating layer(s). Furthermore, the liquid crystal 712 is positioned between the conductive layer 711 and the substrate 705. The conductive layer 713 is electrically connected to a wiring 723 and functions as a common electrode. The conductive layer 711 is electrically connected to the transistor 721 and serves as a pixel electrode. A common potential is supplied to the wiring 723.

The liquid crystal element 710 illustrated in FIG. 31 is a liquid crystal element to which a horizontal electric field mode (for example, an FFS mode) is applied. The conductive layer 711 has a comb-like top surface shape or a top surface shape including a slit. In the liquid crystal element 710, the alignment state of the liquid crystal 712 is controlled by an electric field generated between the conductive layer 711 and the conductive layer 713.

Furthermore, the capacitor 790 functioning as a storage capacitor is formed of a stacked-layer structure of the conductive layer 711, the conductive layer 713, and one or more insulating layers sandwiched between the conductive layer 711 and the conductive layer 713. Thus, another capacitor need not be provided, and thus the aperture ratio can be increased.

A material that transmits visible light or a material that reflects visible light can be used for the conductive layer 711 and the conductive layer 713. As a light-transmitting material, for example, an oxide material containing indium, zinc, tin, or the like is preferably used. As a reflective material, for example, a material containing aluminum, silver, or the like is preferably used.

When a reflective material is used for one or both of the conductive layer 711 and the conductive layer 713, the display device 700a is a reflective liquid crystal display device. In contrast, when a light-transmitting material is used for both of the conductive layer 711 and the conductive layer 713, the display device 700a is a transmissive liquid crystal display device. For a reflective liquid crystal display device, a polarizing plate is provided on the viewer side. By contrast, for a transmissive liquid crystal display device, a pair of polarizing plates is provided so that the liquid crystal element is placed therebetween.

FIG. 31 shows an example of a transmissive liquid crystal display device. A polarizing plate 755 and a light source 757 are provided on the outer side of the substrate 701, and a polarizing plate 756 is provided on the outer side of the substrate 705. The light source 757 functions as a backlight.

The light-blocking layer 738 and the coloring layer 736 are provided on a surface of the substrate 705 that is on the substrate 701 side. An insulating layer 734 functioning as a planarization layer is provided to cover the light-blocking layer 738 and the coloring layer 736. A spacer 727 is provided on a surface of the insulating layer 734 that is on the substrate 701 side.

The liquid crystal 712 is positioned between an alignment film 725 covering the conductive layer 711 and an alignment film 726 covering the insulating layer 734. Note that the alignment film 725 and the alignment film 726 are not necessarily provided when not needed.

Although not illustrated in FIG. 31, an optical member (optical film) such as a retardation film or an anti-reflection film, a protection film, an antifouling film, or the like can be provided on the outer side of the substrate 705 as appropriate. As examples of the anti-reflection film, an AG (Anti Glare) film, an AR (Anti Reflection) film, or the like can be given.

As the liquid crystal 712, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, or the like can be used. In the case where a horizontal electric field mode is employed, a liquid crystal exhibiting a blue phase for which an alignment film is not used may be used.

As the mode of the liquid crystal element, a TN (Twisted Nematic) mode, a VA (Vertical Alignment) mode, an IPS (In-Plane-Switching) mode, an FFS (Fringe Field Switching) mode, an ASM (Axially Symmetric aligned Micro-cell) mode, an OCB (Optically Compensated Birefringence) mode, an ECB (Electrically Controlled Birefringence) mode, a guest-host mode, or the like can be employed.

In addition, a scattering liquid crystal employing a polymer dispersed liquid crystal, a polymer network liquid crystal, or the like can be used for the liquid crystal 712. At this time, monochrome display may be performed without the coloring layer 736, or color display may be performed using the coloring layer 736.

As a driving method of the liquid crystal element, a time-division display method (also referred to as a field-sequential driving method) by which color display is performed by a successive additive color mixing method may be used. In that case, a structure without the coloring layer 736 can be employed. In the case where the time-division display method is employed, advantages such as the aperture ratio of each pixel or the resolution being increased can be obtained because subpixels that exhibit R (red), G (green), and B (blue), for example, need not be provided.

The display device 700a illustrated in FIG. 31 has a structure in which an organic insulating film functioning as a planarization layer is not provided on a surface on which the conductive layer 711 functioning as a pixel electrode or the conductive layer 713 functioning as a common electrode is provided. Furthermore, bottom-gate transistors, which can be manufactured through a relatively short process, are used as the transistor 721 and the like included in the display device 700a. Moreover, the wiring 704, the connection terminal 703a, and the like can be manufactured with steps common to the manufacturing steps of the transistors, the liquid crystal element, and the like without special steps. With such a structure, the manufacturing cost can be reduced and the manufacturing yield can be increased, so that a display device having high reliability can be provided at low cost.

At least part of the structure examples, the drawings corresponding thereto, and the like described in this embodiment as examples can be implemented in combination with the other structure examples, the other drawings, and the like as appropriate.

At least part of this embodiment can be implemented in combination with the other embodiments described in this specification as appropriate.

### Embodiment 4

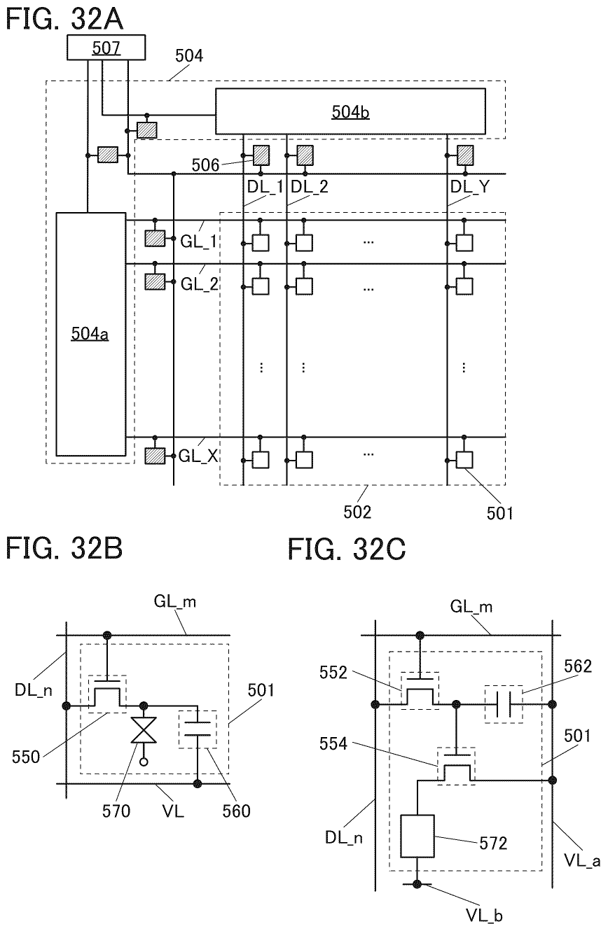

In this embodiment, a display device that includes the semiconductor device of one embodiment of the present invention is described with reference to FIG. 32A to FIG. 32C.

A display device illustrated in FIG. 32A includes a pixel portion 502, a driver circuit portion 504, protection circuits 506, and a terminal portion 507. Note that a structure in which the protection circuits 506 are not provided may be employed.

The transistor of one embodiment of the present invention can be used as transistors included in the pixel portion 502 and the driver circuit portion 504. The transistor of one embodiment of the present invention may also be used in the protection circuits 506. The pixel portion 502 includes a plurality of pixel circuits 501 arranged in X rows and Y columns (X and Y each independently represent a natural number of 2 or more). Each of the pixel circuits 501 includes a circuit for driving a display element.

The driver circuit portion 504 includes driver circuits such as a gate driver 504a that outputs a scanning signal to gate lines GL_1 to GL_X and a source driver 504b that supplies a data signal to data lines DL_1 to DL_Y. The gate driver 504a includes at least a shift register. The source driver 504b is formed using a plurality of analog switches, for example. Alternatively, the source driver 504b may be formed using a shift register or the like.

The terminal portion 507 refers to a portion provided with terminals for inputting power, control signals, image signals, and the like to the display device from external circuits.

The protection circuit 506 is a circuit that, when a potential out of a certain range is supplied to a wiring to which the protection circuit 506 is connected, establishes continuity between the wiring and another wiring. The protection circuit 506 illustrated in FIG. 32A is connected to a variety of wirings such as the gate lines GL that are wirings between the gate driver 504a and the pixel circuits 501 and the data lines DL that are wirings between the source driver 504b and the pixel circuits 501, for example. Note that the protection circuits 506 are hatched in FIG. 32A to distinguish the protection circuits 506 from the pixel circuits 501.

The gate driver 504a and the source driver 504b may be provided over a substrate over which the pixel portion 502 is provided, or a substrate where a gate driver circuit or a source driver circuit is separately formed (e.g., a driver circuit board formed using a single crystal semiconductor or a polycrystalline semiconductor) may be mounted on the substrate by COG or TAB (Tape Automated Bonding).

FIG. 32B and FIG. 32C each illustrate a configuration example of a pixel circuit that can be used as the pixel circuit 501.

The pixel circuit 501 illustrated in FIG. 32B includes a liquid crystal element 570, a transistor 550, and a capacitor 560. The data line DL_n, the gate line GL_m, a potential supply line VL, and the like are connected to the pixel circuit 501.

The potential of one of a pair of electrodes of the liquid crystal element 570 is set appropriately in accordance with the specifications of the pixel circuit 501. The alignment state of the liquid crystal element 570 is set depending on written data. Note that a common potential may be supplied to one of the pair of electrodes of the liquid crystal element 570 included in each of the plurality of pixel circuits 501. Moreover, a different potential may be supplied to one of the pair of electrodes of the liquid crystal element 570 of the pixel circuit 501 in each row.

The pixel circuit 501 illustrated in FIG. 32C includes a transistor 552, a transistor 554, a capacitor 562, and a light-emitting element 572. The data line DL_n, the gate line GL_m, a potential supply line VL_a, a potential supply line VL_b, and the like are connected to the pixel circuit 501.

Note that a high power supply potential VDD is supplied to one of the potential supply line VL_a and the potential supply line VL_b, and a low power supply potential VSS is supplied to the other. Current flowing through the light-emitting element 572 is controlled in accordance with a potential supplied to a gate of the transistor 554, whereby the luminance of light emitted from the light-emitting element 572 is controlled.

At least part of the structure examples, the drawings corresponding thereto, and the like described in this embodiment as examples can be implemented in combination with the other structure examples, the other drawings, and the like as appropriate.

At least part of this embodiment can be implemented in combination with the other embodiments described in this specification as appropriate.

### Embodiment 5

A pixel circuit including a memory for correcting gray levels displayed by pixels and a display device including the pixel circuit are described below. The transistor including the metal oxide film described in Embodiment 1 can be used as a transistor used in the pixel circuit described below.

### Circuit Configuration

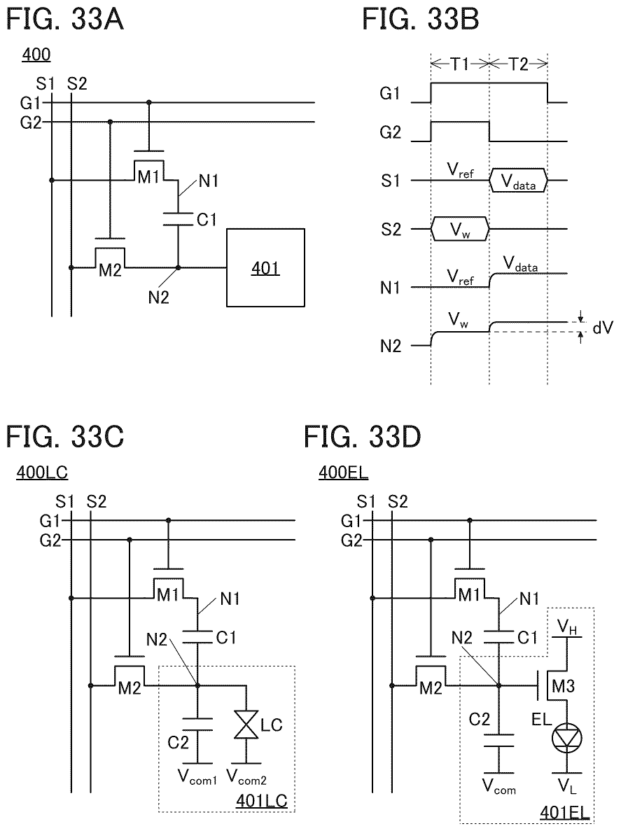

FIG. 33A is a circuit diagram of a pixel circuit 400. The pixel circuit 400 includes a transistor M1, a transistor M2, a capacitor C1, and a circuit 401. A wiring S1, a wiring S2, a wiring G1, and a wiring G2 are connected to the pixel circuit 400.

In the transistor M1, a gate is connected to the wiring G1, one of a source and a drain is connected to the wiring S1, and the other is connected to one electrode of the capacitor C1. In the transistor M2, a gate is connected to the wiring G2, one of a source and a drain is connected to the wiring S2, and the other is connected to the other electrode of the capacitor C1 and the circuit 401.

The circuit 401 is a circuit including at least one display element. Any of a variety of elements can be used as the display element, and typically, a light-emitting element such as an organic EL element or an LED element, a liquid crystal element, a MEMS (Micro Electro Mechanical Systems) element, or the like can be used.

A node connecting the transistor M1 and the capacitor C1 is denoted as a node N1, and a node connecting the transistor M2 and the circuit 401 is denoted as a node N2.

In the pixel circuit 400, the potential of the node N1 can be retained when the transistor M1 is turned off. The potential of the node N2 can be retained when the transistor M2 is turned off. When a predetermined potential is written to the node N1 through the transistor M1 with the transistor M2 being in an off state, the potential of the node N2 can be changed in accordance with displacement of the potential of the node N1 owing to capacitive coupling through the capacitor C1.

Here, the transistor using an oxide semiconductor, which is described in Embodiment 1 as an example, can be used as one or both of the transistor M1 and the transistor M2. Accordingly, owing to an extremely low off-state current, the potentials of the node N1 and the node N2 can be retained for a long time. Note that in the case where the period in which the potential of each node is retained is short (specifically, the case where the frame frequency is higher than or equal to 30 Hz, for example), a transistor using a semiconductor such as silicon may be used.

### Driving Method Example

Next, an example of a method for operating the pixel circuit 400 is described with reference to FIG. 33B. FIG. 33B is a timing chart of the operation of the pixel circuit 400. Note that for simplification of description, the influence of various kinds of resistance such as wiring resistance, parasitic capacitance of a transistor, a wiring, or the like, the threshold voltage of the transistor, and the like is not taken into account here.

In the operation shown in FIG. 33B, one frame period is divided into a period T1 and a period T2. The period T1 is a period in which a potential is written to the node N2, and the period T2 is a period in which a potential is written to the node N1.

### Period T1

In the period T1, a potential for turning on the transistor is supplied to both the wiring G1 and the wiring G2. In addition, a potential V_{ref} that is a constant potential is supplied to the wiring S1, and a first data potential V_{w} is supplied to the wiring S2.

The potential V_{ref} is supplied from the wiring S1 to the node N1 through the transistor M1. The first data potential V_{w} is supplied from the wiring S2 to the node N2 through the transistor M2. Accordingly, a potential difference V_{w}−V_{ref} is retained in the capacitor C1.

### T2

Next, in the period T2, a potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into a floating state.

The second data potential V_{data} is supplied from the wiring S1 to the node N1 through the transistor M1. At this time, capacitive coupling due to the capacitor C1 changes the potential of the node N2 in accordance with the second data potential V_{data} by a potential dV. That is, a potential that is the sum of the first data potential V_{w} and the potential dV is input to the circuit 401. Note that although the potential dV is shown as a positive value in FIG. 33B, dV may be a negative value. That is, the second data potential V_{data} may be lower than the potential V_{ref}.

Here, the potential dV is roughly determined by the capacitance of the capacitor C1 and the capacitance of the circuit 401. When the capacitance of the capacitor C1 is sufficiently larger than the capacitance of the circuit 401, the potential dV is a potential close to the second data potential V_{data}.

In the above manner, the pixel circuit 400 can generate a potential to be supplied to the circuit 401 including the display element, by combining two kinds of data signals; hence, a gray level can be corrected in the pixel circuit 400.

The pixel circuit 400 can also generate a potential exceeding the maximum potential that can be supplied to the wiring S1 and the wiring S2. For example, in the case where a light-emitting element is used, high-dynamic range (HDR) display or the like can be performed. In the case where a liquid crystal element is used, overdriving or the like can be achieved.

### Application Examples

### Example Using Liquid Crystal Element

A pixel circuit 400LC illustrated in FIG. 33C includes a circuit 401LC. The circuit 401LC includes a liquid crystal element LC and a capacitor C2.

In the liquid crystal element LC, one electrode is connected to the node N2 and one electrode of the capacitor C2, and the other electrode is connected to a wiring supplied with a potential V_{com2}. The other electrode of the capacitor C2 is connected to a wiring supplied with a potential V_{com1}.

The capacitor C2 functions as a storage capacitor. Note that the capacitor C2 can be omitted when not needed.

In the pixel circuit 400LC, a high voltage can be supplied to the liquid crystal element LC; thus, high-speed display can be performed by overdriving or a liquid crystal material with a high driving voltage can be employed, for example. Moreover, by supply of a correction signal to the wiring S1 or the wiring S2, a gray level can be corrected in accordance with the operating temperature, the deterioration state of the liquid crystal element LC, or the like.

### Example Using Light-Emitting Element

A pixel circuit 400EL illustrated in FIG. 33D includes a circuit 401EL. The circuit 401EL includes a light-emitting element EL, a transistor M3, and the capacitor C2.

In the transistor M3, a gate is connected to the node N2 and one electrode of the capacitor C2, one of a source and a drain is connected to a wiring supplied with a potential V_{H}, and the other is connected to one electrode of the light-emitting element EL. The other electrode of the capacitor C2 is connected to a wiring supplied with a potential V_{com}. The other electrode of the light-emitting element EL is connected to a wiring supplied with a potential V_{L}.

The transistor M3 has a function of controlling a current to be supplied to the light-emitting element EL. The capacitor C2 functions as a storage capacitor. The capacitor C2 can be omitted when not needed.

Note that although the structure in which the anode side of the light-emitting element EL is connected to the transistor M3 is described here, the transistor M3 may be connected to the cathode side. In that case, the values of the potential V_{H} and the potential V_{L} can be appropriately changed.

In the pixel circuit 400EL, a large amount of current can flow through the light-emitting element EL when a high potential is supplied to the gate of the transistor M3, which enables HDR display, for example. Moreover, a variation in the electrical characteristics of the transistor M3 and the light-emitting element EL can be corrected by supply of a correction signal to the wiring S1 or the wiring S2.

Note that the configuration is not limited to the circuits shown in FIG. 33C and FIG. 33D, and a configuration to which a transistor, a capacitor, or the like is further added may be employed.

At least part of this embodiment can be implemented in combination with the other embodiments described in this specification as appropriate.

### Embodiment 6

In this embodiment, a display module that can be fabricated using one embodiment of the present invention will be described.

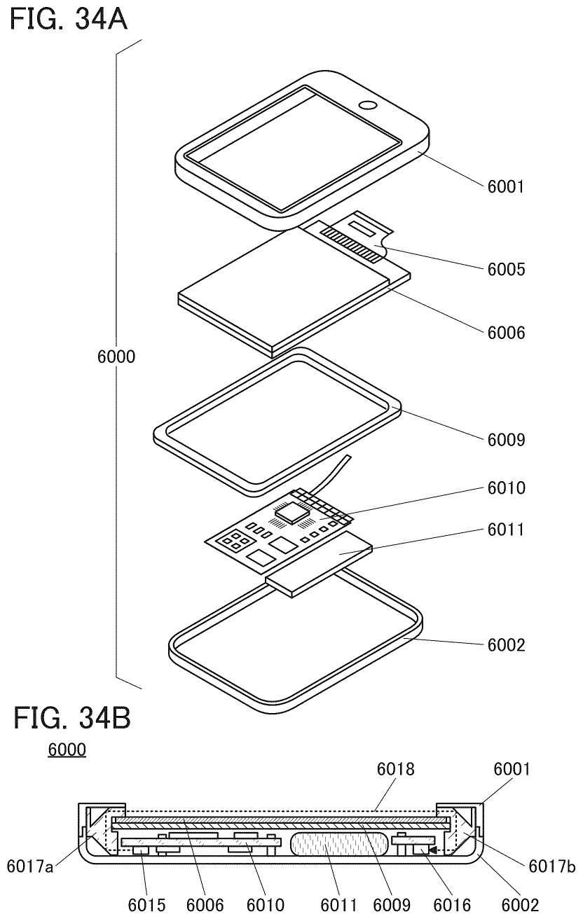

In a display module 6000 illustrated in FIG. 34A, a display device 6006 to which an FPC 6005 is connected, a frame 6009, a printed circuit board 6010, and a battery 6011 are provided between an upper cover 6001 and a lower cover 6002.

A display device fabricated using one embodiment of the present invention can be used as the display device 6006, for example. With the display device 6006, a display module with extremely low power consumption can be achieved.

The shape and size of the upper cover 6001 and the lower cover 6002 can be changed as appropriate in accordance with the size of the display device 6006.

The display device 6006 may have a function of a touch panel.

The frame 6009 may have a function of protecting the display device 6006, a function of blocking electromagnetic waves generated by the operation of the printed circuit board 6010, a function of a heat dissipation plate, or the like.

The printed circuit board 6010 includes a power supply circuit, a signal processing circuit for outputting a video signal and a clock signal, a battery control circuit, and the like. FIG. 34B is a schematic cross-sectional view of the display module 6000 having an optical touch sensor.

The display module 6000 includes a light-emitting portion 6015 and a light-receiving portion 6016 that are provided on the printed circuit board 6010. Furthermore, a pair of light guide portions (a light guide portion 6017a and a light guide portion 6017b) are provided in regions surrounded by the upper cover 6001 and the lower cover 6002.

The display device 6006 overlaps with the printed circuit board 6010 and the battery 6011 with the frame 6009 therebetween. The display device 6006 and the frame 6009 are fixed to the light guide portion 6017a and the light guide portion 6017b.

Light 6018 emitted from the light-emitting portion 6015 travels over the display device 6006 through the light guide portion 6017a and reaches the light-receiving portion 6016 through the light guide portion 6017b. For example, blocking of the light 6018 by a sensing target such as a finger or a stylus enables detection of touch operation.

A plurality of light-emitting portions 6015 are provided along two adjacent sides of the display device 6006, for example. A plurality of light-receiving portions 6016 are provided at the positions on the opposite side of the light-emitting portions 6015. Accordingly, information on the position of touch operation can be acquired.

As the light-emitting portion 6015, a light source such as an LED element can be used, for example, and it is particularly preferable to use a light source emitting infrared rays. As the light-receiving portion 6016, a photoelectric element that receives light emitted from the light-emitting portion 6015 and converts it into an electric signal can be used. A photodiode that can receive infrared rays can be suitably used.

With the use of the light guide portion 6017a and the light guide portion 6017b which transmit the light 6018, the light-emitting portion 6015 and the light-receiving portion 6016 can be placed under the display device 6006, and a malfunction of the touch sensor due to external light reaching the light-receiving portion 6016 can be suppressed. Particularly when a resin that absorbs visible light and transmits infrared rays is used, a malfunction of the touch sensor can be suppressed more effectively.

At least part of this embodiment can be implemented in combination with any of the other embodiments described in this specification as appropriate.

### Embodiment 7

In this embodiment, examples of an electronic device for which a display device of one embodiment of the present invention can be used are described.

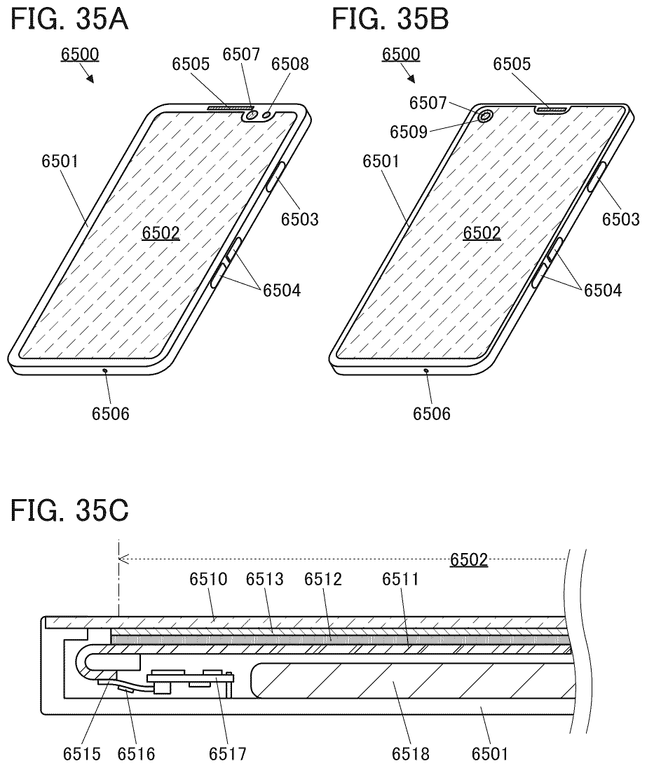

An electronic device 6500 illustrated in FIG. 35A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

The display portion 6502 has a notch, and the camera 6507 and the light source 6508 are provided to be engaged with the notch. With such a structure, an area occupied by the display portion 6502 with respect to the housing 6501 can be large.

Moreover, FIG. 35B shows an example in which the display portion 6502 has an opening, and the camera 6507 and an annular light source 6509 surrounding the camera 6507 are placed in the opening. Furthermore, the speaker 6505 is provided to be engaged with the notch of the display portion 6502. The display portion 6502 may be used as a light source that illuminates a subject. With such a structure, an area occupied by the display portion 6502 with respect to the housing 6501 can be large.

FIG. 35C is a schematic cross-sectional view including an end portion of the housing 6501 on the microphone 6506 side.

A protective member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protective member 6510.

The display panel 6511, the optical member 6512, and the touch sensor panel 6513 are fixed to the protective member 6510 with an adhesive layer not illustrated.

Part of the display panel 6511 is bent in a region outside the display portion 6502. An FPC 6515 is connected to the bent part. An IC 6516 is mounted on the FPC 6515. The FPC 6515 is connected to a terminal provided for the printed circuit board 6517.

A flexible display panel of one embodiment of the present invention can be used as the display panel 6511. Thus, an extremely lightweight electronic device can be achieved. Furthermore, since the display panel 6511 is extremely thin, the battery 6518 with a high capacity can be provided without an increase in the thickness of the electronic device. Moreover, part of the display panel 6511 is bent to provide a connection portion with the FPC 6515 on the back side of the pixel portion, whereby an electronic device with a narrow bezel can be obtained.

At least part of this embodiment can be implemented in combination with the other embodiments described in this specification as appropriate.

### Embodiment 8

In this embodiment, electronic devices each including a display device fabricated using one embodiment of the present invention are described.

Electronic devices described below are each provided with a display device of one embodiment of the present invention in a display portion. Thus, the electronic devices achieve high resolution. In addition, the electronic devices can achieve both high resolution and a large screen.

The display portion of the electronic device of one embodiment of the present invention can display, for example, an image with a resolution of full high definition, 4K2K, 8K4K, 16K8K, or more.

Examples of electronic devices include electronic devices having relatively large screens, such as a television device, a laptop personal computer, a monitor, digital signage, a pachinko machine, and a game machine; a digital camera; a digital video camera; a digital photo frame; a mobile phone; a portable game console; a portable information terminal; an audio reproducing device; and the like.

The electronic device using one embodiment of the present invention can be incorporated along a flat surface or a curved surface of an inside wall or an outside wall of a house or a building, an interior or an exterior of a car, or the like.

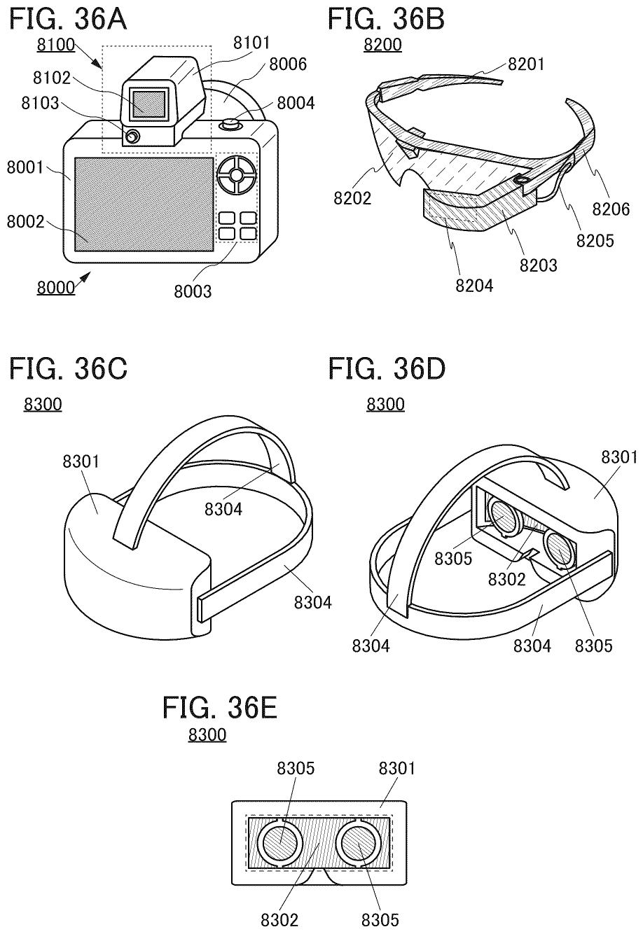

FIG. 36A is an external view of a camera 8000 to which a finder 8100 is attached.

The camera 8000 includes a housing 8001, a display portion 8002, operation buttons 8003, a shutter button 8004, and the like. Furthermore, a detachable lens 8006 is attached to the camera 8000.

Note that the lens 8006 may be included in the housing of the camera 8000.

Images can be taken with the camera 8000 at the press of the shutter button 8004 or the touch of the display portion 8002 functioning as a touch panel.

The housing 8001 includes a mount including an electrode, so that the finder 8100, a stroboscope, or the like can be connected.

The finder 8100 includes a housing 8101, a display portion 8102, a button 8103, and the like

The housing 8101 is attached to the camera 8000 by a mount for engagement with the mount of the camera 8000. In the finder 8100, an image or the like received from the camera 8000 can be displayed on the display portion 8102.

The button 8103 has a function of a power supply button and the like. A display device of one embodiment of the present invention can be used in the display portion 8002 of the camera 8000 and the display portion 8102 of the finder 8100. Note that a finder may be incorporated in the camera 8000.

FIG. 36B is an external view of a head-mounted display 8200.

The head-mounted display 8200 includes a mounting portion 8201, a lens 8202, a main body 8203, a display portion 8204, a cable 8205, and the like. The mounting portion 8201 includes a battery 8206.

Power is supplied from the battery 8206 to the main body 8203 through the cable 8205. The main body 8203 includes a wireless receiver or the like to receive image data and display it on the display portion 8204. The main body 8203 includes a camera, and information on the movement of the eyeballs or the eyelids of the user can be used as an input means.

The mounting portion 8201 may include a plurality of electrodes capable of sensing current flowing with the movement of the user's eyeball at a position in contact with the user to achieve a function of recognizing the user's sight line. The mounting portion 8201 may have a function of monitoring the user's pulse with the use of current flowing in the electrodes. The mounting portion 8201 may include various kinds of sensors such as a temperature sensor, a pressure sensor, and an acceleration sensor to achieve a function of displaying the user's biological information on the display portion 8204 and a function of changing an image displayed on the display portion 8204 in accordance with the movement of the user's head.

A display device of one embodiment of the present invention can be used in the display portion 8204.

FIG. 36C, FIG. 36D and FIG. 36E are external views of a head-mounted display 8300. The head-mounted display 8300 includes a housing 8301, a display portion 8302, a fixing band 8304, and a pair of lenses 8305.

A user can see display on the display portion 8302 through the lenses 8305. Note that the display portion 8302 is preferably curved because the user can feel a high realistic sensation. Another image displayed in another region of the display portion 8302 is viewed through the lenses 8305, so that three-dimensional display using parallax or the like can be performed. Note that the number of the display portions 8302 is not limited to one; two display portions 8302 may be provided for user's respective eyes.

Note that a display device of one embodiment of the present invention can be used in the display portion 8302. A display device including a semiconductor device of one embodiment of the present invention has an extremely high resolution; thus, even when an image is magnified using the lenses 8305 as illustrated in FIG. 36E, the user does not perceive pixels, and thus a more realistic image can be displayed.

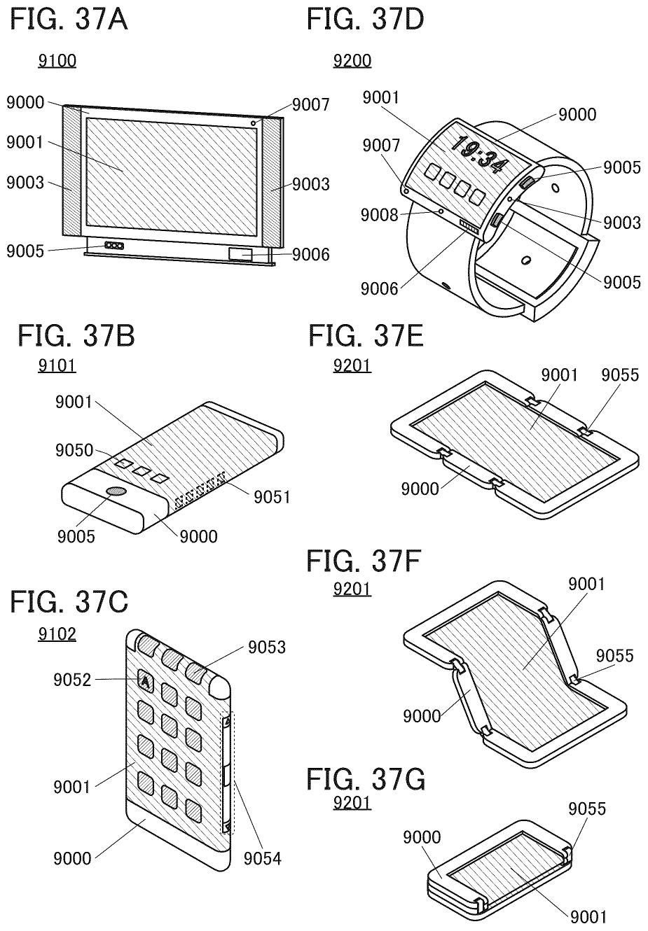

Electronic devices illustrated in FIG. 37A to FIG. 37G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIG. 37A to FIG. 37G have a variety of functions. For example, the electronic devices can have a function of displaying a variety of information (a still image, a moving image, a text image, and the like) on the display portion, a touch panel function, a function of displaying a calendar, the date, the time, and the like, a function of controlling processing with a variety of software (programs), a wireless communication function, a function of reading a program or data stored in a storage medium and processing the program or data, and the like. Note that the electronic devices can have a variety of functions without limitation to the above. The electronic devices may each include a plurality of display portions. The electronic devices may each be provided with a camera or the like and have a function of taking a still image or a moving image, a function of storing the taken image in a storage medium (an external memory medium or a memory medium incorporated in the camera), a function of displaying the taken image on the display portion, or the like.

The electronic devices in FIG. 37A to FIG. 37G are described in detail below.

FIG. 37A is a perspective view illustrating a television device 9100. The television device 9100 can include the display portion 9001 having a large screen size of, for example, 50 inches or more, or 100 inches or more.

FIG. 37B is a perspective view of a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. In the example shown in FIG. 37B, three icons 9050 are displayed. Furthermore, information 9051 indicated by dashed rectangles can be displayed on another surface of the display portion 9001. Examples of the information 9051 include notification of reception of an e-mail, SNS, or an incoming call, the title and sender of an e-mail, SNS, or the like, the date, the time, remaining battery, and the reception strength of an antenna. Alternatively, the icon 9050 or the like may be displayed at the position where the information 9051 is displayed.

FIG. 37C is a perspective view of a portable information terminal 9102. The portable information terminal 9102 has a function of displaying information on three or more surfaces of the display portion 9001. Here, an example in which information 9052, information 9053, and information 9054 are displayed on different surfaces is shown. For example, a user can check the information 9053 displayed in a position that can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 37D is a perspective view of a watch-type portable information terminal 9200. For example, the portable information terminal 9200 can be used as a smartwatch. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. The connection terminal 9006 of the portable information terminal 9200 allows mutual data transmission with another information terminal and charging. Note that the charging operation may be performed by wireless power feeding.

FIG. 37E, FIG. 37F, and FIG. 37G are perspective views of a foldable portable information terminal 9201. FIG. 37E is a perspective view illustrating the portable information terminal 9201 that is opened. FIG. 37G is a perspective view illustrating the portable information terminal 9201 that is folded. FIG. 37F is a perspective view illustrating the portable information terminal 9201 that is shifted from one of the states in FIG. 37E and FIG. 37G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. For example, the display portion 9001 can be bent with a radius of curvature of greater than or equal to 1 mm and less than or equal to 150 mm.

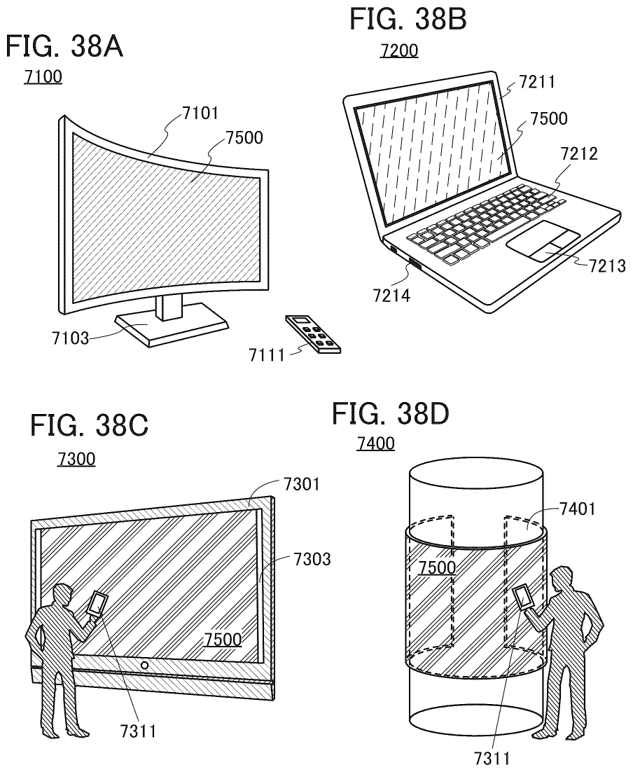

FIG. 38A illustrates an example of a television device. In a television device 7100, a display portion 7500 is incorporated in a housing 7101. Here, the housing 7101 is supported by a stand 7103.

The television device 7100 illustrated in FIG. 38A can be operated with an operation switch provided in the housing 7101 or a separate remote controller 7111. Alternatively, a touch panel may be used in the display portion 7500 so that the television device 7100 can be operated by touching the touch panel. The remote controller 7111 may be provided with a display portion in addition to operation buttons.

Note that the television device 7100 may include a television receiver and a communication device for a network connection.

FIG. 38B illustrates a laptop personal computer 7200. The laptop personal computer 7200 includes a housing 7211, a keyboard 7212, a pointing device 7213, an external connection port 7214, and the like. In the housing 7211, the display portion 7500 is incorporated. FIG. 38C and FIG. 38D illustrate examples of digital signage. A digital signage 7300 illustrated in FIG. 38C includes a housing 7301, the display portion 7500, a speaker 7303, and the like. The digital signage 7300 can also include an LED lamp, an operation key (including a power switch or an operation switch), a connection terminal, a variety of sensors, a microphone, and the like.

FIG. 38D illustrates a digital signage 7400 mounted on a cylindrical pillar 7401. The digital signage 7400 includes the display portion 7500 provided along a curved surface of the pillar 7401.

The larger display portion 7500 can provide a larger amount of information at a time and attract more attention, so that the effectiveness of advertisement can be increased, for example.

A touch panel is preferably used in the display portion 7500 so that the user can operate the digital signage. Thus, the digital signage can be used for not only advertising but also providing information that the user needs, such as route information, traffic information, and an information map of a commercial facility.

Furthermore, as illustrated in FIG. 38C and FIG. 38D, it is preferable that the digital signage 7300 or the digital signage 7400 be capable of working with an information terminal 7311 such as a user's smartphone through wireless communication. For example, information of the advertisement displayed on the display portion 7500 can also be displayed on a screen of the information terminal 7311, or display on the display portion 7500 can be switched by operating the information terminal 7311.

Furthermore, it is possible to make the digital signage 7300 or the digital signage 7400 execute a game with the use of the information terminal 7311 as an operation means (controller). Thus, an unspecified number of users can join in and enjoy the game concurrently.

A display device of one embodiment of the present invention can be used in each of the display portions 7500 in FIG. 38A to FIG. 38D.

The electronic devices of this embodiment each include a display portion; however, one embodiment of the present invention can also be used in an electronic device without a display portion.

### Example 1

This example shows fabrication of transistors each including a metal oxide film of one embodiment of the present invention and evaluation results of the electrical characteristics of the transistors.

### Fabrication of Samples

For the structure of the fabricated transistors, the transistor 350B shown in Structure Example 2-3 in Embodiment 2 and FIG. 27A can be employed.

First, an approximately 100-nm-thick tungsten film was formed over a glass substrate by a sputtering method and processed to obtain a first gate electrode. Subsequently, as a first gate insulating layer, an approximately 300-nm-thick stacked-layer film in which a silicon nitride film and a silicon oxynitride film are stacked was formed by a plasma CVD method.

Next, a metal oxide film with a thickness of approximately 30 nm was deposited over the first gate insulating layer, and the metal oxide film was processed to obtain a semiconductor layer. The metal oxide film was formed by a sputtering method using a metal oxide target having an atomic ratio of metal elements In:Ga:Zn=4:2:4.1 [atomic ratio]. A mixed gas of an argon gas and an oxygen gas was used as a deposition gas. Here, four samples (Sample B1 to Sample B4) whose metal oxide films were deposited under different conditions were fabricated.

The metal oxide film of Sample B1 was deposited under conditions where the proportion of the flow rate of the oxygen gas in the total flow rate of the deposition gas (oxygen flow rate ratio) was 10%. The deposition was carried out without heating the substrate.

The metal oxide film of Sample B2 was deposited under conditions where the oxygen flow rate ratio was 30%. The deposition was carried out without heating the substrate.

The metal oxide film of Sample B3 was deposited under conditions where the oxygen flow rate ratio was 40%. The deposition was carried out without heating the substrate.

The metal oxide film of Sample B4 was deposited under conditions where the oxygen flow rate ratio was 50%. The deposition was carried out without heating the substrate.

The metal oxide films of Sample B1 to Sample B4 were formed under the same conditions as the metal oxide films of sample A1 to sample A4 described in Embodiment 1 above, respectively.

After the semiconductor layer was formed, heat treatment was performed at 350° C. in a nitrogen gas atmosphere for one hour. After that, another heat treatment was performed at 350° C. in a mixed gas atmosphere of a nitrogen gas and an oxygen gas for one hour.

Next, as a second gate insulating layer, a silicon oxynitride film with a thickness of approximately 150 nm was deposited by a plasma CVD method.

Next, a metal oxide film with a thickness of approximately 20 nm was deposited over the second gate insulating layer by a sputtering method. The metal oxide film was deposited using a metal oxide target having an atomic ratio of metal elements In:Ga:Zn=4:2:4.1 [atomic ratio] under an atmosphere containing oxygen. After that, heat treatment was performed at 350° C. in an atmosphere containing nitrogen for one hour.

Then, a molybdenum film with a thickness of approximately 100 nm was deposited over the metal oxide film by a sputtering method. After that, part of the molybdenum film and part of the metal oxide film were removed by etching, so that a second gate electrode and a metal oxide layer were obtained.

Then, treatment of adding boron as an impurity element was performed using the second gate electrode as a mask. A plasma ion doping apparatus was used for addition of the impurity. A B₂H₆ gas was used as a gas for supplying boron.

Next, a silicon oxynitride film with a thickness of approximately 300 nm was deposited by a plasma CVD method as a protective insulating layer covering the transistor. Subsequently, an opening was formed in part of the protective insulating layer and part of the second gate insulating layer by etching, and a molybdenum film was deposited by a sputtering method and then processed to obtain a source electrode and a drain electrode. After that, an approximately 1.5-μm-thick acrylic film was formed as a planarization layer, and heat treatment was performed at 250° C. in a nitrogen atmosphere for one hour.

Through the above steps, Sample B1 to Sample B4 each including a transistor formed over the glass substrate were obtained.

### Id-Vg Characteristics of Transistors

Next, the Id-Vg characteristics of the transistors fabricated as above were measured.

As the conditions for measuring the Id-Vg characteristics of the transistors, a voltage applied to the gate electrodes (the first gate electrode and the second gate electrode) (also referred to as a gate voltage (Vg)) was applied from −15 V to +20 V in increments of 0.25 V. Moreover, a voltage applied to the source electrode (also referred to as a source voltage (Vs)) was 0 V, and a voltage applied to the drain electrode (also referred to as a drain voltage (Vd)) was 0.1 V and 10 V.

The measured transistors each had a designed channel length of 2 μm and a designed channel width of 3 μm.

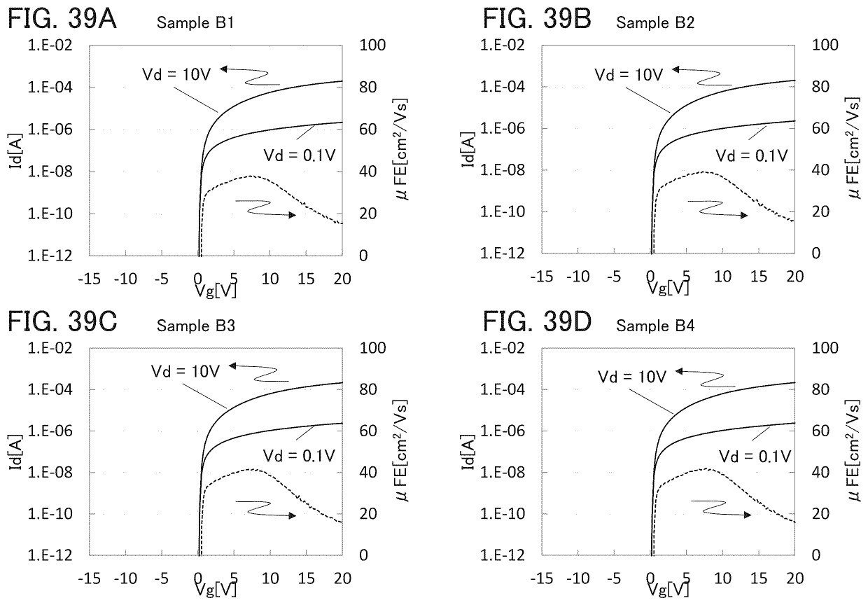

FIG. 39A to FIG. 39D show the Id-Vg characteristics of Sample B1 to Sample B4. In each graph, the horizontal axis represents a gate voltage (Vg) and the vertical axis represents a drain current (Id). In each graph, a dashed line shows the field-effect mobility (μFE) calculated from the Id-Vg characteristics at a drain voltage (Vd) of 10 V.

It was confirmed that favorable electrical characteristics can be obtained in each sample as shown in FIG. 39A to FIG. 39D. It was thus suggested that in the transistors using the metal oxide film of one embodiment of the present invention, the electrical characteristics are only slightly affected by a variation in the deposition conditions of the metal oxide film (particularly the oxygen flow rate ratio), and it was confirmed that the transistor has excellent mass productivity.

### Reliability Evaluation

Next, the reliability of Sample B1 to Sample B4 above was evaluated. A gate bias stress test (a GBT test) was performed for the reliability evaluation. In the GBT test, the substrate over which the transistor was formed was held at 60° C., a voltage of 0 V was applied to the source and the drain of the transistor, and a voltage of 20 V or −20 V was applied to the gate; this state was held for one hour. The results of the PBTS test and the NBTIS test are specifically described here. Note that for light irradiation in the NBTIS, white LED light with approximately 3400 lx was used. The transistors measured here each had a designed channel length of 2 μm and a designed channel width of 3 μm.

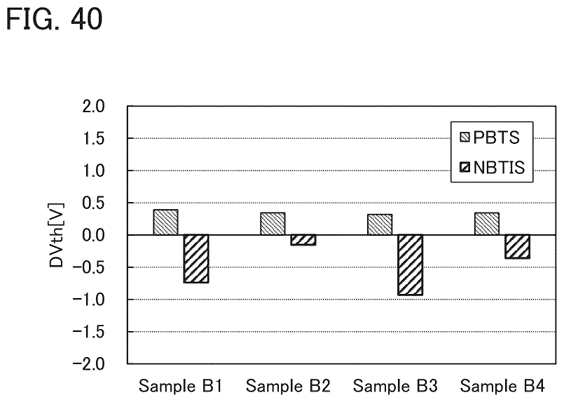

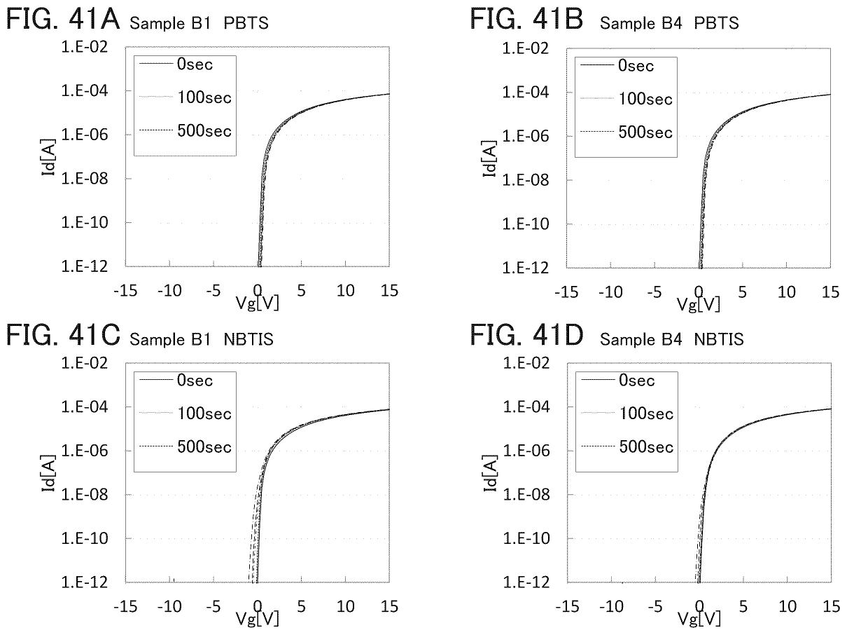

FIG. 40 shows the amount of change in threshold voltage (ΔVth), in Sample B1 to Sample B4, between before and after each of the PBTS test and the NBTIS test. As examples, FIG. 41A to FIG. 41D show shifts of the Id-Vg characteristics of Sample B1 and Sample B4 between before and after the GBT tests. FIG. 41A shows the results of the PBTS test of Sample B1; FIG. 41B, those of the PBTS test of Sample B4; FIG. 41C, those of the NBTIS test of Sample B1; and FIG. 41D, those of the NBTIS test of Sample B4.

As shown in FIG. 40 and FIG. 41A to FIG. 41D, it was confirmed that the transistor of each sample has a small variation in the threshold voltage and high reliability.

From the above results, it was confirmed that the transistor using the metal oxide film of one embodiment of the present invention has favorable transistor characteristics even when having a short channel length and has high reliability.

### Example 2

In this example, results of examining the composition of the metal oxide film of one embodiment of the present invention are described.

### Fabrication of Samples

Samples used in this example are metal oxide films each deposited over a glass substrate by a sputtering method. The metal oxide film was deposited using a metal oxide target having an atomic ratio of metal elements In:Ga:Zn=4:2:4.1 [atomic ratio]. A mixed gas of an argon gas and an oxygen gas was used as a deposition gas. The deposition of the metal oxide film was performed without heating the substrate. Here, three samples (Sample C1 to Sample C3) whose metal oxide films were deposited under different conditions were fabricated.

The metal oxide film of Sample C1 was deposited under conditions where the proportion of the flow rate of the oxygen gas in the total flow rate of the deposition gas (oxygen flow rate ratio) was 10%. The metal oxide film of Sample C2 was deposited under conditions where the oxygen flow rate ratio was 30%. The metal oxide film of Sample C3 was deposited under conditions where the oxygen flow rate ratio was 50%.

### HAADF-STEM Observation and EDX Analysis

For the three samples fabricated, observation by high-angle annular dark field scanning transmission electron microscopy (HAADF-STEM) and composition analysis by energy dispersive X-ray spectroscopy (EDX) were carried out.

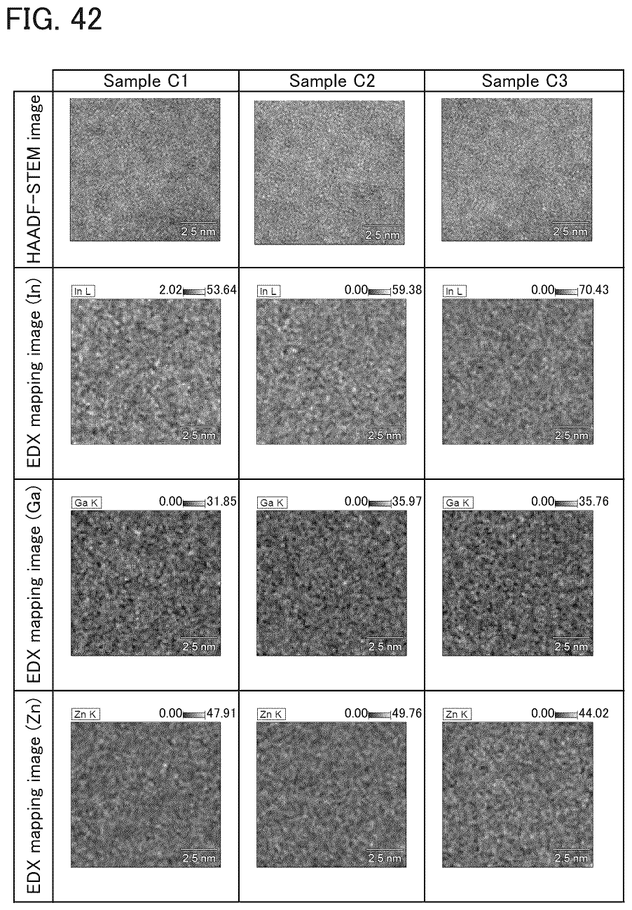

FIG. 42 shows a HAADF-STEM image and EDX mapping images regarding In, Ga, and Zn of each sample. The HAADF-STEM image and EDX mapping images of each sample are results of observation of the same region.

In a HAADF-STEM image, a contrast proportional to the square of an atomic number is obtained; therefore, a brighter region suggests the existence of a heavier atom. In an EDX mapping image, a bright color region corresponds to a region including a large quantity of the target element, and a dark color region corresponds to a region including a small quantity of the target element.

As shown in the EDX mapping images in FIG. 42, light and shade were observed in each of Sample C1, Sample C2, and Sample C3. It was thus confirmed that In, Ga, and Zn do not exist uniformly in a several-nanometer range.

### Quantitative Analysis of Composition

Subsequently, quantitative analysis of In, Ga, and Zn was performed on a bright region (In-rich region) and a dark region (In-poor region) in the above EDX mapping image regarding In of each sample and a bright region (Ga-rich region) and a dark region (Ga-poor region) of the EDX mapping image regarding Ga of each sample. The quantitative analysis was performed at five points in each region.

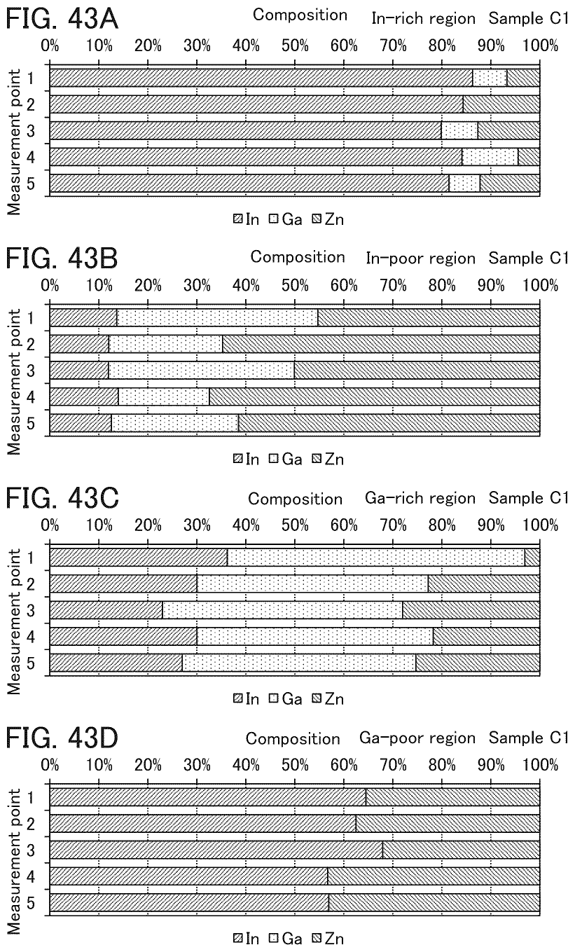

FIG. 43A to FIG. 43D show results of the quantitative analysis of Sample C1. FIG. 43A shows the analysis results of the In-rich region; FIG. 43B, those of the In-poor region; FIG. 43C, those of the Ga-rich region; and FIG. 43D, those of the Ga-poor region. In each graph, the horizontal axis represents the proportion of each element when the sum of the composition of In, Ga, and Zn is 100%, and the proportions at the five measurement points are shown by column graphs.

With a focus on FIG. 43B and FIG. 43C, it is found that there are regions where more Ga is detected than In or the Ga proportion is high as compared to the composition of the target (In:Ga:Zn=4:2:4.1). Note that In was detected in the In-poor region in FIG. 43B probably because the measurement sample had a thickness of approximately 30 nm and In existing in the depth direction was detected.

With a focus on FIG. 43A and FIG. 43D, portions where the Ga composition was extremely low or no Ga was detected were also observed. It is presumed that a state such as indium oxide or indium zinc oxide exists in the region where no Ga is detected.

From the above results, it was confirmed that the metal oxide film actually deposited is not a uniform film reflecting the composition of the target but a film in which regions with different compositions are distributed.

Note that although only the results of Sample C1 have been described here, Sample C2 and Sample C3 also showed similar tendency.

### Examination Using Histogram

Next, quantitative analysis of the whole EDX mapping images shown in FIG. 42 was conducted, and examination using a histogram was conducted on the composition of each of In, Ga, and Zn.

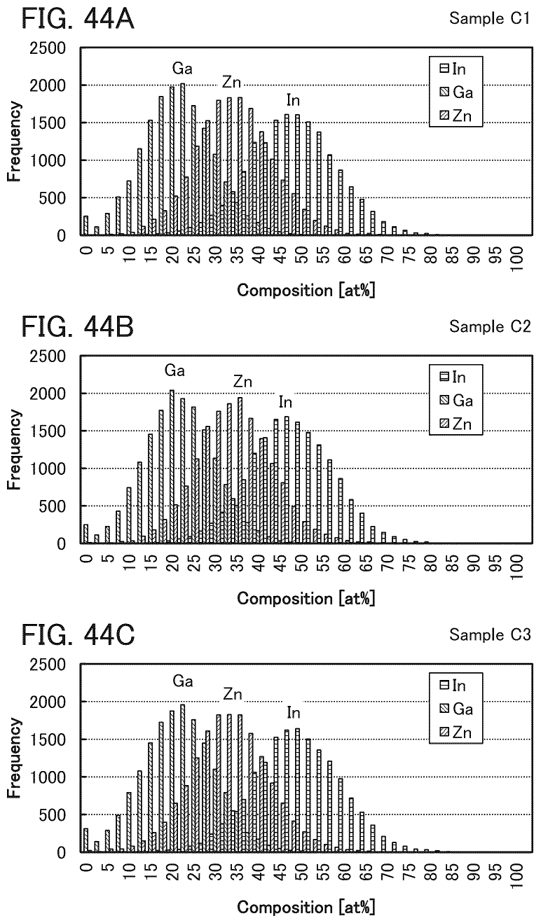

FIG. 44A, FIG. 44B, and FIG. 44C show histograms of Sample C1, Sample C2, and Sample C3. In each graph, the horizontal axis represents the composition and the vertical axis represents the frequency. For easy viewing of each element, the name of the element is shown near the top of the peak in each graph.

As shown in FIG. 44A to FIG. 44C, it was confirmed that there is no significant difference in the distribution of the composition between the samples. Furthermore, it was confirmed that there is a region where no Ga is detected (a region where the Ga composition is 0) in each sample. From the above, it was confirmed that there is no significant distribution difference of the composition between a plurality of metal oxide films which were formed with different oxygen flow rate ratios to have different crystallinities.

From the above results, it was confirmed that the metal oxide film of one embodiment of the present invention is not a uniform film but a film in which the metal elements constituting the metal oxide film are unevenly distributed and is observed like a composite.

### REFERENCE NUMERALS

10: substrate, 11: metal oxide film, 12a, 12b: region, 20: direct spot, 20a, 20b, 20c, 20d: electron diffraction pattern, 21: first spot, 22: second spot, 30, 30a, 30b, 30c, 30r: histogram, 31: first region, 32: second region, 41, 42: peak, 300, 300A: transistor, 302: substrate, 304: conductive layer, 306: insulating layer, 308: semiconductor layer, 312a, 312b, 313a, 313b: conductive layer, 314, 316:

insulating layer, 320: conductive layer, 342: opening, 350, 350A, 350B, 350C: transistor, 352: substrate, 353, 353a, 353b: insulating layer, 356: conductive layer, 358: semiconductor layer, 358n: low-resistance region, 360: insulating layer, 362: conductive layer, 364: metal oxide layer, 366, 368: insulating layer, 370a, 370b: conductive layer, 391a, 391b, 392: opening

1. An evaluation method of a metal oxide film, comprising:
irradiating a plurality of regions of the metal oxide film with an electron beam with a beam diameter of greater than or equal to 0.3 nm and less than or equal to 10 nm from a direction perpendicular to a film surface of the metal oxide film to acquire a plurality of electron diffraction patterns;
calculating interplanar spacings d for a plurality of spots observed in the plurality of electron diffraction patterns; and
evaluating crystallinity of the metal oxide film from a shape of frequency distribution of the interplanar spacings d.

2. An evaluation method of a metal oxide film, comprising:
irradiating a plurality of regions of the metal oxide film with an electron beam with a beam diameter of greater than or equal to 0.3 nm and less than or equal to 10 nm from a direction perpendicular to a film surface of the metal oxide film to acquire a plurality of electron diffraction patterns;
calculating angles θ from reference lines for a plurality of spots observed in the plurality of electron diffraction patterns; and
evaluating crystallinity of the metal oxide film from a shape of distribution of the angles 0.
